(19) United States
(12) Patent Application Publication
(10) Pub. No.: US 2024/0217882 A1
(43) Pub. Date: Jul. 4, 2024

(54) PIEZOELECTRIC MATERIAL COMPOSITION, METHOD OF MANUFACTURING THE SAME, PIEZOELECTRIC DEVICE, AND APPARATUS INCLUDING THE PIEZOELECTRIC DEVICE

(71) Applicants: LG Display Co., Ltd., Seoul (KR); KOREA UNIVERSITY RESEARCH AND BUSINESS FOUNDATION, Seoul (KR)

(72) Inventors: Daesu KIM, Gyeonggi-do (KR); YongWoo LEE, Gyeonggi-do (KR); JounHo LEE, Gyeonggi-do (KR); Sooyoun KIM, Gyeonggi-do (KR); HwaYoul LEE, Gyeonggi-do (KR); Uihyeon JEONG, Gyeonggi-do (KR); Sahn NAHM, Gyeonggi-do (KR); Su-Hwan GO, Gyeonggi-do (KR); Yeongyeong CHAE, Gyeonggi-do (KR); Seok-June CHAE, Gyeonggi-do (KR); Hero KIM, Gyeonggi-do (KR)

(73) Assignees: LG Display Co., Ltd., Seoul (KR); KOREA UNIVERSITY RESEARCH AND BUSINESS FOUNDATION, Seoul (KR)

(21) Appl. No.: 18/216,756

(22) Filed: Jun. 30, 2023

(30) Foreign Application Priority Data
Dec. 30, 2022 (KR) 10-2022-0190393
Jun. 22, 2023 (KR) 10-2023-0080118

(51) Int. Cl. C04B 35/495; C04B 35/493; C04B 35/626; C04B 35/64; H10N 30/097; H10N 30/853

(52) U.S. Cl. CPC C04B 35/495; C04B 35/493; C04B 35/6262; C04B 35/64; H10N 30/097; H10N 30/8542; C04B 2235/3234; C04B 2235/3249; C04B 2235/3255; C04B 2235/3262; C04B 2235/3272; C04B 2235/3281; C04B 2235/6025; C04B 2235/6567; C04B 2235/765; C04B 2235/786

(57) ABSTRACT

A piezoelectric material composition may be represented by Equation 1,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 1 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

### CROSS-REFERENCE TO RELATED APPLICATIONS

This application claims the benefit of Korean Patent Application No. 10-2022-0190393 filed on Dec. 30, 2022, and Korean Patent Application No. 10-2023-0080118 filed on Jun. 22, 2023, the entirety of each which is hereby incorporated by reference as if fully set forth herein.

### BACKGROUND

### Technical Field

The present disclosure relates to a piezoelectric material composition, a method of manufacturing the same, a piezoelectric device, and an apparatus including the piezoelectric device.

### Discussion of the Related Art

Piezoelectric materials are being widely used as materials of parts such as ultrasound vibrators, electromechanical transducers, and actuators used in the broad field such as ultrasound apparatuses, image apparatuses, sound apparatuses, communication apparatuses, and sensors.

The inventors have recognized the following problems occurring when a developed piezoelectric material is practically applied.

Pb(Zr, Ti)O₃ (PZT)-based materials have a high piezoelectric characteristic, and thus, are used as a piezoelectric material. However, lead (Pb) is a material having strong toxicity and has high volatility in a sintering process, and due to this, causes serious environmental pollution.

Therefore, because a PZT piezoelectric material occupying the most of piezoelectric materials causes an environmental pollution problem, it is required to develop a Pb-free piezoelectric material. The Pb-free piezoelectric material has a low piezoelectric characteristic compared to the PZT piezoelectric material, and thus, a high piezoelectric characteristic is needed.

### SUMMARY

Accordingly, embodiments of the present disclosure are directed to a piezoelectric material composition, a method of manufacturing the same, a piezoelectric device, and an apparatus including the piezoelectric device that substantially obviates one or more of the problems due to limitations and disadvantages of the related art.

An aspect of the present disclosure is to provide a piezoelectric material composition which may not include lead and may have a high piezoelectric characteristic.

Another aspect of the present disclosure is to provide a method of manufacturing a piezoelectric material composition, which may orient grains of a piezoelectric material by using a template so as to provide a piezoelectric material composition having a high piezoelectric characteristic, thereby enhancing a piezoelectric characteristic.

Another aspect of the present disclosure is to provide a piezoelectric device having a high piezoelectric characteristic and an apparatus including the piezoelectric device.

Another aspect of the present disclosure is to provide a piezoelectric device, having a composition of various combinations for developing a material where a rhombohedral-orthorhombic-tetragonal (R-O-T) structure having a high rhombohedral-orthorhombic (R-O) ratio is provided in a room temperature, and a piezoelectric device including a material having enhanced performance.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a piezoelectric material composition is represented by [Equation 1]:

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 1 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00.

In another aspect, a piezoelectric material composition according to an embodiment of the present disclosure may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

In another aspect of the present disclosure, a method of manufacturing a piezoelectric material composition according to an embodiment of the present disclosure, the method may comprise mixing a matrix material with a seed material to prepare a slurry, molding the slurry to prepare a molding element, and sintering the molding element to prepare a sintered material, the sintered material may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

In another aspect, a piezoelectric device according to one or more embodiments of the present disclosure may comprise a piezoelectric device layer including a first material and a second material surrounded by the first material, a first electrode part disposed at a first surface of the piezoelectric device layer, and a second electrode part disposed at a second surface different from the first surface of the piezoelectric device layer, the piezoelectric device layer may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

In another aspect, an apparatus according to an embodiment of the present disclosure may comprise a vibration member, and a piezoelectric device disposed at a rear surface of the vibration member. The piezoelectric device may comprise a piezoelectric device layer including a first material and a second material surrounded by the first material, a first electrode part disposed at a first surface of the piezoelectric device layer, and a second electrode part disposed at a second surface different from the first surface of the piezoelectric device layer, the piezoelectric device layer may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

According to an embodiment of the present disclosure, because a piezoelectric material composition does not include lead (Pb) and has a high piezoelectric characteristic, a piezoelectric device and a display apparatus each including the piezoelectric material composition may be driven with a low driving voltage.

According to an embodiment of the present disclosure, a method of manufacturing a piezoelectric material composition may be considerably reduced in time and cost, thereby considerably enhancing productivity.

According to an embodiment of the present disclosure, productivity may be enhanced, and thus, optimization of a manufacturing process may be implemented.

According to an embodiment of the present disclosure, because a piezoelectric material composition does not include Pb, a production restriction material may be reduced and replacement of a harmful material may be implemented, and thus, an environment-friendly piezoelectric material composition may be provided.

Other systems, methods, features and advantages will be, or will become, apparent to one with skill in the art upon examination of the following figures and detailed description. It is intended that all such additional systems, methods, features and advantages be included within this description, and be within the scope of the present disclosure. Nothing in this section should be taken as a limitation on the claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a cross-sectional view illustrating a piezoelectric device according to an embodiment of the present disclosure.

FIG. 2 is a cross-sectional view illustrating a piezoelectric device according to another embodiment of the present disclosure.

FIG. 3 illustrates a method of manufacturing a non-templated grain growth (TGG) piezoelectric device according to an embodiment of the present disclosure.

FIG. 4 illustrates a method of manufacturing a non-TGG piezoelectric device according to another embodiment of the present disclosure.

FIG. 5 illustrates a method of manufacturing a TGG piezoelectric device according to an embodiment of the present disclosure.

FIG. 6 illustrates a method of manufacturing a TGG piezoelectric material composition according to an embodiment of the present disclosure.

FIG. 7 illustrates a method of manufacturing a seed material of a TGG piezoelectric material composition according to an embodiment of the present disclosure.

FIG. 8 illustrates a change in a sintering temperature with respect to a time, in a piezoelectric material composition according to an embodiment of the present disclosure.

FIG. 9 illustrates a crystal structure of a TGG piezoelectric material according to an embodiment of the present disclosure.

FIGS. 10A to 10C illustrate a tetragonal (T), orthorhombic (O), and rhombohedral (R) crystallographic direction of orientation of a TGG piezoelectric material composition according to an embodiment of the present disclosure.

FIG. 11 illustrates an X-ray diffractometer (XRD) measurement value of a seed manufactured by the manufacturing method of FIG. 7.

FIG. 12 illustrates a scanning electron microscope (SEM) image of a seed manufactured by the manufacturing method of FIG. 7.

FIG. 13 illustrates a grain variation occurring in a preparing a secondary seed of FIG. 7.

FIG. 14 illustrates an X-ray diffraction pattern with respect to a BAZ content of a non-TGG composition according to an embodiment of the present disclosure.

FIGS. 15A to 15E are graphs showing an X-ray diffraction pattern in about 66 degrees with respect to a BAZ content of a non-TGG composition according to an embodiment of the present disclosure.

FIGS. 16A to 16E illustrate an SEM image with respect to a BAZ content of a non-TGG composition according to an embodiment of the present disclosure.

FIGS. 17A to 17E illustrate polarization versus electric field (P-E) and current versus electric field (I-E) of a non-TGG composition according to an embodiment of the present disclosure.

FIGS. 18A to 18E illustrate an X-ray diffraction pattern with respect to a BAZ content of a non-TGG composition according to an embodiment of the present disclosure.

FIGS. 19A to 19C are Rietveld refinement result tables of non-TGG KNNS-BZ-BAZ ceramic according to an embodiment of the present disclosure.

FIGS. 20A to 20E are temperature versus dielectric constant graphs in different frequencies with respect to a BAZ content of a non-TGG composition according to an embodiment of the present disclosure.

FIG. 21 is a temperature versus dielectric constant graph with respect to a BAZ content of a non-TGG composition according to an embodiment of the present disclosure.

FIG. 22 is a graph showing a relative density (%), a dielectric constant ε^{T}₃₃/ε₀, a loss factor tan δ, a piezoelectric charge constant d₃₃, an electromechanical coupling factor k_{ρ}, and an energy harvesting performance index with respect to a BAZ content of a non-TGG composition according to an embodiment of the present disclosure.

FIGS. 23A to 23D illustrate a piezoelectric characteristic when an electric field is applied to a non-TGG composition according to an embodiment of the present disclosure.

FIG. 24 is a graph showing a piezoelectric charge constant d₃₃ with respect to a variation of an annealing temperature of a non-TGG composition according to an embodiment of the present disclosure.

FIG. 25 is a graph showing an X-ray diffraction pattern with respect to a BAZ content according to an embodiment of the present disclosure.

FIG. 26 illustrates a TEM image of a TGG composition according to an embodiment of the present disclosure.

FIGS. 27A and 27B illustrate an electron backscatter diffraction (EBSD) image of each of a TGG composition and a non-TGG composition according to an embodiment of the present disclosure.

FIGS. 28A and 28B illustrate a pole figure in a {110} orientation of each of a TGG composition and a non-TGG composition according to an embodiment of the present disclosure.

FIGS. 29A to 29E illustrate a microstructure based on a BAZ content of a TGG composition sample according to an embodiment of the present disclosure.

FIGS. 30A to 30E illustrate P-E and I-E of a TGG composition according to an embodiment of the present disclosure.

FIG. 31 illustrates numerical variations of saturated polarization Pₛ, remnant polarization Pᵣ, and a coercive field E_{c} with respect to a BAZ content of each of a TGG composition and a non-TGG composition according to an embodiment of the present disclosure.

FIGS. 32A to 32E are graphs showing an X-ray diffraction pattern with respect to a BAZ content of a TGG composition according to an embodiment of the present disclosure.

FIGS. 33A to 33C are Rietveld refinement result tables of TGG KNNS-BZ-BAZ ceramic according to an embodiment of the present disclosure.

FIGS. 34A to 34E are temperature versus dielectric constant graphs in different frequencies with respect to a BAZ content of a TGG composition according to an embodiment of the present disclosure.

FIG. 35 is a graph showing a relative density (%), a dielectric constant ε^{T}₃₃/ε₀, a loss factor tan δ, a piezoelectric charge constant d₃₃, an electromechanical coupling factor k_{ρ}, and an energy harvesting performance index of a TGG piezoelectric material composition with respect to a BAZ content according to an embodiment of the present disclosure.

FIGS. 36A to 36C illustrate a piezoelectric characteristic when an electric field is applied to a TGG composition according to an embodiment of the present disclosure.

FIG. 37 is a graph showing a piezoelectric charge constant d₃₃ with respect to a variation of an annealing temperature with respect to a BAZ content according to an embodiment of the present disclosure.

FIG. 38 is a graph showing a piezoelectric charge constant d₃₃ with respect to a BAZ content according to an embodiment of the present disclosure.

FIG. 39 is a graph showing a density (%), a dielectric constant ε^{T}₃₃/ε₀, a loss factor tan δ, an electromechanical coupling factor k_{ρ}, and a piezoelectric charge constant d₃₃ with respect to a content of antimony (Sb) of a non-TGG composition according to an embodiment of the present disclosure.

FIG. 40 is a graph showing a volume fraction of R-O-T with respect to a content of Sb of a non-TGG composition according to an embodiment of the present disclosure.

FIG. 41 is a graph showing a density (%), a dielectric constant ε^{T}₃₃/ε₀, a loss factor tan δ, an electromechanical coupling factor k_{ρ}, and a piezoelectric charge constant d₃₃ with respect to a content of Sb of a TGG composition according to an embodiment of the present disclosure.

FIG. 42 is a graph showing an X-ray diffraction pattern with respect to a content of Sb of a TGG composition according to an embodiment of the present disclosure.

FIGS. 43A to 43K are temperature versus dielectric constant graphs with respect to a content of Sb according to an embodiment of the present disclosure.

FIGS. 44A to 44K illustrate a microstructure of a piezoelectric material composition based on a content of Sb according to an embodiment of the present disclosure.

FIG. 45 is a graph showing a piezoelectric charge constant d₃₃ of each of a TGG composition and a non-TGG composition based on a BAZ content according to an embodiment of the present disclosure.

FIG. 46 is a graph showing a strain of each of a TGG composition and a non-TGG composition based on a BAZ content according to an embodiment of the present disclosure.

FIG. 47 is a graph showing a ratio of a piezoelectric charge constant and a ratio of an R-O phase structure of each of a TGG composition and a non-TGG composition based on a BAZ content according to an embodiment of the present disclosure.

FIGS. 48A to 48D illustrate a direction of orientation with respect to the kind of phase.

FIG. 49 illustrates a comsol driving simulation result of an energy harvester EH of each of a TGG composition and a non-TGG composition according to an embodiment of the present disclosure.

FIG. 50 illustrates a frequency versus output voltage graph of an energy harvester EH of each of a TGG composition and a non-TGG composition according to an embodiment of the present disclosure.

FIG. 51 illustrates a load resistance versus output voltage graph of an energy harvester EH of each of a TGG composition and a non-TGG composition according to an embodiment of the present disclosure.

FIG. 52 illustrates a load resistance versus output current graph of an energy harvester EH of each of a TGG composition and a non-TGG composition according to an embodiment of the present disclosure.

FIG. 53 illustrates a load resistance versus output power graph of an energy harvester EH of each of a TGG composition and a non-TGG composition according to an embodiment of the present disclosure.

FIG. 54 illustrates an output power of each of an energy harvester EH according to a comparative example and an energy harvester EH according to an embodiment of the present disclosure.

FIG. 55 illustrates an energy harvester EH according to an embodiment of the present disclosure.

FIG. 56 illustrates an example where the energy harvester EH of FIG. 55 is mounted on a zig.

FIG. 57 is an image showing a break surface of a multi-layered actuator prepared based on a TGG composition according to an embodiment of the present disclosure.

FIG. 58 illustrates a comsol driving simulation result of a multi-layered actuator MLA prepared based on a non-TGG composition and a TGG composition according to an embodiment of the present disclosure.

FIG. 59 illustrates a frequency versus acceleration graph of a multi-layered actuator MLA prepared based on a non-TGG composition and a TGG composition according to an embodiment of the present disclosure.

FIG. 60 illustrates a displacement graph of a multi-layered actuator MLA prepared based on a non-TGG composition and a TGG composition according to an embodiment of the present disclosure.

FIG. 61 illustrates a variation of an acceleration with respect to a voltage of a multi-layered actuator MLA prepared based on a non-TGG composition and a TGG composition according to an embodiment of the present disclosure.

FIG. 62 illustrates a variation of a displacement with respect to a voltage of a multi-layered actuator MLA prepared based on a non-TGG composition and a TGG composition according to an embodiment of the present disclosure.

FIGS. 63A and 63B illustrate an acceleration and a displacement of each of a multi-layered actuator MLA according to a comparative example and a multi-layered actuator MLA prepared based on a non-TGG composition and a TGG composition according to an embodiment of the present disclosure.

FIG. 64 illustrates a multi-layered actuator MLA prepared based on a non-TGG composition and a TGG composition according to an embodiment of the present disclosure.

FIG. 65 illustrates an example where a non-TGG composition and a TGG composition according to an embodiment of the present disclosure is mounted on a zig.

FIG. 66 is an image showing a break surface of a multi-layered actuator prepared based on a TGG composition according to an embodiment of the present disclosure.

FIGS. 67A to 67I illustrate energy dispersive spectrometer (EDS) analysis data of a multi-layered actuator prepared based on a TGG composition according to an embodiment of the present disclosure.

FIG. 68 illustrates a piezoelectric characteristic of each of a non-TGG composition and a TGG composition according to an embodiment of the present disclosure.

FIG. 69 illustrates a vehicular sound apparatus according to an embodiment of the present disclosure.

FIG. 70 is a perspective view of a display apparatus according to an embodiment of the present disclosure.

FIG. 71 is a cross-sectional view taken along line I-I′ of FIG. 70 according to an embodiment of the present disclosure.

FIG. 72 illustrates a piezoelectric device of FIG. 70 according to an embodiment of the present disclosure.

Throughout the drawings and the detailed description, unless otherwise described, the same drawing reference numerals should be understood to refer to the same elements, features, or structures. The sizes, lengths, and thicknesses of layers, regions, and elements, and depiction thereof may be exaggerated for clarity, illustration, or convenience.

### DETAILED DESCRIPTION

Reference is now made in detail to the exemplary embodiments of the present disclosure, examples of which may be illustrated in the accompanying drawings. In the following description, where a detailed description of relevant known functions or configurations is determined to unnecessarily obscure a gist of the inventive concept, a detailed description of such known functions or configurations may be omitted or may be briefly provided for brevity. The progression of processing steps and/or operations described is an example, and the sequence of steps and/or operations is not limited to that set forth herein and may be changed as is known in the art, with the exception of steps and/or operations necessarily occurring in a particular order.

Advantages and features of the present disclosure, and implementation methods thereof, will be clarified through the following exemplary embodiments described with reference to the accompanying drawings. The present disclosure may, however, be embodied in different forms and should not be construed as limited to the exemplary embodiments set forth herein. Rather, these example embodiments may be provided so that this disclosure may be sufficiently thorough and complete and to assist those skilled in the art to fully understand the scope of the present disclosure.

The shapes, dimensions, areas, ratios, angles, numbers, and the like, which are illustrated in the drawings to describe various example embodiments of the present disclosure, are merely given by way of example. Therefore, the present disclosure is not limited to the illustrations in the drawings. Like reference numerals generally denote like elements throughout the specification, unless otherwise specified.

Where a term like “comprise,” “have,” “include,” “contain,” “constitute,” “made up of,” or “formed of,” is used, one or more other elements may be added unless a more limiting term, such as “only” or the like, is used. The terms and names used in the present disclosure are merely used to describe particular embodiments, and are not intended to limit the scope of the present disclosure. An element described in the singular form is intended to include a plurality of elements, and vice versa, unless the context clearly indicates otherwise.

The word “exemplary” is used to mean serving as an example or illustration, unless otherwise specified. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, where a structure is described as being positioned “on,” “over,” “under,” “above,” “below;” “beneath,” “near,” “close to,” “adjacent to,” “beside,” or “next to” another structure, this description could be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row;” “vertical,” “horizontal,” and the like refer to an arbitrary frame of reference, unless otherwise specified.

In describing a temporal relationship, where the temporal order is described as, for example, “after,” “subsequent,” “next,” “before,” “preceding.” “prior to,” or the like, a case that is not consecutive or not sequential may be included unless a more limiting term, such as “just,” “immediate(ly),” or “direct(ly),” is used.

It is understood that, although the term “first,” “second,” “A,” “B,” “a,” “b,” etc. may be used herein to describe various elements, these elements should not be interpreted to be limited by these terms, for example, to any particular order, precedence, or number of elements. These terms are only used to distinguish one element from another. For example, a first element could be termed as a second element, and, similarly, a second element could be termed as a first element, without departing from the scope of the present disclosure. Furthermore, the first element, the second element, and the like may be arbitrarily named according to the convenience of those skilled in the art without departing from the scope of the present disclosure. The terms “first,” “second,” “A,” “B,” “(a),” “(b),” and the like may be used to distinguish components from each other, but the functions or structures of the components are not limited by ordinal numbers or component names in front of the components, and the terms “first,” “second,” “A,” “B,” “(a),” “(b),” or the like are not used to define the essence, sequence, basis, order, or number of the elements.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The term “at least one” could be understood as including any and all combinations of one or more of the associated listed items. For example, the meaning of “at least one of a first item, a second item, and a third item” encompasses three listed items, combinations of any two of the three items, as well as each individual item, the first item, the second item, or the third item.

The expression of a first element, a second elements “and/or” a third element could be understood as one of the first, second and third elements or as any or all combinations of the first, second and third elements. By way of example, A, B and/or C can refer to only A: only B: only C: any or some combination of A, B, and C: or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various embodiments of the present disclosure may be partially or wholly coupled to or combined with each other, and may be operated, linked or driven technically together in various ways. The embodiments of the present disclosure may be carried out independently from each other, or may be carried out together in a co-dependent or related relationship. In one or more aspects, the components of each apparatus according to various embodiments of the present disclosure may be operatively coupled and configured.

Unless otherwise defined, the terms (including technical and scientific terms) used herein have the same meaning as commonly understood by one of ordinary skill in the art to which example embodiments belong. It should be further understood that terms, such as those defined in commonly used dictionaries, could be interpreted as having a meaning that is, for example, consistent with their meaning in the context of the relevant art and should not be interpreted in an idealized or overly formal sense unless expressly defined otherwise herein.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, or thickness illustrated in the drawings.

Hereinafter, embodiments of the present disclosure will be described in detail with reference to the accompanying drawings.

The inventors of the present disclosure have developed a piezoelectric material and have recognized the following problems occurring when the developed piezoelectric material is practically applied.

Because a PZT piezoelectric material occupying the most of piezoelectric materials causes an environmental pollution problem, it is required to develop a Pb-free piezoelectric material. The Pb-free piezoelectric material has a low piezoelectric characteristic compared to the PZT piezoelectric material, and thus, it is required to develop a material having a high piezoelectric characteristic.

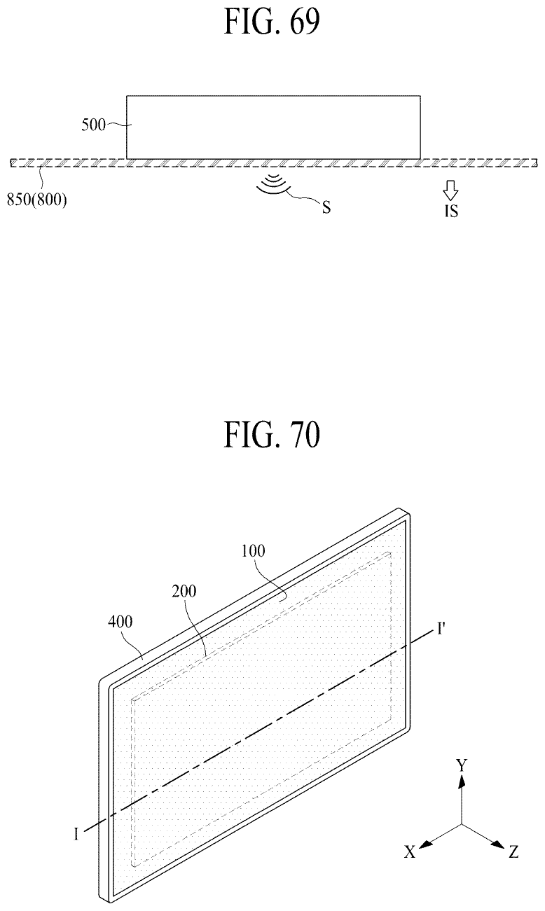

To solve such a problem, as described below with reference to FIGS. 1 to 69, the inventors have developed an optimal composition and sintering method on a non-TGG piezoelectric material composition expressed as the following Equation 1 and a TGG composition expressed as the following Equation 2, based on experiments performed a plurality of times.

FIG. 1 is a cross-sectional view illustrating a piezoelectric device according to an embodiment of the present disclosure.

With reference to FIG. 1, a piezoelectric device 10 according to an embodiment of the present disclosure may include a piezoelectric material composition 11, a first electrode layer 12, and a second electrode layer 13.

The piezoelectric material composition 11 may be provided between the first electrode layer 12 and the second electrode layer 13. The piezoelectric material composition 11 may be expressed as the following Equation 1.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 1 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00.

The piezoelectric material composition 11 may include a plurality of grains. Each of the plurality of grains may be divided by a grain boundary GB. The piezoelectric material composition 11 may include one of Fe₂O₃, Co₂O₃, Mn₂O₃, ZnO, GeO₂, CuO, and NiO. For example, when the piezoelectric material composition 11 includes iron oxide (Fe₂O₃), Fe₂O₃ may be added to the piezoelectric material composition of Equation 1 by 0 mol % to 1 mol %. For example, Fe₂O₃ may be added to the piezoelectric material composition of Equation 1 by 0.5 mol %. Accordingly, according to an embodiment of the present disclosure, sinterability may be further enhanced.

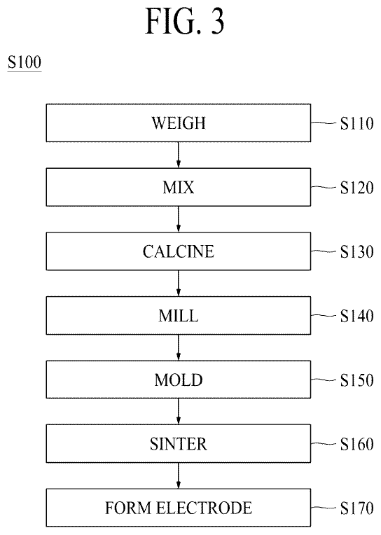

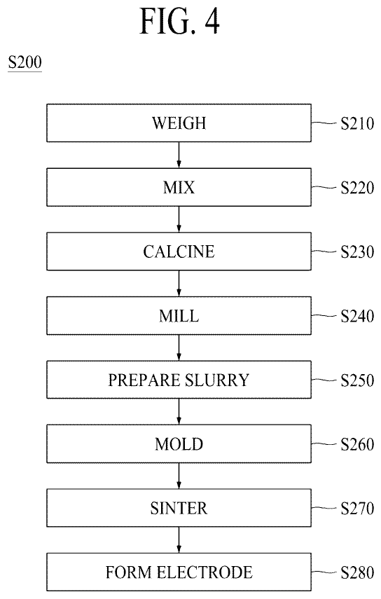

The piezoelectric material composition 11 may have a (001) crystal orientation and may have a random direction of orientation. For example, the piezoelectric material composition 11 according to an embodiment of the present disclosure may include a plurality of first materials 11a. For example, the plurality of first materials 11a may not include a seed material which does not affect a grain growth orientation, and thus, may have a random direction of orientation. For example, the plurality of first materials 11a may have a (001) crystal orientation. For example, the plurality of first materials 11a may have a crystal structure which is grown in a (001) orientation, and a direction of orientation of each of the plurality of first materials 11a may be randomly configured. The first material 11a according to an embodiment of the present disclosure may be prepared by a method of manufacturing a piezoelectric material composition described below with reference to FIGS. 3 and 4.

The first electrode layer 12 and the second electrode layer 13 may be provided to face each other with the piezoelectric material composition 11 therebetween. For example, the first electrode layer 12 may be provided at a first surface (or a lower surface) of the piezoelectric material composition 11, and the second electrode layer 13 may be provided at a second surface (or an upper surface) of the piezoelectric material composition 11. The piezoelectric material composition 11 according to an embodiment of the present disclosure may be configured with a piezoelectric device 10 by the first electrode layer 12 and the second electrode layer 13 respectively provided at the first surface (or the lower surface) and the second surface (or the upper surface).

Accordingly, in an embodiment of the present disclosure, because a piezoelectric material composition does not include lead (Pb), a production restriction material may be reduced and replacement of a harmful material may be implemented, and thus, an environment-friendly piezoelectric material composition and a piezoelectric device including the same may be provided.

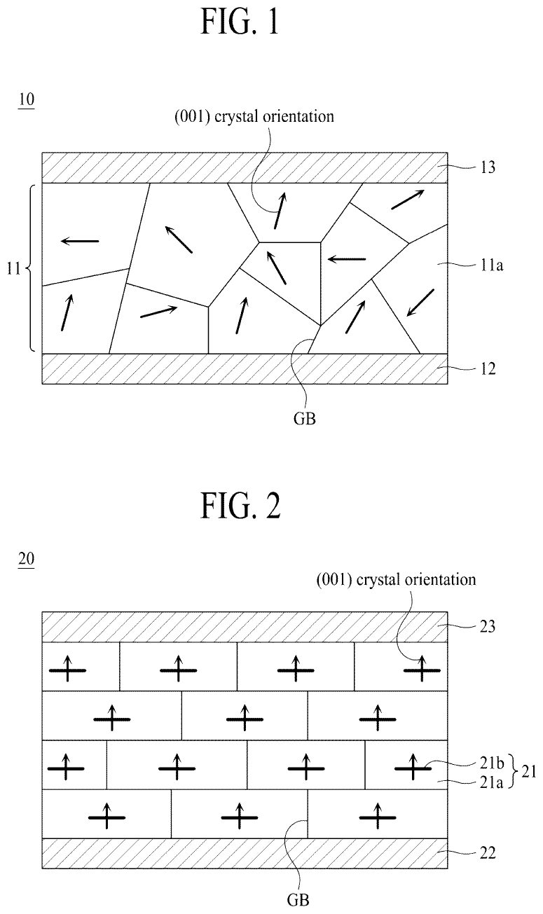

FIG. 2 is a cross-sectional view illustrating a piezoelectric device according to another embodiment of the present disclosure. This is a cross-sectional view illustrating a piezoelectric deice including a piezoelectric material composition manufactured by a TGG process. Except for a composition of a piezoelectric material composition, a piezoelectric device according to another embodiment of the present disclosure may be the same as the piezoelectric device described above with reference to FIG. 1. For example, a TGG piezoelectric material composition according to another embodiment of the present disclosure may further include a seed material in a non-TGG piezoelectric material composition. Hereinafter, therefore, only different elements will be described.

With reference to FIG. 2, a piezoelectric device 20 according to another embodiment of the present disclosure may include a piezoelectric material composition 21, a first electrode layer 22, and a second electrode layer 23.

The piezoelectric material composition 21 may be provided between the first electrode layer 22 and the second electrode layer 23. The piezoelectric material composition 21 may be expressed as the following Equation 2.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

The piezoelectric material composition 21 may include a plurality of grains configured with a first material 21a and a second material 21b. Each of the plurality of grains configured with the first material 21a and the second material 21b may be divided by a grain boundary GB.

The first material 21a may be a matrix material. For example, the first material 21a may have the same composition as that of the non-TGG piezoelectric material composition 11 described above with reference to FIG. 1. For example, a matrix material of a TGG composition according to another embodiment of the present disclosure may have the same composition as that of a non-TGG composition. For example, the first material 21a may be expressed as the following Equation 3. For example, Equation 3 may be configured to be equal to Equation 1 described above with reference to FIG. 1.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 3 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00.

The first material 21a may be a material where the second material 21b is excluded in Equation 2. For example, the first material 21a may include a material where NaNbO₃ which is the second material 21b is excluded in Equation 2. For example, Equation 3 may be a Equation where NaNbO₃ is excluded in Equation 2. For example, the first material 21a may have the same composition as that of the first material 11a of the piezoelectric material composition described above with reference to FIG. 1. Hereinafter, therefore, only different elements will be described.

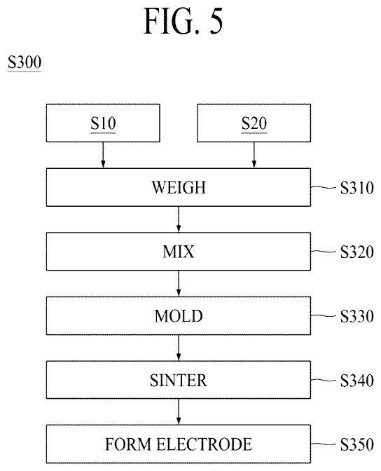

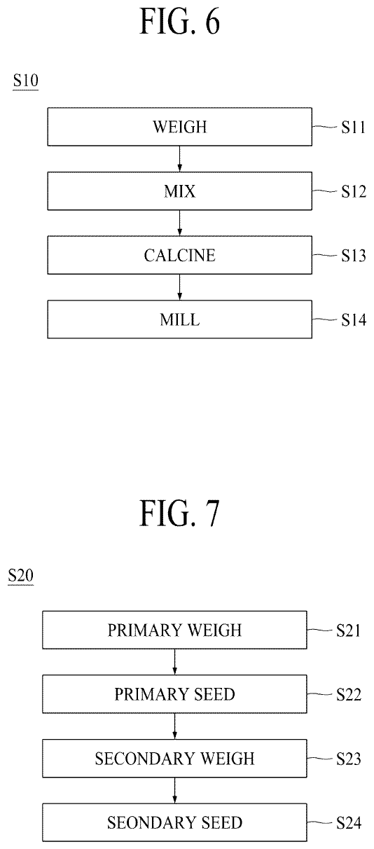

A grain of the first material 21a may be grown based on a crystal orientation of the second material 21b. For example, an aspect ratio of the second material 21b may be 5 to 20. For example, the piezoelectric material composition 21 according to another embodiment of the present disclosure may include a plurality of first materials 21a. For example, the plurality of first materials 21 a may have the same or substantially the same crystal orientation. For example, the plurality of first materials 21a may have a (001) crystal orientation. For example, the plurality of first materials 21a may have a crystal structure which is grown in a (001) orientation. Accordingly, the first material 21a according to an embodiment of the present disclosure may be configured to surround the second material 21b. The first material 21a according to an embodiment of the present disclosure may be prepared by a method of preparing a matrix material described below with reference to FIGS. 5 and 6.

The second material 21b may be formed in the first material 21a. The second material 21b may be surrounded by the first material 21a. The second material 21b may be disposed at a center portion of the first material 21a. For example, the center portion may not numerically and accurately correspond to a center (or middle) in the first material 21a having a certain volume and may be a certain region including a center (or middle) of the first material 21a having a certain volume. For example, the center portion may be a region extending from a center of the first material 21a, in the first material 21a having a certain volume. Therefore, in an embodiment of the present disclosure, even when the second material 21b is provided at a position deviating from the center (or middle) of the first material 21a, this may be within the scope of the present disclosure. For example, the second material 21b may be disposed in each of the plurality of first materials 21a, and in grain orientation growth, the second material 21b may be provided close to a grain boundary GB which is a boundary between the plurality of first materials 21a. The second material 21b according to an embodiment of the present disclosure may be a seed material. For example, the second material 21b may include NaNbO₃. For example, NaNbO₃ may be added to the piezoelectric material composition of Equation 1 by 2 mol % to 4 mol %. For example, the second material 21b may function as a template so that the first material 21a grows in a crystal orientation of the second material 21b, in a sintering process. For example, the first material 21a may be sintered based on a crystal orientation of the second material 21b. Accordingly, crystal orientations of the plurality of first materials 21a may be oriented in the same or substantially the same orientation. The second material 21b according to an embodiment of the present disclosure may be prepared by a method of preparing a seed material described below with reference to FIGS. 5 and 7.

Accordingly, in an embodiment of the present disclosure, because a piezoelectric material composition does not include Pb, a production restriction material may be reduced and replacement of a harmful material may be implemented, and thus, an environment-friendly piezoelectric material composition and a piezoelectric device including the same may be provided.

FIG. 3 illustrates a method of manufacturing a non-templated grain growth (TGG) piezoelectric device according to an embodiment of the present disclosure. This relates to a method of manufacturing the non-TGG piezoelectric material composition described above with reference to FIG. 1 by a press molding process.

With reference to FIG. 3, a method S100 of manufacturing a piezoelectric device according to an embodiment of the present disclosure may include a step S110 of weighing raw materials, a step S120 of mixing the weighed raw materials, a calcination and synthesis step S130 of synthesizing the mixed raw materials, a step S140 of milling a synthesized matrix material, a step S150 of press-molding the matrix material to prepare a molding element, a step S160 of sintering the molding element to prepare a sintered material, and a step S170 of forming an electrode. For example, a method of manufacturing a piezoelectric material composition according to one or more embodiments of the present disclosure may start from mixing raw materials having Equation 1. In the following description, a condition based on the method of manufacturing the piezoelectric material composition may include, for example, a temperature, pressure, and a time, but embodiments of the present disclosure are not limited thereto.

First, the step S110 of weighing the raw material may be a weighing a raw material on the basis of a mole ratio to add an appropriate amount of solvent.

The piezoelectric material composition of the piezoelectric device according to an embodiment of the present disclosure may be expressed as the following Equation 1.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A , \qquad [ Equation 1 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00.

A raw material of a non-TGG piezoelectric material composition satisfying Equation 1 may include sodium carbonate (Na₂CO₃), potassium carbonate (K₂CO₃), niobium oxide (Nb₂O₅), antimony oxide (Sb₂O₃), strontium carbonate (SrCO₃), zirconium oxide (ZrO₂), calcium carbonate (CaCO₃), barium carbonate (BaCO₃), hafnium oxide (HfO₂), titanium oxide (TiO₂), tin oxide (SnO₂), bismuth oxide (Bi₂O₃), silver oxide (Ag₂O), and iron oxide (Fe₂O₃). However, embodiments of the present disclosure are not limited thereto. For example, the raw material may include oxide other than carbonate including a corresponding positive ion (for example, Na⁺, K⁺, Nb⁺⁵, Sb⁺³, Ca⁺², Sr⁺², and Zr⁺⁴). For example, the step S110 of weighing the raw material may be process which weighs the raw material on the basis of a mole ratio of a composition to synthesize, puts the weighed raw material into a nylon jar, and adds an appropriate amount of solvent (for example, ethanol), but embodiments of the present disclosure are not limited thereto.

The matrix material according to an embodiment of the present disclosure may include Fe₂O₃. For example, Fe₂O₃ may be added by 1 mol % or less. For example, Fe₂O₃ may be added by 0.5 mol %. Accordingly, according to an embodiment of the present disclosure, Fe₂O₃ may be added, and thus, the sinterability of a piezoelectric material may more increase.

Subsequently, the step S120 of mixing the raw materials may be mixing and milling the weighed raw material and ethanol by a ball milling process. The weighed raw materials and ethanol may be put into Nalgene bottle along with zirconia ball (for example, vittria stabilized zirconia (YSZ) ball) and ethanol and may be milled. For example, milling may be wet milling, but embodiments of the present disclosure are not limited thereto. For example, a ball milling process may be performed for 12 hours to 36 hours within a range of 100 rpm to 150 rpm, but embodiments of the present disclosure are not limited thereto.

An embodiment of the present disclosure may further include a drying step of separating a powder mixed with the solvent after the mixing step. Here, the drying step may separate and discharge the milled raw material from the ball, and then, may put the mixed raw material into a dish and may dry the mixed raw material at a temperature of 90° C. to 100° C. For example, drying may be performed for 3 hours, but embodiments of the present disclosure are not limited thereto. Accordingly, ethanol mixed with the raw material may be removed.

Subsequently, an embodiment of the present disclosure may include a step S130 of calcining the raw material. The step S130 of calcining the raw material may be phase-synthesizing primarily mixed raw materials. The phase-synthesizing step S130 may finely grind a dried compound with a mortar after mixing is completed, put the grinded compound into an alumina crucible, increase a temperature of the grinded compound up to 400° C. in an electric furnace at a temperature increasing speed of 5° C./min, and maintain the compound at an increased temperature for 30 minutes after a temperature increases. Subsequently, the phase-synthesizing step S130 may be increasing a temperature up to 400° C. from a calcination temperature at a temperature increasing speed of 5° C./min, calcining the compound at the calcination temperature for 3 hours to 6 hours, and cooling or naturally cooling the calcined compound at a room temperature (or a normal temperature). For example, the calcination temperature may be 700° C. to 900° C. and a maintenance time may be 1 hour to 6 hours, but embodiments of the present disclosure are not limited thereto. Accordingly, in an embodiment of the present disclosure, carbonate of the raw material may be removed, and the raw material may uniformly react to form a uniform perovskite phase.

Subsequently, the step S140 of milling the matrix material on which calcination ends may be putting the matrix material into Nalgene bottle along with YSZ ball and a solvent (ethanol) and milling the matrix material by a ball milling process to form small particles, but embodiments of the present disclosure are not limited thereto. A milling process may be performed for 24 hours within a range of 100 rpm to 150 rpm, but embodiments of the present disclosure are not limited thereto.

Moreover, the milling step may further include a drying step of separating a powder mixed with the solvent after the milling step. Here, the drying step may separate and discharge the milled raw material from the ball, and then, may put the milled matrix material into a dish and may dry the milled matrix material at a temperature of 90° C. to 100° C. For example, drying may be performed for 3 hours, but embodiments of the present disclosure are not limited thereto.

According to an embodiment of the present disclosure, the step $140 of milling a calcination-completed matrix material may further include sieving or granulating a material.

The sieving or granulating step may be filtering out dried powders finely grinded by the mortar by a 40-mesh sieve to produce powders including particles having a certain size or less. A powder passing through the 40-mesh sieve may have a size of 400 μm or less, but embodiments of the present disclosure are not limited thereto. For example, the sieving step may be granulating a composition.

Subsequently, the step S150 of molding (or press-molding) a slurry to prepare the molding element may include manufacturing the molding element having a certain volume and shape by the granulated matrix material which is prepared in step S140.

For example, the molding element may be prepared by performing a process which puts the granulated matrix material into a uniaxial press molding mold having a diameter of 16 pi, maintains the granulated matrix material for 10 seconds to 30 seconds with pressure of 100 MPa, and performs uniaxial press molding in a disk shape.

Subsequently, the step S160 of sintering the molding element to prepare the sintered material may be putting the molding element into a furnace, increasing a temperature up to 400° C. from a room temperature (25° C.) at a temperature increasing speed of 5° C./min and then maintaining the molding element at an increased temperature for 30 minutes, increasing a temperature up to 1,090° C. from 400° C. at a temperature increasing speed of 5° C./min and then cooling or naturally cooling the molding element at a room temperature (or a normal temperature), but embodiments of the present disclosure are not limited thereto.

Subsequently, the step S170 of forming the electrode in the sintered material may form the electrode on a first surface of the sintered material of a piezoelectric material, which is prepared in a previous step, and a second surface, which is opposite to the first surface, of the sintered material of the piezoelectric material. For example, the second surface of the sintered material of the piezoelectric material may differ from the first surface, or may be opposite to the first surface. For example, the electrode may include a metal, for example, may be formed by coating metal (for example, silver (Ag)), but embodiments of the present disclosure are not limited thereto and the electrode may be used without being limited to a general electrode. For example, the step S170 of forming the electrode in the sintered material may print the electrode in the sintered material by a screen printing, but embodiments of the present disclosure are not limited thereto. For example, the step S170 of forming the electrode in the sintered material may include forming the electrode in the sintered material, increasing a temperature up to 600° C. from 400° C. at a temperature increasing speed of 5° C./min and then maintaining the sintered material at 600° C. for 10 minutes to 30 minutes, naturally cooling the sintered material at a room temperature, and applying an electric field of 3 kV/mm at a temperature of 20° C. to 40° C. for about 20 minutes to perform a polarization (or poling) process on the electrode, but embodiments of the present disclosure are not limited thereto.

For example, a sintering process, including a step of performing sintering for long time (for example, 10 hours) at a second sintering temperature of 1,090° C. after reaching up to a first sintering temperature of 1,190° C. which is very high, may be complicated in sintering profile and may need the first sintering temperature of 1,190° C. which is high. Comparing with this, a sintering method according to an embodiment of the present disclosure may include a primary sintering process of increasing a temperature up to 400° C. and then maintaining an increased temperature for 30 minutes and a secondary sintering process of increasing a temperature up to 1,090° C. and then maintaining an increased temperature for 3 hours to 6 hours, and thus, a sintering profile may be simple and it may not be required to increase a sintering temperature at a time, based on increasing a temperature up to 1,090° C. after performing sintering at 400° C.

FIG. 4 illustrates a method of manufacturing a non-TGG piezoelectric device according to another embodiment of the present disclosure. This relates to a method of manufacturing the non-TGG piezoelectric material composition described above with reference to FIG. 1 by a tape casting method. The tape casting method may be a method of molding and sintering a material with a sheet having ductility. Therefore, in another embodiment of the present disclosure, a process up to before a step S240 of milling a synthesized matrix material may be performed like an embodiment of the present disclosure described above with reference to FIG. 3. Hereinafter, therefore, a description of the same manufacturing method is omitted, and only a process after the step S240 of milling the synthesized matrix material will be described.

With reference to FIG. 4, a method of manufacturing a piezoelectric device according to another embodiment of the present disclosure may include, after the step S240 of milling a synthesized matrix material, a step S250 of preparing a slurry, a step S260 of preparing a molding element, a step S270 of sintering the molding element to prepare a sintered material, and a step S280 of forming an outer electrode in the sintered material.

First, the step S250 of preparing the slurry may include performing primary slurry milling on a matrix material, performing secondary slurry milling on the matrix material, and performing tape casting on the matrix material.

The step S250 of preparing the slurry may add an appropriate amount of dispersant and solvent to the matrix material having a composition of Equation 1. For example, the solvent may include one or more of ethanol, methanol, isopropanol, methyl ethyl ketone (MEK), toluene, and distilled water, but embodiments of the present disclosure are not limited thereto. By adding an appropriate amount of dispersant and solvent to the matrix material, a slurry where the matrix material is well dispersed in the solvent may be prepared. For example, the step of preparing the slurry may be prepared through a milling step performed twice, but embodiments of the present disclosure are not limited to the number of milling steps.

For example, the primary slurry milling may be performed on the prepared matrix material slurry by putting an appropriate amount of solvent and dispersant into Nalgene bottle along with YSZ ball. Such a primary slurry milling step may be dispersing matrix powders. The primary slurry milling may be ball milling, but embodiments of the present disclosure are not limited thereto. For example, the primary slurry milling may be performed for 12 hours to 72 hours within a range of 100 rpm to 150 rpm, but embodiments of the present disclosure are not limited thereto. For example, the primary slurry milling may be performed for 12 hours in 130 rpm, but embodiments of the present disclosure are not limited thereto. For example, the primary slurry milling may be wet milling, but embodiments of the present disclosure are not limited thereto.

For example, after the primary slurry milling, the secondary slurry milling may be performed by further adding an appropriate amount of binder and plasticizer. The secondary slurry milling may be mixing and dispersing the binder and the plasticizer in the primary slurry. The secondary slurry milling may be ball milling, but embodiments of the present disclosure are not limited thereto. For example, the secondary slurry milling may be performed for 6 hours to 24 hours within a range of 100 rpm to 150 rpm, but embodiments of the present disclosure are not limited thereto. For example, the secondary slurry milling may be wet milling, but embodiments of the present disclosure are not limited thereto.

An embodiment of the present disclosure may further include an aging step and a degassing step of removing an air bubble and a gas after the secondary slurry milling.

The degassing step may be adjusting the slurry to have appropriate viscosity for a molding process and removing an air bubble remaining in the slurry, in a below-described step of molding a piezoelectric material. For example, the degassing step may be adjusted to have a viscosity of 1,000 cPs to 3,000 cPs (centipoise), 1,500 cPs to 2,500 cPs, or 3,000 cPs by a vacuum stirrer at a room temperature, but embodiments of the present disclosure are not limited thereto. For example, the degassing step may be adjusted to have a viscosity of 1,700 cPs to 2,400 cPs, or 2,000 cPs (centipoise) by a vacuum stirrer at a room temperature, but embodiments of the present disclosure are not limited thereto. Accordingly, an air bubble may be removed in the slurry, and a viscosity may be adjusted by volatilizing a solvent.

The aging step may be adjusting a temperature to a room temperature again because the slurry is cooled when a solvent is volatilized in the degassing step. For example, in the aging step, stirring may be performed for a short time at a low speed of about 10 rpm by the stirrer, but embodiments of the present disclosure are not limited thereto. Accordingly, a piezoelectric material having a slurry form may be configured.

Subsequently, a tape casting step may be tape-casting a slurry where the matrix material prepared in a previous step is mixed with a seed material, by a tape casting device (or a blade). For example, in a case where tape casting is performed at 90° C. or more, because a evaporation speed of a solvent is fast, a manufactured sheet may be cracked, or a defect such as a void may occur. Therefore, a temperature condition of each period of the tape casting device may be 30° C. to less than 90° C. For example, the tape casting step may be a process where the degassed secondary slurry is put into a slurry chamber, passes through a doctor blade (or a comma blade) adjusted to a certain height at a certain speed (for example, a speed of 0.5 mm/min), and is molded to a green sheet (or a mold sheet) via a temperature period. The temperature period may include a period of 40° C., 60° C., and 80° C., but embodiments of the present disclosure are not limited thereto.

Additionally, an embodiment of the present disclosure may further include a step S260 of forming an inner electrode. For example, the step S260 of forming the inner electrode may be printing an electrode in the tape-casted green sheet. For example, an inner patterned electrode for manufacturing a multi-layered ceramic application (MLCA) may be printed by a screen printing method. For example, the MLCA may be a multi-layered vibration device. For example, the multi-layered vibration device may include a plurality of vibration devices which are sequentially stacked. Each of the plurality of vibration devices may include a vibration layer including ceramic and an electrode layer which is formed at each of an upper surface and a lower surface of the vibration layer. For example, because each of the plurality of vibration devices is sequentially stacked, an electrode layer may be provided at each of a lowermost surface and an uppermost surface of the multi-layered vibration device, and each of electrode layers may be provided between two adjacent vibration layers of a plurality of vibration layers including ceramic. For example, the other electrode layer (or an electrode layer provided between adjacent vibration layers) except an electrode layer provided at an uppermost surface and an electrode layer provided at a lowermost surface among a plurality of electrode layers may be an inner patterned electrode which is formed by a printing such as screen printing. As another example, in a single-layered ceramic application (SLCA), an inner electrode may not be needed, and thus, a step of printing the inner electrode may be omitted. For example, the SLCA may include one vibration device. For example, one vibration device may include a vibration layer including ceramic and an electrode layer which is formed at each of an upper surface and a lower surface of the vibration layer. For example, in a single-layered ceramic application (SLCA), an inner electrode may not be needed, and thus, a step of printing the inner electrode may be omitted. For example, in the SLCA, an electrode layer may not be provided between vibration layers, and thus, a step of printing the inner electrode may be omitted.

The tape-casted piezoelectric material (or sheet) may be stacked (or laminated), and then, may be pressed for 10 minutes to 30 minutes with pressure of 2,500 psi/cm² to 4,000 psi/cm² at 55° C. to 75° C. For example, the tape-casted piezoelectric material (or sheet) may be stacked, and then, may be pressed for 10 minutes with pressure of 3,000 psi/cm² at 60° C. For example, lamination (or stack) may be stacking prepared green sheets and the green sheets may be stacked with pressure of 100 MPa/cm², but embodiments of the present disclosure are not limited thereto.

A step of molding the tape-casted piezoelectric material may be performed through warm isostatic press (WIP). In the piezoelectric material composition according to an embodiment of the present disclosure, the WIP may be performed in a case where a molding element is prepared based on stack and lamination such as tape casting. For example, a stacked piezoelectric material may be vacuum-packed by the WIP, and then, may be put into water of 60° C. to 65° C. and may be maintained and pressed with pressure of 3,000 psi/cm² or more for 10 minutes, but embodiments of the present disclosure are not limited thereto. The WIP may be thermal isostatic press, but embodiments of the present disclosure are not limited thereto.

The step S260 of molding the slurry may further include a degreasing step. The degreasing step may be removing a solvent or an organic material. The degreasing step may be firing an organic solvent such as a binder, a plasticizer, or a dispersant before sintering a WIP-completed stack mold sheet. The degreasing step may maintain a molding element in a furnace for 24 hours to 72 hours within a temperature range of 250° C. to 600° C., and then, may cool the molding element up to a room temperature. For example, the degreasing step may be increasing a temperature up to 330° C. from a room temperature at a temperature increasing speed of 0.3° C./min and then maintaining an increased temperature for 16 hours, increasing a temperature up to 550° C. from 330° C. at a temperature increasing speed of 0.3° C./min and then maintaining an increased temperature for 12 hours, and naturally cooling the molding element.

Subsequently, the step S270 of sintering the molding element to prepare the sintered material and the step S280 of forming an electrode in the sintered material may be performed like an embodiment of the present disclosure described above with reference to FIG. 3. The step S280 of forming the outer electrode in the sintered material may include a printing an electrode in the tape-casted green sheet.

FIG. 5 illustrates a method of manufacturing a TGG piezoelectric device according to an embodiment of the present disclosure. This illustrates a method of manufacturing the TGG piezoelectric material composition described above with reference to FIG. 2 by a tape casting method.

With reference to FIG. 5, a method S300 of manufacturing a piezoelectric device according to an embodiment of the present disclosure may include a step S310 of preparing a seed material and a matrix material of a piezoelectric material composition, a step S320 of mixing the matrix material with the seed material to prepare a slurry, a step S330 of molding the slurry to prepare a molding element, a step S340 of sintering the molding element to prepare a sintered material, and a step S350 of forming an electrode in a sintered piezoelectric material composition. The piezoelectric material composition may be expressed as the following Equation 2.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

For example, the matrix material may be a material where NaNbO₃ which is a seed is excluded in Equation 2 and may be prepared by a method S10 of preparing a matrix material described below. The seed material may have a NaNbO₃ composition and may have a size of 5 μm or more, but embodiments of the present disclosure are not limited to a size of the seed material. An aspect ratio of the seed may be within a range of 5 to 20 or 10 to 15 and may be prepared by a method S20 of preparing a seed described below. For example, the seed material may be added to the piezoelectric material composition of Equation 1 by 2 mol % to 4 mol %, but embodiments of the present disclosure are not limited thereto. Accordingly, the step S310 of preparing the seed material and the matrix material of the piezoelectric material composition may be completed.

Subsequently, the method 300 may include the step S320 of mixing the matrix material with the seed material to prepare the slurry. The step S320 of mixing the matrix material with the seed material to prepare the slurry may include preparing the slurry including the matrix material and mixing the seed material with the matrix material.

The step of preparing the slurry including the matrix material may add an appropriate amount of dispersant and solvent to the matrix material having a composition of Equation 3. For example, the solvent may include one or more of ethanol, methanol, isopropanol, MEK, toluene, and distilled water, but embodiments of the present disclosure are not limited thereto. By adding an appropriate amount of dispersant and solvent to the matrix material, a slurry where the matrix material is well dispersed in the solvent may be prepared. According to an embodiment of the present disclosure, a dispersant may decrease the viscosity of a slurry including the matrix material and may be used for dispersing the first material 21a and the second material 21b in a solvent. For example, the step of preparing the slurry may be prepared through a milling step performed four times, but embodiments of the present disclosure are not limited to the number of milling steps.

For example, primary slurry milling may be performed by adding an appropriate amount of solvent and dispersant to the prepared matrix material slurry. The primary slurry milling may be dispersing matrix powders. The primary slurry milling may be ball milling, but embodiments of the present disclosure are not limited thereto. For example, the primary slurry milling may be performed for 24 hours to 72 hours within a range of 100 rpm to 150 rpm, but embodiments of the present disclosure are not limited thereto. For example, the primary slurry milling may be performed for 12 hours to 16 hours within a range of 100 rpm to 150 rpm, but embodiments of the present disclosure are not limited thereto. For example, the primary slurry milling may be wet milling, but embodiments of the present disclosure are not limited thereto. For example, the primary slurry milling may be performed for 12 hours to 16 hours within a range of 100 rpm to 150 rpm after matrix powders, a solvent, and a dispersant are put into Nalgene bottle along with nylon or high density polyethylene (HDPE) and a ZrO₂ ball (for example, a YSZ ball), but embodiments of the present disclosure are not limited thereto.

For example, after the primary slurry milling, secondary slurry milling may be performed by further adding an appropriate amount of binder and plasticizer. The secondary slurry milling may be mixing and dispersing the binder and the plasticizer in the primary slurry. The secondary slurry milling may be ball milling, but embodiments of the present disclosure are not limited thereto. For example, the secondary slurry milling may be performed for 6 hours to 24 hours within a range of 100 rpm to 150 rpm, but embodiments of the present disclosure are not limited thereto. For example, the secondary slurry milling may be wet milling, but embodiments of the present disclosure are not limited thereto. For example, after the binder and the plasticizer are added to the primary slurry milling, the secondary slurry milling may be performed for 6 hours to 25 hours within a range of 100 rpm to 150 rpm along with a ZrO₂ ball (for example, a YSZ ball), but embodiments of the present disclosure are not limited thereto.

The binder (or a bonding agent) may provide the stiffness, flexibility, ductility, durability, tenacity, and smoothness of a molding element. The binder may include at least one of PVB resin, PVA, and PEG, but embodiments of the present disclosure are not limited thereto and a binder known to those skilled in the field of piezoelectric material composition may be used.

The plasticizer may be added for providing the elasticity and plastic characteristic of the molding element. The plasticizer may include at least one of phthalate-based plasticizer, adipate-based plasticizer, phophate-based plasticizer, polyether-based plasticizer, and polyester-based plasticizer, and a plasticizer material known to those skilled in the field of piezoelectric material composition may be used.

The step of mixing the seed material with the matrix material may be mixing the seed material with the slurry including the matrix material which is prepared at a previous step and may be performed through tertiary slurry milling and quaternary slurry milling. For example, the tertiary slurry milling may separate and discharge the slurry from the ball, add an NN seed (NaNbO₃) by d mol % on the basis of a ratio of matrix powers included in the discharged slurry, and put the slurry into Nalgene bottle without a ball, and thus, the tertiary slurry milling may be performed for 3 hours to 6 hours within a range of 20 rpm to 30 rpm, but embodiments of the present disclosure are not limited thereto. For example, the milling process may be performed for a short time at a speed which is lower than the primary slurry milling and the secondary slurry milling. For example, the tertiary slurry milling may be performed for 3 hours to 6 hours within a range of 20 rpm to 30 rpm by adding a seed after the ZrO₂ ball is removed, but embodiments of the present disclosure are not limited thereto.

For example, the quaternary slurry milling may be performed after the tertiary slurry milling. The quaternary slurry milling may be performed through planetary milling performed three times for 10 minutes within a range of 500 rpm to 2,000 rpm, but embodiments of the present disclosure are not limited thereto. For example, the quaternary slurry milling may be uniformly dispersing a seed material (for example, an NN seed (NaNbO₃)). Accordingly, a method of manufacturing a piezoelectric material composition according to an embodiment of the present disclosure may mix a seed material with a matrix material so as to be uniformly distributed.

An embodiment of the present disclosure may further include an aging step and a degassing step of removing an air bubble and a gas after the quaternary slurry milling.

The degassing step may be adjusting the slurry to have appropriate viscosity for a molding process and removing an air bubble remaining in the slurry, in a below-described step of molding a piezoelectric material. For example, the degassing step may be adjusted to have a viscosity of 1,000 cPs to 3,000 cPs (centipoise), 1,500 cPs to 2,500 cPs, or 3,000 cPs by a vacuum stirrer at a room temperature, but embodiments of the present disclosure are not limited thereto. For example, the degassing step may be adjusted to have a viscosity of 1,700 cPs to 2,400 cPs, or 2,000 cPs (centipoise) by a vacuum stirrer at a room temperature, but embodiments of the present disclosure are not limited thereto. Accordingly, an air bubble may be removed in the slurry, and a viscosity may be adjusted by volatilizing a solvent.

The aging step may be adjusting a temperature to a room temperature again because the slurry is cooled when a solvent is volatilized in the degassing step. For example, in the aging step, stirring may be performed for a short time at a low speed of about 10 rpm by the stirrer, but embodiments of the present disclosure are not limited thereto. Accordingly, a piezoelectric material having a slurry form may be configured.

Subsequently, a step S103 of molding (or press-molding) a slurry to prepare a molding element may include manufacturing the molding element having a certain volume and shape by a slurry (or a piezoelectric material) where the matrix material and the seed material prepared in the step S102 are mixed with each other.

For example, a step of molding the slurry (or the piezoelectric material) to prepare a molding element may include tape-casting a piezoelectric material, performing primary molding on the tape-casted piezoelectric material, and performing secondary molding on a primarily-molded piezoelectric material.

The tape casting step may be tape-casting a slurry where the matrix material prepared in a previous step is mixed with a seed material, by a tape casting device (or a blade). For example, in a case where tape casting is performed at 90° C. or more, because a evaporation speed of a solvent is fast, a manufactured sheet may be cracked, or a defect such as a void may occur. Therefore, a temperature condition of each period of the tape casting device may be 30° C. to less than 90° C. For example, the tape casting step may be a process where the degassed secondary slurry is put into a slurry chamber, passes through a doctor blade (or a comma blade) adjusted to a certain height at a certain speed (for example, a speed of 0.5 mm/min), and is molded to a green sheet (or a mold sheet) via a temperature period. The temperature period may include a period of 40° C., 60° C., and 80° C., but embodiments of the present disclosure are not limited thereto.

The tape-casted piezoelectric material (or sheet) may be stacked (or laminated), and then, may be pressed for 10 minutes to 30 minutes with pressure of 2,500 psi/cm² to 4,000 psi/cm² at 55° C. to 75° C. For example, the tape-casted piezoelectric material (or sheet) may be stacked, and then, may be pressed for 10 minutes with pressure of 3,000 psi/cm² at 60° C. For example, lamination (or stack) may be stacking prepared green sheets and the green sheets may be stacked with pressure of 100 MPa/cm², but embodiments of the present disclosure are not limited thereto.

A step of performing primary molding on the tape-casted piezoelectric material may be performed through WIP, and a step of performing secondary molding on the tape-casted piezoelectric material may be performed through cold isostatic press (CIP) and may be used for increasing a density of a sintered material in a sintering step described below. In the piezoelectric material composition according to an embodiment of the present disclosure, the WIP may be performed in a case where a molding element is prepared based on stack and lamination such as tape casting. For example, by the WIP, a stacked piezoelectric material may be maintained and pressed for 10 minutes with pressure of 3,000 psi/cm² or more at 60° C., but embodiments of the present disclosure are not limited thereto. The WIP may be thermal isostatic press, but embodiments of the present disclosure are not limited thereto.

The step S330 of molding the piezoelectric material may further include a degreasing step after primary molding. The degreasing step may be firing an organic solvent such as a binder, a plasticizer, or a dispersant before sintering a WIP-completed stack mold sheet. The degreasing step may be removing a solvent or an organic material. The degreasing step may maintain a molding element in a furnace for 24 hours to 72 hours within a temperature range of 250° C. to 60° C., and then, may cool the molding element up to a room temperature. For example, in the degreasing step, a temperature and a maintenance time of the furnace may be set based on the kinds of dispersant, binder, and plasticizer used therein.

The step S330 of molding the piezoelectric material may include performing secondary molding after the degreasing step. For example, the secondary molding step may be performed through CIP. For example, the secondary molding step may be performed at a room temperature and may be maintaining the piezoelectric material for 8 minutes to 12 minutes in 28,000 psi to 30,000 psi, but embodiments of the present disclosure are not limited thereto. For example, the secondary molding step may be performed at a room temperature and may be maintaining the piezoelectric material for 10 minutes in 29,000 psi, but embodiments of the present disclosure are not limited thereto.

Subsequently, the step S340 of sintering the molding element to prepare the sintered material may be performed in one temperature period, and then, may be cooled. For example, a sintering temperature may be within a range of 1,010° C. to 1,110° C., but embodiments of the present disclosure are not limited thereto. For example, a sintering maintenance time may be 2 hours to 8 hours, but embodiments of the present disclosure are not limited thereto.

Subsequently, the step S350 of forming the electrode in the sintered material may form the electrode on a first surface of the sintered material of a piezoelectric material, which is prepared in a previous step, and a second surface, which is opposite to the first surface, the sintered material of the piezoelectric material. For example, the second surface of the sintered material of the piezoelectric material may differ from the first surface, or may be opposite to the first surface of the sintered material of the piezoelectric material. For example, the electrode may include a metal, for example, may be formed by coating metal (for example, Ag), but embodiments of the present disclosure are not limited thereto and the electrode may be used without being limited to a general electrode. For example, the electrode may be formed in the sintered material, a temperature may increase at a temperature increasing speed of 5° C./min, the electrode may be maintained for 10 minutes at 600° C. and then may be naturally cooled at a room temperature, and an electric field of 3 kV/mm may be applied for about 20 minutes at a temperature of 20° C. to 40° C., and thus, a polarization (or poling) process on the electrode. The step S350 of forming the electrode in the sintered material may include a printing an electrode in a tape-casted green sheet and may be the substantially same as the description of FIG. 4.

FIG. 6 illustrates a method of manufacturing a TGG piezoelectric material composition according to an embodiment of the present disclosure. This illustrates a method of manufacturing the matrix material described above with reference to FIG. 5. A method of manufacturing a matrix material of a TGG piezoelectric material composition according to an embodiment of the present disclosure may be performed by the same process as a method of manufacturing the piezoelectric material composition of the non-TGG device described above with reference to FIG. 4. Hereinafter, therefore, the same elements will be briefly described or are omitted.

With reference to FIG. 6, a method of manufacturing a matrix material of a TGG piezoelectric material composition according to an embodiment of the present disclosure may include a step S11 of weighing raw materials, a step S12 of mixing the weighed raw materials, a step S13 of calcining and synthesizing the mixed raw materials, and a step S14 of milling a synthesized matrix material. The step S11 of weighing the raw materials may be performed independently of the manufacturing method, or may be omitted. For example, a method of manufacturing a matrix material according to one or more embodiments of the present disclosure may start from mixing raw materials having Equation 3. In the following description, a condition (for example, a temperature, pressure, and a time) based on the method of manufacturing the piezoelectric material composition may not limit the details of the present disclosure.

First, the method of manufacturing a matrix material of a piezoelectric material composition according to an embodiment of the present disclosure may include the step S11 of weighing the raw materials, the step S12 of mixing the weighed raw materials, the step S13 of calcining the mixed raw materials, and a step S14 of milling a phase-synthesized matrix material.

First, the step S11 of weighing the raw material may be weighing a raw material on the basis of a mole ratio to add an appropriate amount of solvent.

The matrix material according to an embodiment of the present disclosure may be expressed as the following Equation 3.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A , \qquad [ Equation 3 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00. According to an embodiment of the present disclosure, the matrix material satisfying Equation 3 may be (Na,K,Sr,Bi,Ag)(Nb,Sb,Zr)O₃.

A raw material of a matrix material satisfying Equation 3 may include sodium carbonate (Na₂CO₃), potassium carbonate (K₂CO₃), niobium oxide (Nb₂O₅), antimony oxide (Sb₂O₃), strontium carbonate (SrCO₃), zirconium oxide (ZrO₂), calcium carbonate (CaCO₃), barium carbonate (BaCO₃), hafnium oxide (HfO₂), titanium oxide (TiO₂), tin oxide (SnO₂), bismuth oxide (Bi₂O₃), silver oxide (Ag₂O), and iron oxide (Fe₂O₃). However, embodiments of the present disclosure are not limited thereto. For example, the raw material may include oxide other than carbonate including a corresponding positive ion (for example, Na⁺, K⁺, Nb⁺⁵, Sb⁺³, Ca⁺², Sr⁺², and Zr⁺⁴). For example, the step S11 of weighing the raw material may be process which weighs the raw material on the basis of a mole ratio of a composition to synthesize, puts the weighed raw material into a nylon jar, and adds an appropriate amount of solvent (for example, ethanol), but embodiments of the present disclosure are not limited thereto.

The matrix material according to an embodiment of the present disclosure may include Fe₂O₃. For example, Fe₂O₃ may be added by 1 mol % or less. For example, Fe₂O₃ may be added by 0.5 mol %. Accordingly, according to an embodiment of the present disclosure, Fe₂O₃ may be added, and thus, the sinterability of a piezoelectric material may more increase.

Subsequently, the step S12 of mixing the raw materials may be a mixing and milling the weighed raw materials and a solvent (ethanol) by a ball milling process. For example, the ball milling process may put the weighed raw materials into Nalgene bottle along with YSZ ball and a solvent, and then, the ball milling process may be performed for 12 hours to 36 hours within a range of 100 rpm to 150 rpm, but embodiments of the present disclosure are not limited thereto.

An embodiment of the present disclosure may further include a drying step of separating a powder mixed with the solvent after the milling step. Here, the drying step may separate and discharge the milled raw material from the ball, and then, may put the milled matrix material into a dish and may dry the milled matrix material at a temperature of 90° C. to 100° C. For example, drying may be performed for 3 hours, but embodiments of the present disclosure are not limited thereto. Accordingly, ethanol mixed with the raw material may be removed.

Subsequently, an embodiment of the present disclosure may include the step S13 of calcining the raw materials. The step S13 of calcining the raw materials may be phase-synthesizing primarily mixed raw materials. The calcining step S13 may finely grind a dried compound with a mortar after mixing is completed, put the grinded compound into an alumina crucible, increase a temperature of the grinded compound in an electric furnace at a temperature increasing speed of 5° C./min, calcine the compound at 750° C. to 850° C. for 3 hours to 6 hours, and cool or naturally cool the calcined compound at a room temperature (or a normal temperature). For example, the calcination temperature may be 700° C. to 900° C. and a maintenance time may be 1 hour to 6 hours, but embodiments of the present disclosure are not limited thereto. Accordingly, in an embodiment of the present disclosure, carbonate of the raw material may be removed, and the raw material may uniformly react to form a uniform perovskite phase.

Subsequently, the step S140 of milling the matrix material on which calcination ends may be putting the matrix material into Nalgene bottle along with YSZ ball and a solvent (ethanol) and milling the matrix material by a ball milling process to form small particles, but embodiments of the present disclosure are not limited thereto. A milling process may be performed for 24 hours within a range of 100 rpm to 150 rpm, but embodiments of the present disclosure are not limited thereto.

Moreover, the milling step may further include a drying step of separating a powder mixed with the solvent after the milling step. Here, the drying step may put the milled matrix material into a dish and may sufficiently dry the milled matrix material at a temperature of 100° C. For example, drying may be performed for 3 hours, but embodiments of the present disclosure are not limited thereto.

Moreover, according to an embodiment of the present disclosure, the step S14 of milling the phase-synthesized matrix material may further include sieving a material.

The sieving step may be filtering out dried powders finely grinded by the mortar by a 40-mesh sieve to produce powders including particles having a certain size or less. A powder passing through the 40-mesh sieve may have a size of 400 μm or less, but embodiments of the present disclosure are not limited thereto.

FIG. 7 illustrates a method of manufacturing a seed material of a TGG piezoelectric material composition according to an embodiment of the present disclosure. FIG. 7 illustrates a method of manufacturing a seed material in the method of manufacturing the piezoelectric material composition described above with reference to FIG. 5.

With reference to FIG. 7, a method of manufacturing a seed material of a piezoelectric material composition according to an embodiment of the present disclosure may include a step S21 of primarily weighing a seed material, a step S22 of preparing a primary seed, a step S23 of performing secondary weighing, and a step S24 of preparing a secondary seed.

First, the step S21 of primarily weighing the seed material may be weighing a primary seed material on the basis of a mole ratio to add an appropriate amount of solvent.

Here, a mole ratio of a composition to be synthesized in the primary seed may be (Bi_{2.5}Na_{3.5})Nb₅O₁₆. Hereinafter, therefore, the primary seed may be referred to as a “BNN seed”.

For example, in the step S21 of primarily weighing the seed material, Na₂CO₃, Nb₂O₅, BizO₃, and sodium chloride (NaCl) may be weighed based on a mole ratio of a composition which is to be synthesized and may be put into a nylon jar, and then, an appropriate amount of solvent may be added thereto. For example, the solvent may be ethanol, but embodiments of the present disclosure are not limited thereto.

Moreover, in the primary weighing step, a ratio of Na₂CO₃, Nb₂O₅, Bi₂O₃, and NaCl may be adjusted. For example, a ratio of NaCl to oxide including Na₂CO₃, Nb₂O₅, and Bi₂O₃ may be 1:1.5, but embodiments of the present disclosure are not limited thereto.

The step S22 of preparing the primary seed may further include mixing materials which are weighed in a previous step and phase-synthesizing mixed primary seed materials.

For example, the mixed primary seed material may be mixed with a solvent and may be mixed and milled for 12 hours by a ball milling process. Also, the step of mixing the primary seeds may further include a drying step of separating a powder mixed with the solvent after the mixing and milling step. Here, the drying step may put the primarily mixed matrix material into a dish and may sufficiently dry the mixed matrix material at a temperature of 90° C. to 100° C., but embodiments of the present disclosure are not limited thereto. For example, drying may be performed for 3 hours, but embodiments of the present disclosure are not limited thereto.

For example, the phase-synthesizing step may be finely grinding a compound with a mortar after mixing and drying the primary seed material, putting the grinded compound into an alumina crucible, increasing a temperature of the grinded compound in an electric furnace at a temperature increasing speed of 5° C./min, calcining the compound for 6 hours at 1,100° C. to 1,175° C., and cooling or naturally cooling the calcined compound at a room temperature. A calcination-completed BNN seed may have a plate-shaped particle. Here, the step of phase-synthesizing the primary seed material may be referred to as primary calcination. The phase-synthesizing step may be synthesizing BNN seeds which are precursors.

The step S22 of preparing the primary seed may further include cleaning a calcination-completed primary seed.

For example, a step of cleaning the primary seed may clean and filter the primary seed two to ten times by distilled water of 80° C. or more so as to remove NaCl stained on a primary seed powder, but embodiments of the present disclosure are not limited thereto. Drying may be performed for 3 hours in an oven of 90° C. after filtering, but embodiments of the present disclosure are not limited thereto.

Subsequently, the secondary weighing step S23 may be putting an appropriate amount of solvent and a material including Na for substituting the primary seed powder and Bi of the primary seed powder and weighing the solvent and the material on the basis of a mole ratio of a composition.

Here, a mole ratio of a composition of the secondary seed may correspond to NaNbO₃. Hereinafter, therefore, the secondary seed may be referred to as an “NN seed”.

For example, in the secondary weighing step, Na₂CO₃ and NaCl may be weighed based on a mole ratio of a composition which is to be synthesized and may be put into a beaker, and then, an appropriate amount of solvent may be added thereto. For example, the solvent may be ethanol, but embodiments of the present disclosure are not limited thereto.

Subsequently, the step S24 of preparing the secondary seed may include mixing secondarily weighed materials and performing a topochemical reaction.

For example, the step of mixing the secondarily weighed materials may be performed through a stirring process and may be performed for 6 hours with 80 rpm in a state where a magnetic bar is put into a beaker, but embodiments of the present disclosure are not limited thereto.

Moreover, the step of preparing the secondary seed may further include drying a mixed secondarily weighed material. Here, the drying step may put a compound into a dish and may dry the compound for 3 hours to 6 hours at a temperature of 80° C. to 100° C., but embodiments of the present disclosure are not limited thereto.

Moreover, a temperature may increase up to 975° C. from a room temperature at a temperature increasing speed of 10° C./min and then may be maintained for 6 hours, and then a drying-completed mixed powder may be naturally cooled, but embodiments of the present disclosure are not limited thereto.

For example, the step of performing the topochemical reaction may put a dried secondary seed material into a crucible and may be performed for 6 hours at 975° C., but embodiments of the present disclosure are not limited thereto. By performing the topochemical reaction, Bi included in the primary seed may be replaced with Na. here, the step of performing the topochemical reaction may be referred to as secondary calcination. The step S24 of preparing the secondary seed may further include cleaning a secondary seed on which the topochemical reaction is completed.

For example, the step of cleaning the secondary seed may clean and filter the secondary seed two to ten times by distilled water of 80° C. or more so as to remove NaCl stained on an NN seed, but embodiments of the present disclosure are not limited thereto. Remnant ions Na⁺ and Cl⁻ may be removed through filtering, and drying may be performed for 3 hours to 6 hours in an oven of 90° C. to 100° C. after filtering, but embodiments of the present disclosure are not limited thereto.

Moreover, even after cleaning and filtering, acid treatment may be performed with nitric acid several times so as to remove Bi³⁺ ions and Bi₂O₃ remaining in the NN seed, and then, neutralization cleaning may be performed with water. For example, nitric acid may be put into a beaker, the NN seed may be put, and shaking may be performed at every 10 minutes. This may be repeatedly performed for 10 minutes to 2 hours, but embodiments of the present disclosure are not limited thereto. For example, bismuth remnant materials may be ionized by performing acid treatment for 20 minutes two to three times by nitric acid, and then, may be filtered.

Moreover, in order to remove some remnant nitric acid neutralization and Bi³⁺ ions, cleaning may be performed once to twice by distilled water, and then, remnant ions Bi³⁺ may be removed through filtering. Drying may be performed for 3 hours to 6 hours in an oven of 90° C. to 100° C. after filtering.

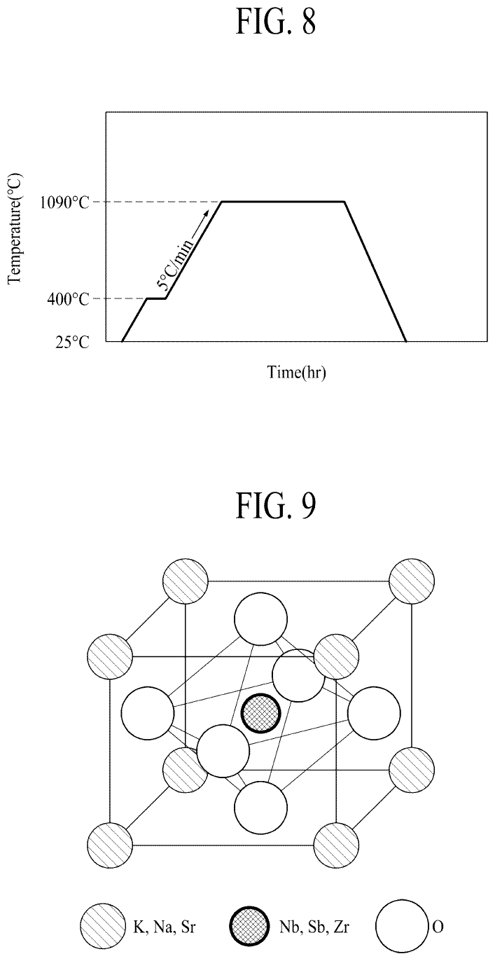

FIG. 8 illustrates a change in a sintering temperature with respect to a time, in a piezoelectric material composition according to an embodiment of the present disclosure. This may be applied to all of a non-TGG process and a TGG process and illustrates in detail a sintering time, a sintering temperature, and a maintenance time in a step of sintering a molding element to prepare a sintered material.

With reference to FIG. 8, a sintered material according to an embodiment of the present disclosure may be prepared through a process of putting a molding element into a furnace, increasing a temperature up to 400° C. from a room temperature (25° C.) at a temperature increasing speed of 5° C./min and then maintaining the molding element at an increased temperature for 30 minutes, increasing a temperature up to 1,090° C. from 400° C. at a temperature increasing speed of 5° C./min and then cooling or naturally cooling the molding element at a room temperature (or a normal temperature).

For example, in a case which puts a molding element into a furnace, increases a temperature of the furnace up to 1,190° C. from a room temperature (25° C.), cools the molding element up to 1,190° C., and sinters the cooled molding element, a cooling process may be added, and thus, a sintering process may be complicated, a sintering time may increase, and a high sintering temperature may be needed.

In an embodiment of the present disclosure, as described above, a sintering temperature may progressively increase and an appropriate maintenance time of each period may be set, and thus, a sintering process may be simplified, a sintering time may be reduced, and a yield rate may be enhanced.

FIG. 9 illustrates a crystal structure of a TGG piezoelectric material according to an embodiment of the present disclosure:

With reference to FIG. 9, a piezoelectric material based on a composition of Equation 2 according to the present disclosure may have a structure of ABX₃. Here, A may be a first positive ion, B may be a second positive ion, and X may be a negative ion which is bonded thereto. The first positive ion may be kalium (K), sodium (Na⁺), strontium (Sr⁺²), bismuth (Bi⁺³), or silver (Ag⁺), the second positive ion may be niobium (Nb⁺⁵), antimony (Sb⁺³), or a zirconium (Zr⁺⁴), and the negative ion may be oxygen (O⁻²). The first positive ion and the negative ion may configure a cube-octahedral structure of AX₁₂, and the second positive ion may be BX₆ and may have a structure bonded in an octahedral structure.

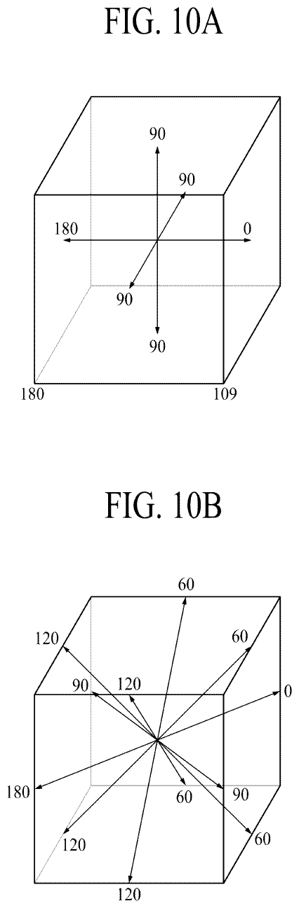

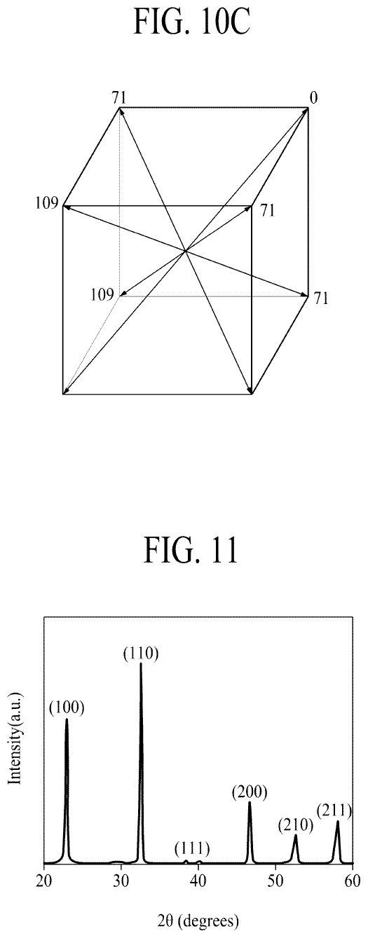

FIGS. 10A to 10C illustrate a tetragonal (T), orthorhombic (O), and rhombohedral (R) crystallographic direction of orientation of a TGG piezoelectric material composition according to an embodiment of the present disclosure.

With reference to FIGS. 10A to 10C, a piezoelectric characteristic of a piezoelectric material composition according to the present disclosure may increase as the number of crystallographic directions of orientations of self-polarization increases. An orthorhombic structure may have six crystallographic directions of orientations, a tetragonal structure may have twelve crystallographic directions of orientations, and a rhombohedral structure may have eight crystallographic directions of orientations. Optimization of a piezoelectric material composition where a tetragonal-orthorhombic-rhombohedral (R-O-T) crystal structure is provided together may be needed for increasing a piezoelectric characteristic.

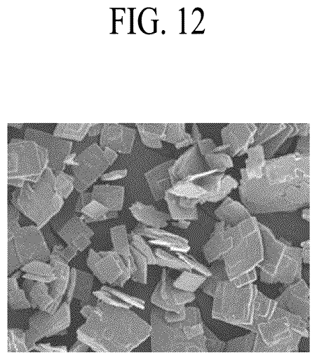

FIG. 11 illustrates an X-ray diffractometer (XRD) measurement value of a seed manufactured by the manufacturing method of FIG. 7. FIG. 12 illustrates a scanning electron microscope (SEM) image of a seed manufactured by the manufacturing method of FIG. 7.

With reference to FIGS. 11 and 12, it may be seen that a seed according to an embodiment of the present disclosure is synthesized in a perovskite structure and has a plate-shaped particle. Also, it may be seen that a size of the seed is 5 μm or more. For example, a seed material according to an embodiment of the present disclosure may have a NaNbO₃ composition.

Therefore, according to an embodiment of the present disclosure, it may be seen that a grain growth of a NaNbO₃ seed is performed in a (110) orientation and a (100) orientation, and the NaNbO₃ seed has a plate-shaped particle and has a particle size of 5 μm or more.

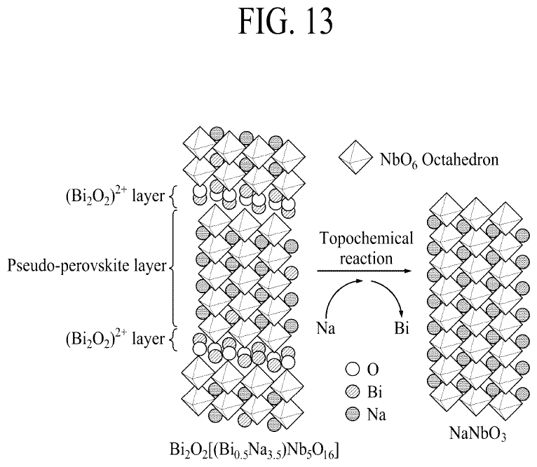

FIG. 13 illustrates a grain variation occurring in preparing a secondary seed of FIG. 7. A crystal structure having a composition of Bi₂O₂[(Bi_{0.5}Na_{3.5})Nb₅O₁₆] illustrated in a left region of FIG. 13 shows a primary seed and may be referred to as a BNN seed. Subsequently, a crystal structure having a composition of NaNbO₃ illustrated in a right region of FIG. 13 shows a secondary seed and may be referred to as an NN seed.

With reference to FIG. 13, the crystal structure of the primary seed having a composition of Bi₂O₂[(Bi_{0.5}Na0.5)Nb₅O₁₆] may be a structure where a layer where an NbO₆ octahedron and Na and Bi are provided between NbO₆ octahedrons are provided from an upper portion, a (Bi₂O₂)²⁺ layer, a pseudo-perovskite layer, and a layer where a (Bi₂O₂)²⁺ layer, an NbO₆ octahedron, and Na and Bi are provided between NbO₆ octahedrons are repeated. Subsequently, a crystal structure of the secondary seed having a composition of NaNbO₃ may have a structure which is surrounded by the Na with an NbO₆ octahedron therebetween.

For example, the primary seed may be changed to the secondary seed by a topochemical reaction in the step of preparing the secondary seed. Here, the topochemical reaction may denote a chemical reaction where a direction of orientation of a mother grain and a grain direction of orientation of a product has different relationships in direction of orientation but a shape of a crystal particle is maintained, in a solid-phase chemical reaction.

Therefore, as shown in FIG. 13, in a process of substituting a Bi element of the primary seed into an Na element, all of a layer where an NbO₆ octahedron and Na and Bi are provided between NbO₆ octahedrons are provided, a (Bi₂O₂)²⁺ layer, and a pseudo-perovskite layer, and a layer where a (Bi₂O₂)²⁺ layer may be changed to a single structure having a composition of NaNbO₃.

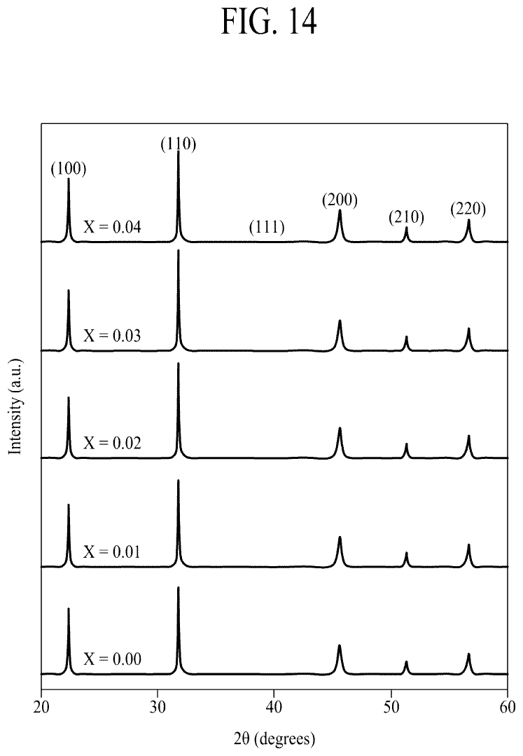

FIG. 14 is a graph showing an X-ray diffraction pattern with respect to a BAZ content of a non-TGG composition according to an embodiment of the present disclosure. In FIG. 14, the X axis represents a 2θ (degrees) value of X-ray diffraction, and the ordinate axis represents relative intensity.

The inventors have measured an X-ray diffraction pattern with respect to a variation of x in Equation 1 of the non-TGG composition described above with reference to FIG. 1, so as to analyze an X-ray diffraction pattern based on a BAZ ((BiAg)ZrO₃) content. A composition of the non-TGG piezoelectric material composition may be 0.96(Na_{0.5}K_{0.5})(Nb_{0.93}Sb_{0.07})O₃-(0.04-x)BaZrO₃-x(Bi_{0.5}Ag_{0.5})ZrO₃+0.5 mol % Fe₂O₃, and a sample of a piezoelectric material composition has been prepared through sintering performed for 6 hours at 1,090° C. The sample of the piezoelectric material composition has been prepared by a non-TGG process using the tape casting method described above with reference to FIG. 4.

The non-TGG piezoelectric material composition according to an embodiment of the present disclosure may be configured where T is Ba, a is 0.50, b is 0.93, c is 0.50, and d is 0.50, in Equation 1 described above with reference to FIG. 1. In the piezoelectric material composition according to an embodiment of the present disclosure, a BAZ content (a value of x in Equation 3) may be set to each of 0.00, 0.01, 0.02, 0.03, and 0.04.

With reference to FIG. 14, in the non-TGG piezoelectric material composition according to an embodiment of the present disclosure, when BAZ contents (or values of x in Equation 1) are 0.00, 0.01, 0.02, 0.03, and 0.04, it may be confirmed that grain growth is performed in a (100) orientation and a (110) orientation.

Moreover, when BAZ contents (or values of x in Equation 3) are 0.00, 0.01, 0.02, 0.03, and 0.04, it may be confirmed that the piezoelectric material composition has a pure perovskite structure and a secondary phase and an unreacted phase are not observed. Accordingly, it may be confirmed that the piezoelectric material composition is smoothly sintered.

A Lotgering factor of the piezoelectric material composition according to an embodiment of the present disclosure represents a high value of 97% or more in all samples. The Lotgering factor represents the degree of orientation of a sample, and when the Lotgering factor is 100%, it may be considered that orientation is completely performed. Accordingly, it may be seen that an orientation of a composition according to an embodiment of the present disclosure is smoothly performed.

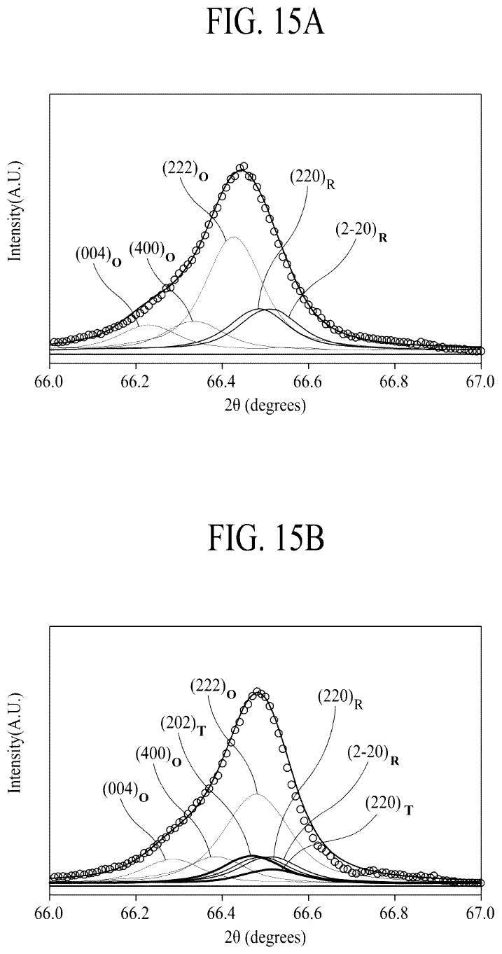

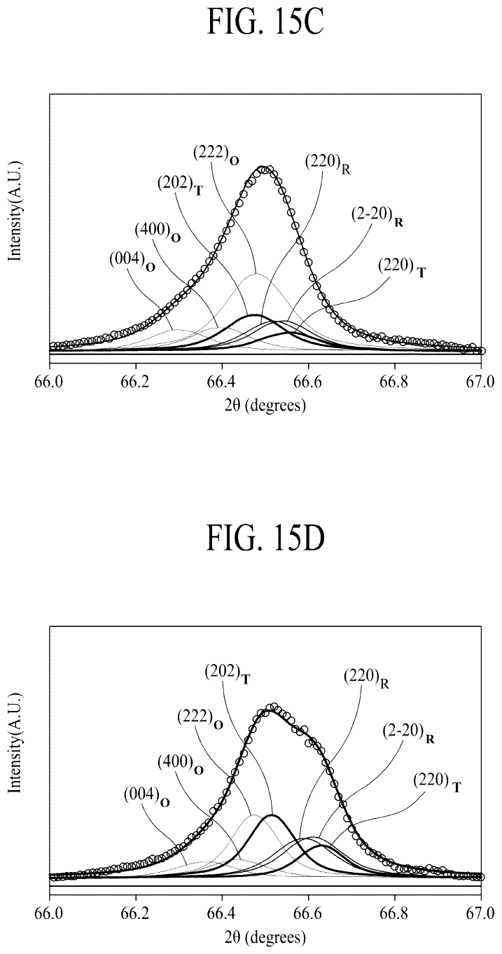

FIGS. 15A to 15E are graphs showing an X-ray diffraction pattern in about 66 degrees with respect to a BAZ content of a non-TGG composition according to an embodiment of the present disclosure. FIGS. 15A to 15E are graphs showing an X-ray diffraction pattern with respect to about 66 degrees in each of samples manufactured by the same method as the non-TGG composition sample according to an embodiment of the present disclosure, and an XRD peak of 66 degrees obtained through low-speed scanning has been more specified by a Voigt function, so as to identify a crystal structure of a sample.

With reference to FIG. 15A, an XRD pattern of a piezoelectric device composition where x is 0.0 represents rhombohedral (220)_{R} and (2-20)_{R} reflection and orthorhombic (004)+, (400)_{O}, and (222)_{O} reflection. Therefore, a combination structure of R-O 2 phases may be confirmed based on an XRD pattern of a piezoelectric device composition where x is 0.0.

With reference to FIGS. 15B to 15D, an XRD pattern of a piezoelectric device composition where x is each of 0.01, 0.02, and 0.03 represents rhombohedral (220))_{R} and (2-20)_{R} reflection and orthorhombic (004)_{O}, (400)_{O}, and (222)_{O} reflection. Also, an XRD pattern of a piezoelectric device composition where x is each of 0.01, 0.02, and 0.03 represents tetragonal (202)T and (220)T reflection. Therefore, a combination structure of R-O-T 3 phases may be confirmed based on an XRD pattern of a piezoelectric device composition where x is 0.01.

With reference to FIG. 15E, an XRD pattern of a piezoelectric device composition where x is 0.04 represents rhombohedral (220)_{R} and (2-20)_{R} reflection and tetragonal (202)T and (220)T reflection. Therefore, a combination structure of R-T 2 phases may be confirmed based on an XRD pattern of a piezoelectric device composition where x is 0.04.

Therefore, in the non-TGG composition according to an embodiment of the present disclosure, it may be seen that a crystal structure is changed from R-O to R-O-T and R-T as a BAZ content increases.

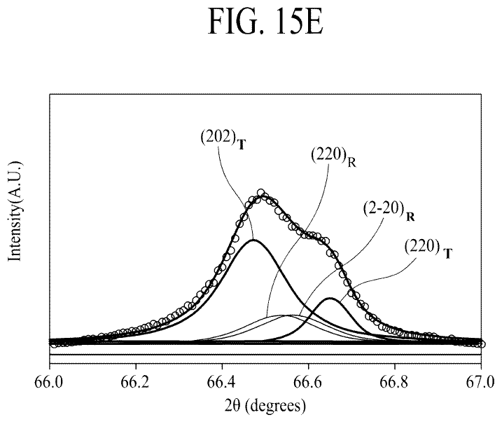

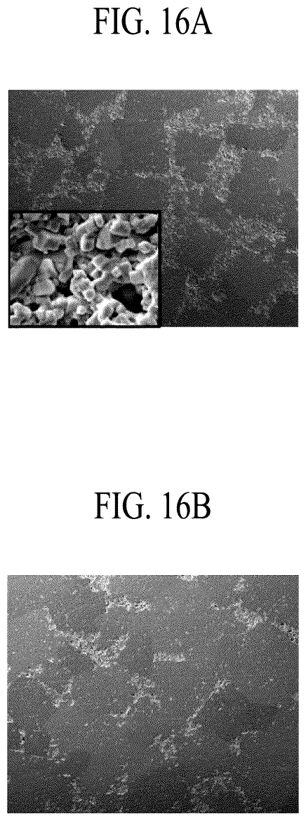

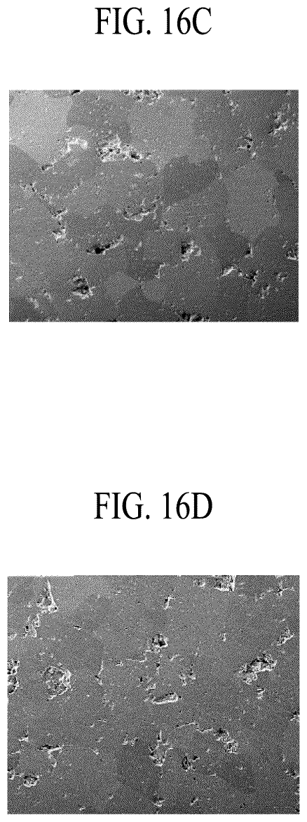

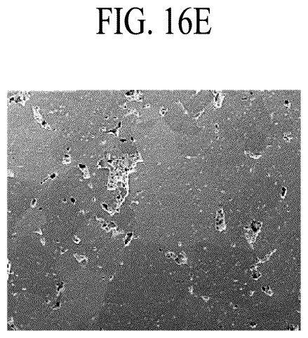

FIGS. 16A to 16E illustrate an SEM image with respect to a BAZ content of a non-TGG composition according to an embodiment of the present disclosure. In FIGS. 16A to 16E, a composition of each sample based on a change in BAZ content of a non-TGG composition has been prepared by the same method as the non-TGG composition sample of FIG. 14. In FIGS. 16A to 16E, values of x are 0.00, 0.01, 0.02, 0.03, and 0.04, respectively.

With reference to FIGS. 16A to 16E, all samples have a dense microstructure. Accordingly, it may be seen that sintering is smoothly performed at 1,090° C.

With reference to FIGS. 16A to 16E, it has been measured that a piezoelectric composition where values of x are 0.0 and 0.01 includes large particles and small particles, an average size of the large particles is about 25 μm, and an average size of the small particles is about 1.0 μm. With reference to FIG. 16A, in a piezoelectric composition, it may be seen that small grains having a size of 1 μm to 2 μm and large grains having a size of 20 μm to 30 μm are provided together and distributed. With reference to FIG. 16B, in a piezoelectric composition, it may be seen that some small grains having a size of 1 μm to 2 μm are provided and large grains having a size of 20 μm to 30 μm are distributed. With reference to FIGS. 16C to 16E, it has been observed that a piezoelectric composition where values of x are 0.02, 0.03, and 0.04 includes large grains. An average grain size has been observed to be 25 μm. Accordingly, in FIGS. 16C to 16E, it may be seen that a size of each grain is hardly changed.

Therefore, in an embodiment of the present disclosure, it may be confirmed that a grain size of NK(NS)-BZ ceramic increases as BAZ is added.

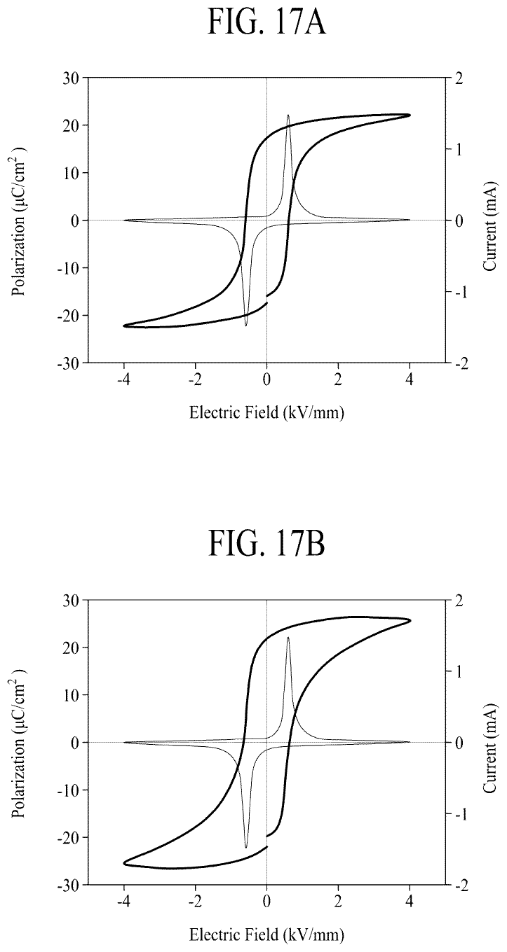

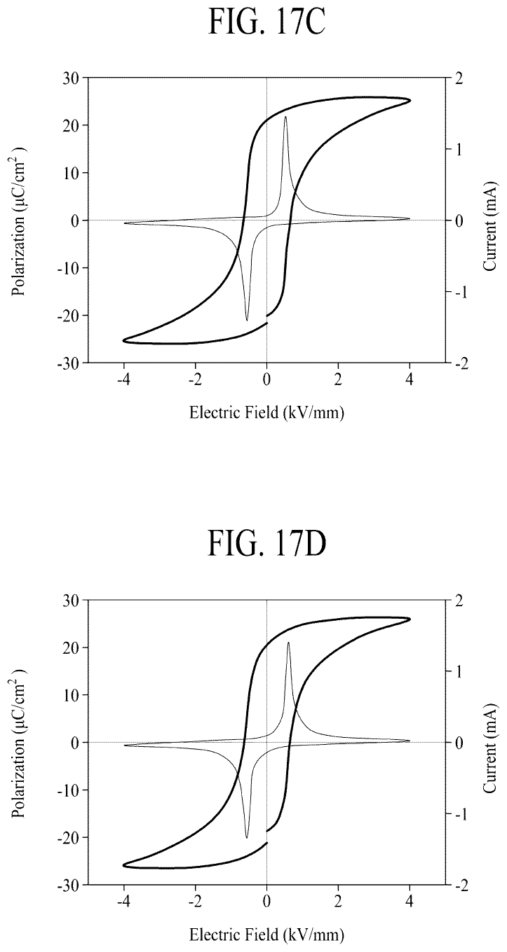

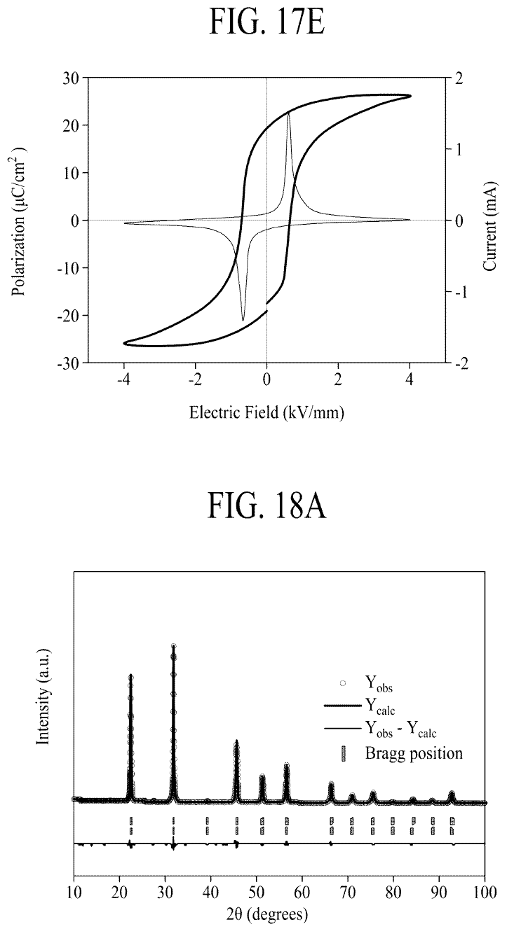

FIGS. 17A to 17E illustrate polarization versus electric field (P-E) and current versus electric field (I-E) of a non-TGG composition according to an embodiment of the present disclosure. In FIGS. 17A to 17E, a red solid line represents a hysteresis curve of polarization versus electric field (P-E) with respect to a BAZ content of a non-TGG composition according to an embodiment of the present disclosure. In FIGS. 17A to 17E, a thin solid line represents current versus electric field (I-E) (red) with respect to the BAZ content of the non-TGG composition according to an embodiment of the present disclosure. In FIGS. 17A to 17E, a composition of each sample based on a change in BAZ content of a composition has been prepared by the same method as the non-TGG composition sample of FIG. 14. In FIGS. 17A to 17E, values of x are 0.0, 0.01, 0.02, 0.03, and 0.04, respectively.

With reference to FIGS. 17A to 17E, a piezoelectric material composition based on a BAZ content represents a conventional P-E hysteresis curve of a ferroelectric material. In an I-E graph of the piezoelectric material composition based on the BAZ content, two peaks have been observed because of domain switching based on application of an electric field. The I-E curve may be observed in a ferroelectric material.

Therefore, it may be confirmed that the non-TGG composition according to an embodiment of the present disclosure has a ferroelectric characteristic.

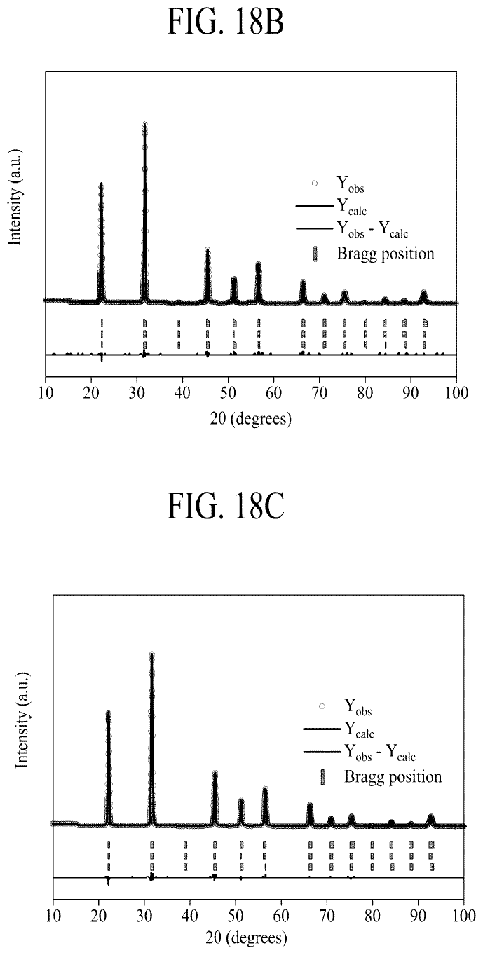

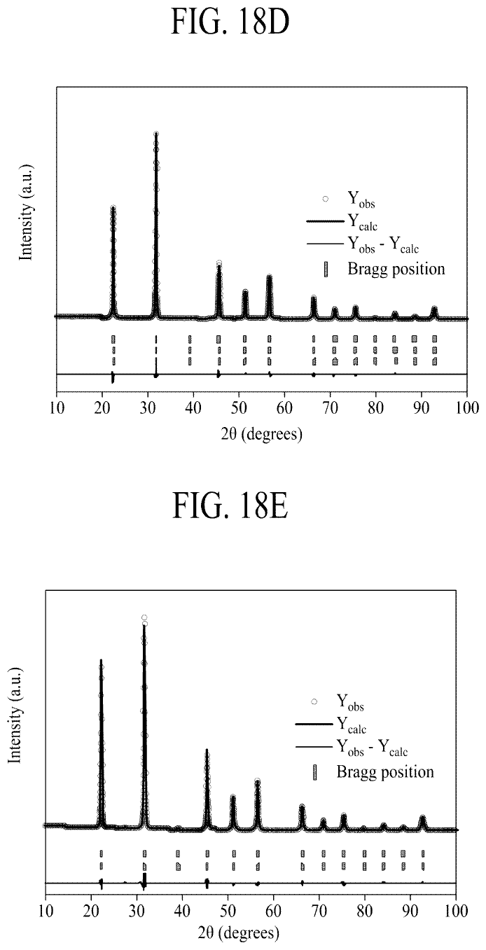

FIGS. 18A to 18E are graphs showing an X-ray diffraction pattern with respect to a BAZ content of a non-TGG composition according to an embodiment of the present disclosure. This is data for checking a volume fraction of rhombohedral, orthorhombic, and tetragonal with respect to a BAZ content of a non-TGG composition. In FIGS. 18A to 18E, intensity (a.u.) of the Y axis is a numerical value expressed as a relative value with respect to a maximum value of an X-ray diffraction pattern. In FIGS. 18A to 18E, Yobs represents an X-ray diffractometer (XRD) measurement value, Yobs-Ycalc represents an error between the XRD measurement value and an XRD analysis calculation value, and a Bragg position represents a refractive index.

The inventors have performed the precise analysis of an X-ray diffraction pattern based on each BAZ content, for optimization of a process. In FIGS. 18A to 18E, samples for analyzing an X-ray diffraction pattern based on each BAZ content have been prepared like FIG. 17. For example, samples for analyzing an X-ray diffraction pattern based on each BAZ content have been prepared based on a non-TGG piezoelectric material composition. For example, in order to check a crystal structure of a matrix composition, a seed (NaNbO₃) is not added. A sample has been prepared where a BAZ content is 0.00 in FIG. 18A, a BAZ content is 0.01 in FIG. 18B, a BAZ content is 0.02 in FIG. 18C, a BAZ content is 0.03 in FIG. 18D, and a BAZ content is 0.04 in FIG. 18E.

With reference to FIG. 18A, when a BAZ content is 0.00, it has been measured that a volume fraction of rhombohedral is 30.09% and a volume fraction of orthorhombic is 69.91%. Therefore, when a BAZ content is 0.00, it may be confirmed that a tetragonal phase is not formed. For example, when a BAZ content is 0.00, it may be seen that a sample has a structure, where rhombohedral and orthorhombic are provided together, or a combination structure of R-O 2 phases.

With reference to FIG. 18B, when a BAZ content is 0.01, it has been measured that a volume fraction of rhombohedral is 29.22%, a volume fraction of orthorhombic is 58.16%, and a volume fraction of tetragonal is 12.62%. For example, when the BAZ content increases, it may be seen that a ratio of a tetragonal appears. For example, when the BAZ content is 0.01, it may be seen that rhombohedral, orthorhombic, and tetragonal are provided together or a combination structure of R-O-T 3 phases is provided.

With reference to FIG. 18C, when a BAZ content is 0.02, it has been measured that a volume fraction of rhombohedral is 29.57%, a volume fraction of orthorhombic is 51.16%, and a volume fraction of tetragonal is 19.27%. Therefore, when the BAZ content is 0.02, it may be confirmed that a volume fraction of each of rhombohedral and orthorhombic is about 80%, and a volume fraction of tetragonal is about 20%. For example, when the BAZ content increases, it may be seen that a ratio of a tetragonal increases. For example, when the BAZ content is 0.02, it may be seen that rhombohedral, orthorhombic, and tetragonal are provided together or a combination structure of R-O-T 3 phases is provided.

With reference to FIG. 18D, when a BAZ content is 0.03, it has been measured that a volume fraction of rhombohedral is 31.90%, a volume fraction of orthorhombic is 35.01%, and a volume fraction of tetragonal is 33.09%. Therefore, when the BAZ content is 0.03, it may be confirmed that a volume fraction of each of rhombohedral, orthorhombic, and tetragonal is measured to be similar within a range of about 31% to about 36%. For example, when the BAZ content is 0.03, it may be seen that a ratio of three phases of rhombohedral, orthorhombic, and tetragonal is about 3:3:3. For example, when the BAZ content increases, it may be seen that a ratio of a tetragonal phase increases and a ratio of an orthorhombic phase decreases. For example, when the BAZ content is 0.03, it may be seen that rhombohedral, orthorhombic, and tetragonal are provided together or a combination structure of R-O-T 3 phases is provided.

With reference to FIG. 18E, when a BAZ content is 0.04, it has been measured that a volume fraction of rhombohedral is 30.18% and a volume fraction of tetragonal is 69.82%. Therefore, when the BAZ content is 0.04, it may be confirmed that phase transition to orthorhombic is omitted and a rhombohedral phase and a tetragonal phase are provided together. For example, when the BAZ content is 0.04, it may be seen that rhombohedral and tetragonal are provided together or a combination structure of R-T 2 phases is provided.

In the piezoelectric material composition according to an embodiment of the present disclosure, as a BAZ content increases, a volume fraction of a tetragonal phase may increase, and a volume fraction of an orthorhombic phase may decrease. In the piezoelectric material composition according to an embodiment of the present disclosure, it may be seen that a volume fraction of a rhombohedral phase is hardly changed as a BAZ content increases.

When a BAZ content is 0.00, the piezoelectric material composition according to an embodiment of the present disclosure may have a structure where rhombohedral and orthorhombic are provided together, and when the BAZ content is 0.04, the piezoelectric material composition according to an embodiment of the present disclosure may have a structure where a rhombohedral phase and a tetragonal phase are provided together. Therefore, when a BAZ content of the piezoelectric material composition according to an embodiment of the present disclosure is within a range of 0.01 to 0.03, it may be seen that the piezoelectric material composition has a structure of three phases of R-O-T. Accordingly, when the BAZ content of the piezoelectric material composition according to an embodiment of the present disclosure is within a range of 0.02 to 0.03, it may be seen that the piezoelectric material composition has a structure where a volume fraction of each of three phases of R-O-T is optimal.

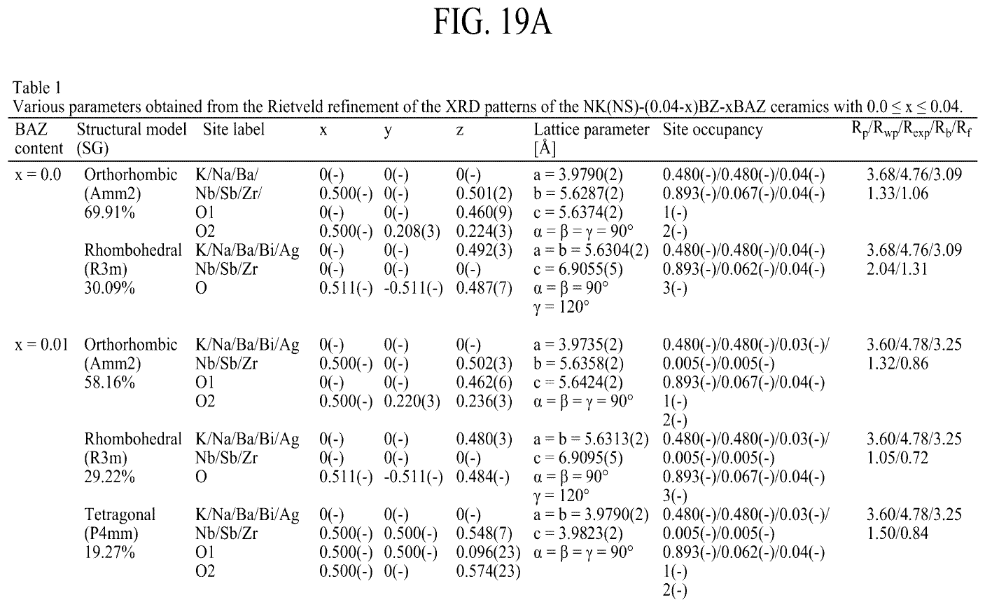

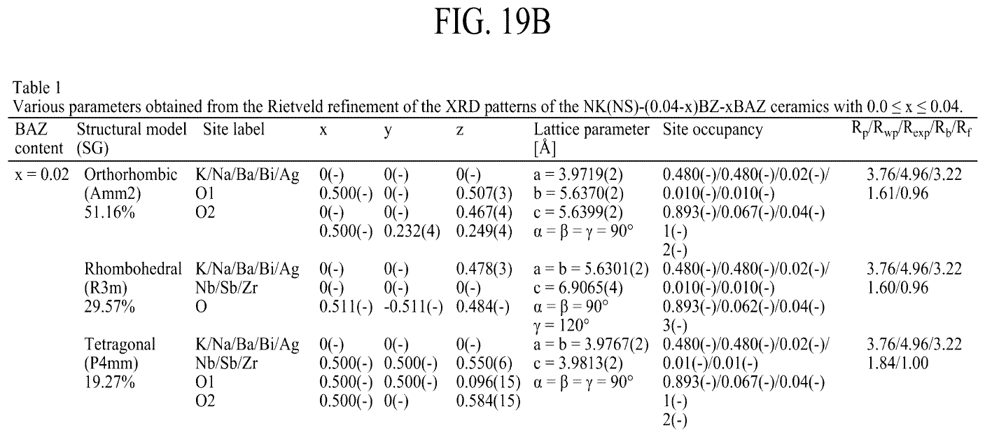

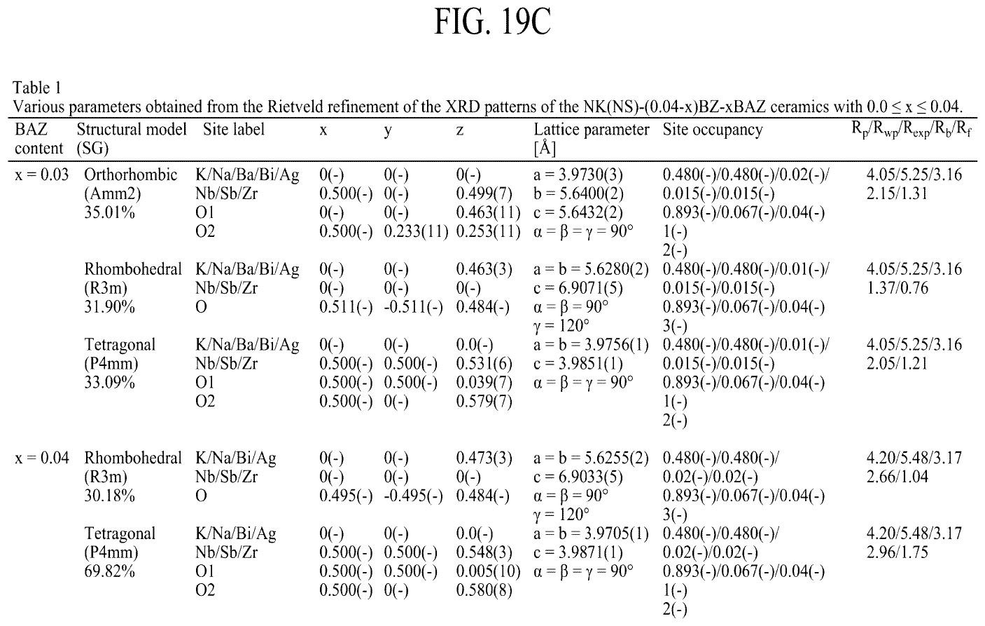

FIGS. 19A to 19C are Rietveld refinement result tables of non-TGG KNNS-BZ-BAZ ceramic according to an embodiment of the present disclosure.

With reference to FIGS. 19A to 19C, a structure model (or a space group SG) represents a fraction and a crystal structure model for analyzing a structure, an R phase has been analyzed to be R3m SG, and a T phase has been analyzed to be P4 mm SG.

A site label and x, y, and z positions represent an element name and x, y, and z positions of atoms arranged in an A-site and a B-site in a ABO₃ perovskite unit cell.

A lattice parameter represents a, b, and c lattice constants of a unit cell obtained as a Rietveld analysis result.

Site occupancy represents a fraction where the atoms arranged in the A-site and the B-site in the ABO₃ perovskite unit cell occupy each site.

In an R parameters, the R value may be a criterion representing the degree to which an actually measured XRD pattern matches a Rietveld analyzed pattern. Here, a profile R-factor (unimportant) (RP) representing the degree to which a shape of the actually measured XRD pattern matches a shape of the Rietveld analyzed pattern.

A weighted profiled R-factor (valuable) (R_{WP}) may be a most important value and may represent a weight of an R_{P} value. For example, the R_{WP} value may be a parameter which is most important in evaluating a Rietveld analysis confidence level. For example, when the R_{WP} value is 10% or more, it may be difficult to use the R_{WP} value as data, and when the R_{WP} value is less than 10%, the R_{WP} value may be used as data. For example, when the R_{WP} value is less than 5%, the R_{WP} value may denote that analysis data has certain reliability, and when the R_{WP} value is less than 3%, the R_{WP} value may denote that the analysis data has high reliability.

An expected weighted profile R-factor (R_{EXP}) may represent the degree to which the actually measured XRD pattern matches a pattern of a background except a Rietveld analyzed pattern peak. A Bragg R-factor (R_{b}) may represent the degree to which a structure model of the Rietveld analyzed pattern satisfies Bragg's raw. A crystallographic R-factor (R_{f}) may represent the degree to which a crystal structure of the Rietveld analyzed pattern matches an analyzed structure model.

Therefore, it may be seen that the inventors have performed Rietveld analysis, and a volume fraction of each of rhombohedral, orthorhombic, and tetragonal based on a BAZ content of a non-TGG composition including no NN seed may be confirmed.

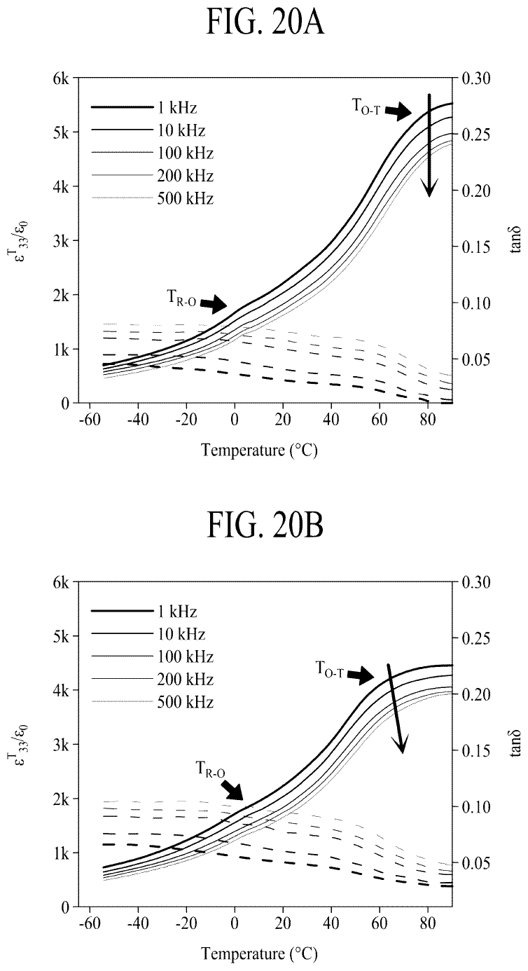

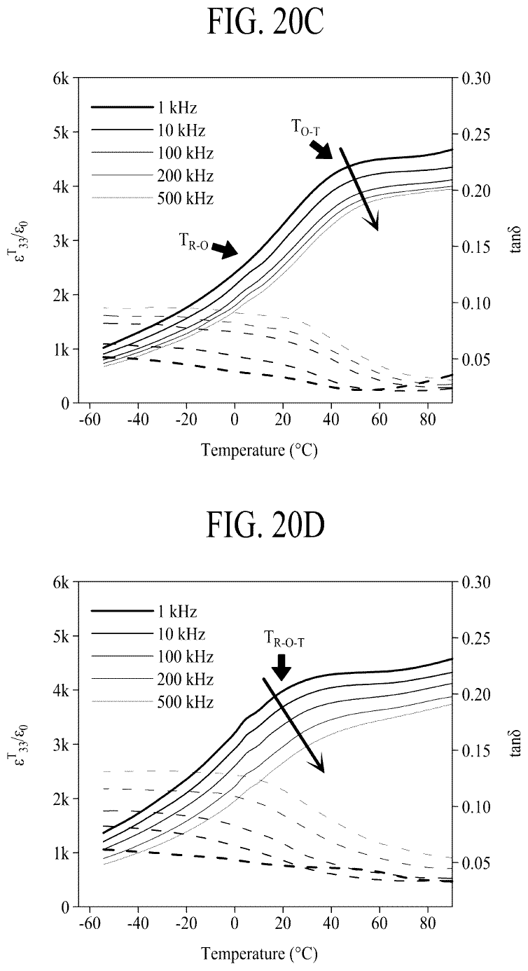

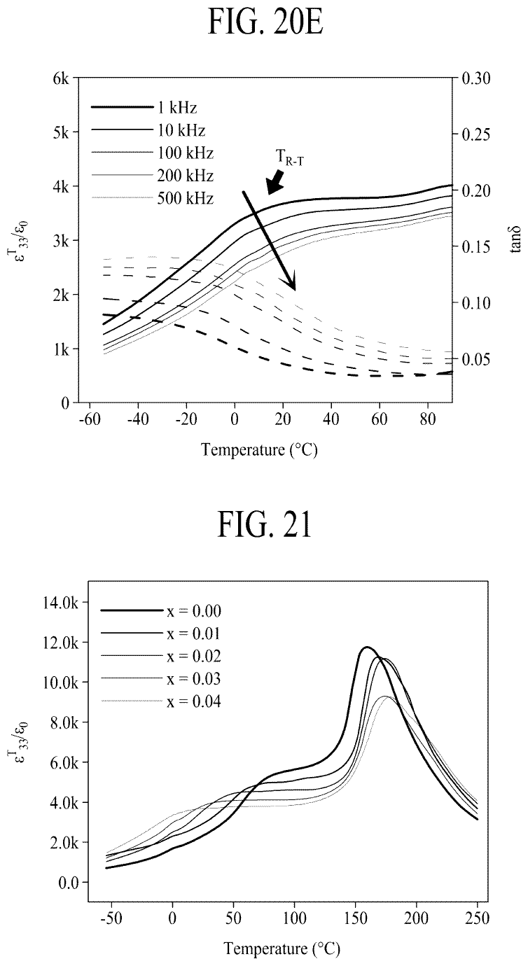

FIGS. 20A to 20E are temperature versus dielectric constant graphs in different frequencies with respect to a BAZ content of a non-TGG composition according to an embodiment of the present disclosure. FIG. 21 is a temperature versus dielectric constant graph with respect to a BAZ content of a non-TGG composition according to an embodiment of the present disclosure. Measurement has been performed under a condition where a temperature is −60° C. to 90° C. In FIGS. 20A to 20E and 21, a composition of each sample based on a variation of a BAZ content of a composition has been prepared by the same method as the non-TGG composition sample, and values of x are 0.00, 0.01, 0.02, 0.03, and 0.04, respectively. Measurement has been performed under a condition where a temperature of a frequency is −60° C. to 250° C. In FIGS. 20A to 20E, a solid line represents a temperature versus a dielectric constant ε^{T}₃₃/ε₀ in different frequencies with respect to a BAZ content of a TGG composition according to an embodiment of the present disclosure, and a dotted line represents a temperature versus a loss factor tan δ.

With reference to FIGS. 20A to 20E, as a content of x increases, it may be seen that a loss factor increases approximately, a T_{O-T} dielectric peak decreases to a low temperature, and a T_{R-O} dielectric peak hardly moves or increases to a very similar temperature. Here, the T_{O-T} dielectric peak may be a phase transition temperature where an orthorhombic (O) phase and a tetragonal (T) phase transit, and the T_{R-O} dielectric peak may be a phase transition temperature where a rhombohedral (R) phase and an orthorhombic (O) phase transit. Accordingly, as a content of x increases, it may be seen that the frequency dependence of the T_{O-T} dielectric peak increases.

With reference to FIG. 21, as a content of x increases, it may be seen that T_{C} approximately moves to a high temperature. T_{C} may be a Curie temperature which is a temperature where a piezoelectric characteristic is removed. Accordingly, as a content of x increases, it may be seen that the Curie temperature increases.

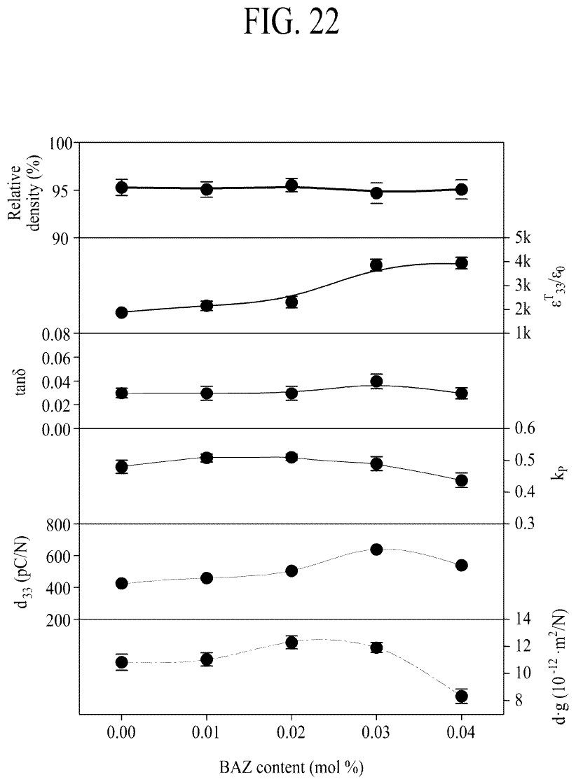

FIG. 22 is a graph showing a relative density (%), a dielectric constant ε^{T}₃₃/ε₀, a loss factor tan δ, a piezoelectric charge constant d₃₃, an electromechanical coupling factor k^{ρ}, and an energy harvesting performance index with respect to a BAZ content of a non-TGG composition according to an embodiment of the present disclosure. In FIG. 22, a composition of each sample based on a variation of a BAZ content of a composition has been prepared by the same method as the non-TGG composition sample, and values of x are 0.00, 0.01, 0.02, 0.03, and 0.04, respectively.

With reference to FIG. 22, a relative density (%) according to an embodiment of the present disclosure represents a value within a range of 94% to 97% in samples where BAZ contents are 0.00, 0.01, 0.02, 0.03, and 0.04. Accordingly, it may be seen that a significant variation based on an increase in BAZ content is not observed.

A dielectric constant ε^{T}₃₃/ε₀ has increased as a BAZ content is 0.00, 0.01, and 0.02. Subsequently, when a BAZ content is 0.03, the BAZ content has increased rapidly compared to a case where a BAZ content is 0.02, and a sample where a BAZ content is 0.04 has a dielectric constant similar to a sample where a BAZ content is 0.03. A dielectric constant ε^{T}₃₃/ε₀ has increased up to 3,964 from 1,895 as a BAZ content is 0.00 to 0.04. Accordingly, when a BAZ content is 0.03 and 0.04, it may be confirmed that a dielectric constant is good.

A loss factor tan δ has a value between 0.02 to 0.05 in a sample where a BAZ content is 0.00, 0.01, 0.02, 0.03, and 0.04. A loss factor tan δ has a similar value in a case where a BAZ content is 0.00 to 0.02 and a loss factor tan δ has slightly increased in a case where a BAZ content is 0.03, but in a case where a BAZ content is 0.04, a loss factor tan δ has decreased again. Accordingly, it may be confirmed that a BAZ content does not largely affect a loss factor tan δ.

An electromechanical coupling factor kρ has a value between 0.40 to 0.55 in samples where BAZ contents are 0.00, 0.01, 0.02, 0.03, and 0.04. Comparing with a case where a BAZ content is 0.00, an electromechanical coupling factor kρ has slightly increased in a case where a BAZ content is 0.01 and 0.02, and as a BAZ content increases to 0.03 and 0.04, an electromechanical coupling factor kρ has slightly decreased. In a case where a BAZ content is 0.01, it may be confirmed that an electromechanical coupling factor kρ has a highest value of 0.51.

In samples where BAZ contents are 0.00, 0.01, 0.02, 0.03, and 0.04, a piezoelectric charge constant d₃₃ has a value within a range of 400 pC/N to 650 pC/N. Comparing with a case where a BAZ content is 0, a piezoelectric charge constant d₃₃ has slightly increased in a case where a BAZ content is 0.01 and 0.02. In a case where a BAZ content is 0.03, it may be confirmed that a piezoelectric charge constant d₃₃ has a highest value of 640 pC/N. However, as a BAZ content increases from 0.03 to 0.04, a piezoelectric charge constant d₃₃ has decreased again. Accordingly, in an embodiment of the present disclosure, when a BAZ content is 0.03, a piezoelectric charge constant d₃₃ is high, and thus, it may be confirmed that a piezoelectric characteristic is good.

In a case where a BAZ content is 0.00 and a case where a BAZ content is 0.01, an energy harvesting performance index (d·g(10⁻¹²·m²/N)) has similar values. In a case where a BAZ content is 0.02, an energy harvesting performance index has a highest value of 12.3 d·g(10⁻¹²·m²/N). However, as a BAZ content increases to 0.03 and 0.04, an energy harvesting performance index has decreased again. In a case where a BAZ content is 0.04, the energy harvesting performance index has a value of 9.0 or less. For example, as a numerical value increases, the energy harvesting performance index has a large output compared to an energy input. Accordingly, in an embodiment of the present disclosure, when a BAZ content is 0.02, it may be seen that an energy harvesting performance index have a highest value and a piezoelectric characteristic is good.

According to an embodiment of the present disclosure, the inventors have analyzed a relative density (%), a dielectric constant ε^{T}₃₃/ε₀, a loss factor tan δ, a piezoelectric charge constant d₃₃, an electromechanical coupling factor k_{ρ}, and an energy harvesting performance index of a piezoelectric material composition with respect to a BAZ content, and thus, have calculated an optimal condition of a BAZ content. For example, an optimal condition of a BAZ content may be 0.02 or 0.03.

Therefore, according to an embodiment of the present disclosure, a piezoelectric material composition may not include Pb and may have a high piezoelectric characteristic.

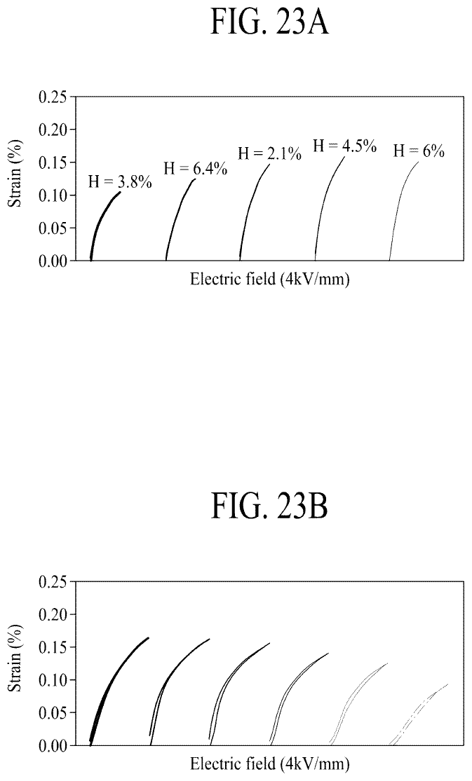

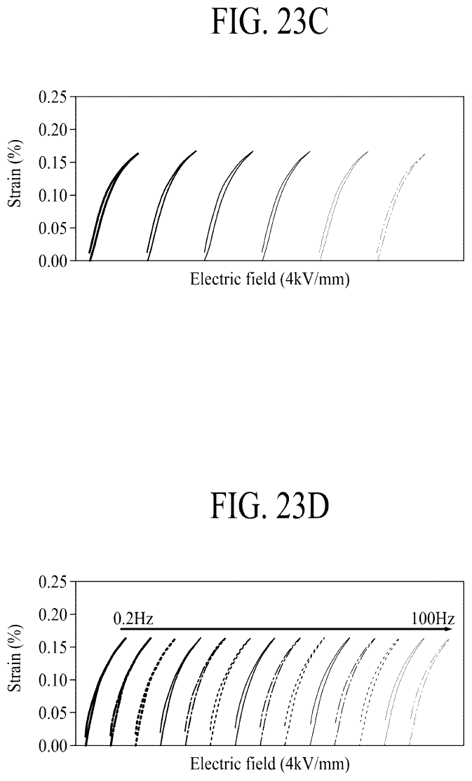

FIGS. 23A to 23D illustrate a piezoelectric characteristic when an electric field is applied to a non-TGG composition according to an embodiment of the present disclosure.

FIG. 23A shows a unipolar strain when an electric field of 4 kV/mm is applied to a sample based on a BAZ content of a non-TGG composition. For example, the unipolar strain denotes a strain when only a positive (+) voltage signal or a negative (−) voltage signal is applied to a piezoelectric material. For example, a case, where the positive (+) voltage signal and the negative (−) voltage signal are applied to the piezoelectric material, may denote a bipolar strain. In a direction from the left of FIG. 23A to the right thereof, a value of x represents a unipolar strain in each of 0.00, 0.01, 0.02, 0.03, and 0.04.

FIG. 23B shows a unipolar strain with respect to a temperature when an electric field of 4 kV/mm is applied to a sample where a BAZ content of a non-TGG composition is 0.03. In a direction from the left of FIG. 23B to the right thereof, a value of x represents a unipolar strain in each of a room temperature, 50° C., 75° C., 100° C., 125° C., and 150° C. FIG. 23C shows a unipolar strain with respect to the number of cycles (100 to 106 cycles) when an electric field of 4 kV/mm is applied to a sample where a BAZ content of a non-TGG composition is 0.03. In a direction from the left of FIG. 23C to the right thereof, a value of x represents a unipolar strain in each of 10⁰, 10¹, 10², 10³, 10⁴, 10⁵, and 10⁶.

FIG. 23D shows a unipolar strain with respect to a frequency when an electric field of 4 kV/mm is applied to a sample where a BAZ content of a non-TGG composition is 0.03.

With reference to FIG. 23A, it may be seen that a unipolar strain when an electric field of 4 kV/mm is applied to a sample based on a BAZ content of a non-TGG composition is 0.16% and highest in a sample where a BAZ content is 0.03.

In FIG. 23A, H may denote hysteresis and may be one of performance indicators of an actuator, and the actuator may be more precisely driven as an H value is reduced. With reference to FIG. 23A, in a sample where a BAZ content is 0.02, it may be seen that an H value is 2.1% and lowest.

With reference to FIG. 23B, it may be seen that a unipolar strain with respect to a temperature when an electric field of 4 kV/mm is applied to a sample where a BAZ content of a non-TGG composition is 0.03 represents a strain of 0.16% in a room temperature RT, and a strain is maintained up to 0.13% in about 125° C. Also, it may be seen that a unipolar strain decreases to 0.10% or less in about 150° C. or more.

With reference to FIG. 23C, it may be seen that a unipolar strain, which is based on the number of cycles (100 to 106 cycles) when an electric field of 4 kV/mm is applied to a sample where a BAZ content of a non-TGG composition is 0.03, is not reduced even when driving is performed based on an input signal of 1 kV/mm up to 100 to 106 cycles.

For example, cycling has been performed with 1 kV/mm, and after cycling, strain evaluation has been performed with 4 kV/mm. For example, the inventors have evaluated a unipolar strain when an electric field of 4 kV/mm after 1 kV/mm is applied in 100 cycle, have evaluated a unipolar strain when an electric field of 4 kV/mm after 1 kV/mm is applied in 101 cycle, have evaluated a unipolar strain when an electric field of 4 kV/mm after 1 kV/mm is applied in 102 cycle, and have evaluated a unipolar strain when an electric field of 4 kV/mm after 1 kV/mm is applied in 103 cycle. Also, the inventors have evaluated a unipolar strain when an electric field of 4 kV/mm after 1 kV/mm is applied in 10⁴ cycle, the inventors have evaluated a unipolar strain when an electric field of 4 kV/mm after 1 kV/mm is applied in 105 cycle, and the inventors have evaluated a unipolar strain when an electric field of 4 kV/mm after 1 kV/mm is applied in 106 cycle.

With reference to FIG. 23D, it may be seen that a unipolar strain with respect to a frequency when an electric field of 4 kV/mm is applied to a sample where a BAZ content of a non-TGG composition is 0.03 represents a strain of 0.16% in a room temperature RT is hardly changed in a frequency range of 0.2 Hz to 100 Hz.

Therefore, according to an embodiment of the present disclosure, when a BAZ content of a non-TGG composition is 0.03, it may be confirmed that a piezoelectric characteristic is good.

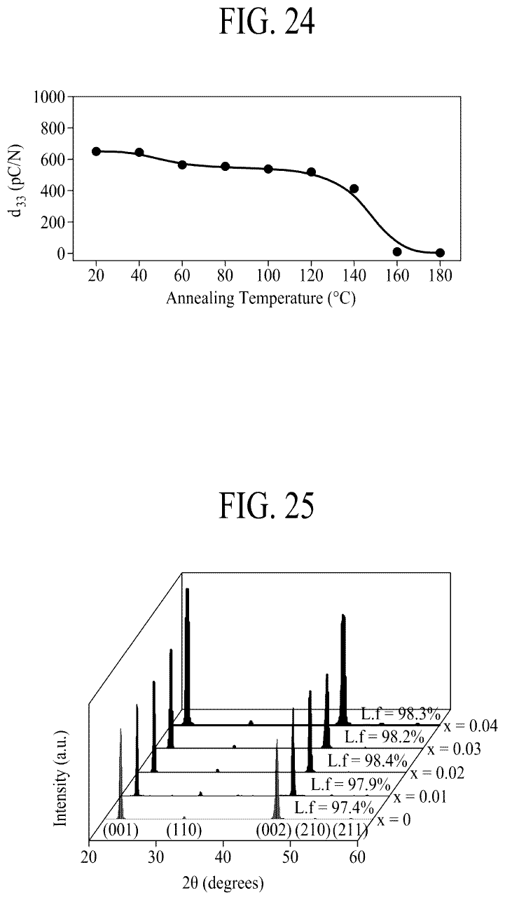

FIG. 24 is a graph showing a piezoelectric charge constant d₃₃ with respect to a variation of an annealing temperature of a non-TGG composition according to an embodiment of the present disclosure.

The inventors have measured a piezoelectric charge constant d₃₃ of a piezoelectric material composition based on an annealing temperature, so as to optimize a non-TGG process. Samples for preparing the piezoelectric charge constant d₃₃ of the piezoelectric material composition based on the annealing temperature have been prepared to have the same composition as FIG. 14. Here, a BAZ content may be 0.03.

With reference to FIG. 24, according to an embodiment of the present disclosure, a piezoelectric charge constant d₃₃ has been measured to be about 640 pC/N in an annealing temperature of 20° C. and 40° C. According to an embodiment of the present disclosure, as the annealing temperature increases to 60° C., 80° C., and 100° C., the piezoelectric charge constant d₃₃ has been slightly reduced. When the annealing temperature is 120° C. or more, the piezoelectric charge constant d₃₃ is 520 pC/N and has decreased up to about 81%.

According to an embodiment of the present disclosure, the reliability of a piezoelectric material composition may be maintained under a condition where an annealing temperature of the piezoelectric material composition is less than 100° C., and the piezoelectric material composition may have a highest piezoelectric characteristic and a high piezoelectric charge constant d₃₃ within a range of 20° C. and 40° C.

FIG. 25 is a graph showing an X-ray diffraction pattern with respect to a BAZ content according to an embodiment of the present disclosure. FIG. 25 is a graph showing an X-ray diffraction pattern with respect to a BAZ content of a TGG piezoelectric material according to an embodiment of the present disclosure. In FIG. 25, the X axis represents a 20 value of X-ray diffraction, and the ordinate axis represents relative intensity.

The inventors have measured an X-ray diffraction pattern with respect to a variation of x in Equation 2 described above with reference to FIG. 2, so as to analyze an X-ray diffraction pattern based on a BAZ ((BiAg)ZrO₃) content. A composition of the non-TGG piezoelectric material composition may be 0.96(Na_{0.5}K_{0.5})(Nb_{0.93}Sb_{0.07})O₃-(0.04-x)BaZrO₃-x(Bi_{0.5}Ag_{0.5})ZrO₃+0.5 mol % Fe₂O₃+3 mol % NaNbO₃, and a sample of a piezoelectric material composition has been prepared through sintering performed for 6 hours at 1,090° C. The piezoelectric material composition according to an embodiment of the present disclosure may be configured where T is Ba, a is 0.50, b is 0.93, c is 0.50, d is 0.50, and e is 3.00 in Equation 2 described above with reference to FIG. 2. In the piezoelectric material composition according to an embodiment of the present disclosure, a BAZ content (or a value of x in Equation 2) may be set to each of 0.00, 0.01, 0.02, 0.03, and 0.04. A seed material has used NaNbO₃ of 3 mol %.

With reference to FIG. 25, in the non-TGG piezoelectric material composition according to an embodiment of the present disclosure, when BAZ contents (or values of x in Equation 1) are 0.00, 0.01, 0.02, 0.03, and 0.04, it may be confirmed that a grain growth orientation of a TGG piezoelectric material composition according to an embodiment of the present disclosure is oriented in a (001) orientation in the most of all samples. In a grain growth orientation of a piezoelectric material composition according to an embodiment of the present disclosure, it may be seen that a diffraction surface in a (110) orientation is not observed in all samples.

Therefore, in an embodiment of the present disclosure, it may be seen that a sample, where NaNbO₃ seeds of 3 mol % are mixed and oriented, is oriented and sintered in a (001) orientation without forming a secondary phase in all samples regardless of a BAZ content.

A Lotgering factor of the piezoelectric material composition according to an embodiment of the present disclosure represents a high value of 97% or more in all samples. The Lotgering factor represents the degree of orientation of a sample, and when the Lotgering factor is 100%, it may be considered that orientation is completely performed. For example, the Lotgering factor L_{f(%)} may be expressed as the following Formula 1.

$${L}_{f} ( \% ) = \frac{p - {p}_{0}}{1 - {p}_{0}} \qquad [ Formula 1 ]$$

In Formula 2, p may denote the degree of orientation calculated by Formula 1, and p₀ may denote a fraction of I₀₀₁ in a piezoelectric material composition which is randomly oriented or has substantially the same composition. The degree of orientation p may be calculated as the following Formula 2.

$$p = \frac{{ΣΙ}_{001}}{{ΣΙ}_{001} + {ΣΙ}_{non - 001}} \qquad [ Formula 2 ]$$

In Formula 2, I₍₀₀₁₎ may denote a diffraction peak such as (001) and (002) expressed as (001), and Iₙₒₙ₋₍₀₀₁₎ may denote a diffraction peak such as (110), (111), (210), and (211), which are not expressed as (001).

According to an embodiment of the present disclosure, Lotgering factors of samples where BAZ contents are 0.00, 0.01, 0.02, 0.03, and 0.04 have been measured to be 97.4%, 97.9%, 98.4%, 98.2%, and 98.3%. According to an embodiment of the present disclosure, as a BAZ content increases to 0.00, 0.01, and 0.02, it may be seen that a Lotgering factor increases and a Lotgering factor decreases after 0.03. Therefore, when a BAZ content is 0.02, the inventors have confirmed that the degree of orientation of a sample is best. Accordingly, according to an embodiment of the present disclosure, when x has a value of 0.015 to 0.025 in Formula 1, the inventors have confirmed that the degree of orientation of a sample is best.

According to an embodiment of the present disclosure, it may be confirmed that a TGG piezoelectric material composition is oriented and grown in a (001) orientation when BAZ contents (or values of x in Equation 2) are 0.00, 0.01, 0.02, 0.03, and 0.04, and a Lotgering factor is 97% or more. Also, it may be seen that the piezoelectric material composition has a perovskite structure and a secondary phase and an unreacted phase are not observed.

FIG. 26 illustrates a TEM image of a TGG composition according to an embodiment of the present disclosure.

The inventors have prepared a sample where a value of x is 0.02 in Equation 2 described above with reference to FIG. 2, so as to analyze a TEM image of a TGG composition. A composition of the piezoelectric material composition may be 0.96(Na_{0.5}K_{0.5})(Nb_{0.93}Sb_{0.07})O₃-(0.04-x)BaZrO₃-x(Bi_{0.5}Ag_{0.5})ZrO₃+0.5 mol % Fe₂O₃+3 mol % NaNbO₃, and a sample of a piezoelectric material composition has been prepared through sintering performed for 6 hours at 1,090° C. The piezoelectric material composition may be configured where T is Ba, a is 0.50, b is 0.93, c is 0.50, d is 0.50, and e is 3.00 in Equation 2 described above with reference to FIG. 2.

With reference to FIG. 26, as a result obtained by measuring a domain of a sample where a value of x is 0.02, based on TEM, a domain having a size of about 1 nm to about 2 nm has been observed.

FIGS. 27A and 27B illustrate an electron backscatter diffraction (EBSD) image of each of a TGG composition and a non-TGG composition according to an embodiment of the present disclosure. FIG. 27A shows an electron backscatter diffraction (EBSD) image of a non-TGG composition according to an embodiment of the present disclosure, and FIG. 27B shows an EBSD image of a TGG composition according to an embodiment of the present disclosure.

The inventors have prepared samples where values of x are 0.02 in Equation 1 described above with reference to FIG. 1 and Equation 2 described above with reference to FIG. 2, so as to analyze the EBSD image of each of the non-TGG composition and the TGG composition.

For example, a composition of a sample of the non-TGG composition may be 0.96(Na_{0.5}K_{0.5})(Nb_{0.93}Sb_{0.07})O₃-(0.04-x)BaZrO₃-x(Bi_{0.5}Ag_{0.5})ZrO₃+0.5 mol % Fe₂O₃, and a sample has been prepared through sintering performed for 6 hours at 1,090° C. For example, in the sample of the non-TGG composition, it has been prepared that T is Ba, a is 0.50, b is 0.93, c is 0.50, and d is 0.50.

For example, a composition of a sample of the TGG composition for EBSD measurement may be 0.96(Na_{0.5}K_{0.5})(Nb_{0.93}Sb_{0.07})O₃-(0.04-x)BaZrO₃-x(Bi_{0.5}Ag_{0.5})ZrO₃+0.5 mol % Fe₂O₃+3 mol % NaNbO₃, and a sample has been prepared through sintering performed for 6 hours at 1,090° C. For example, in the sample of the TGG composition, it has been prepared that T is Ba, a is 0.50, b is 0.93, c is 0.50, d is 0.50, and e is 3.00.

With reference to FIG. 27A, as a result of EBSD analysis, it has been confirmed that a sample of a non-TGG composition has a random grain growth orientation.

With reference to FIG. 27B, as a result of EBSD analysis, it has been confirmed that a sample of a TGG composition is aligned in a (001) orientation.

Accordingly, in an embodiment of the present disclosure, as a seed (NaNbO₃) is provided, it has been confirmed that a grain is oriented in a (001) orientation in sintering.

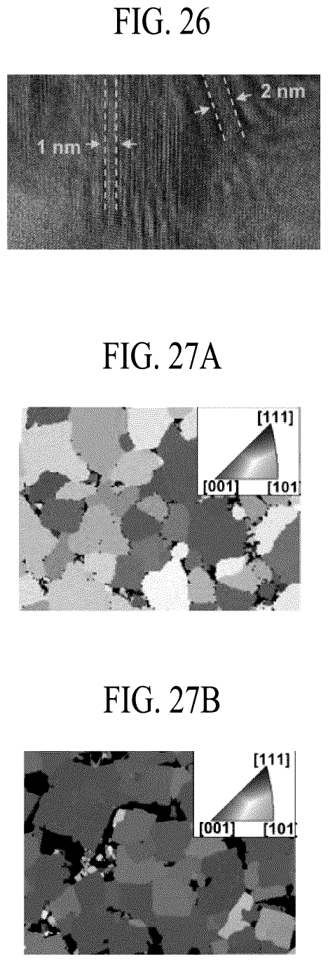

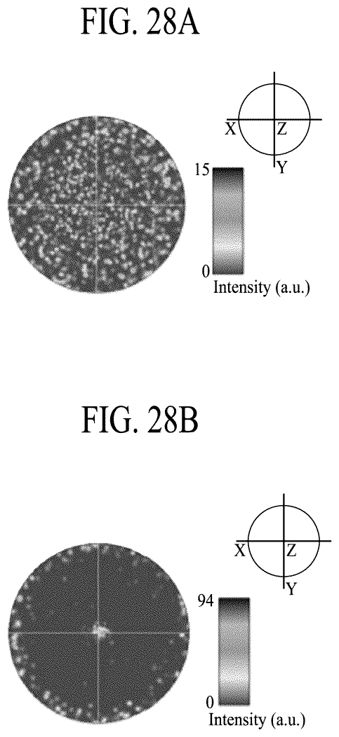

FIGS. 28A and 28B illustrate a pole figure in a {110} orientation of each of a TGG composition and a non-TGG composition according to an embodiment of the present disclosure. In FIGS. 28A and 28B, samples of a non-TGG composition and a TGG composition have been prepared like FIGS. 27A and 27B. A value of x of each sample has been set to 0.02.

With reference to FIG. 28A, as a result of pole figure analysis in a (001) orientation, in a non-TGG composition sample, it has been confirmed that stereographic projection on diffraction intensity is performed in a random orientation.

With reference to FIG. 28B, as a result of pole figure analysis in a (001) orientation, in a TGG composition sample, it has been confirmed that stereographic projection on diffraction intensity is performed in a (001) orientation.

Accordingly, in an embodiment of the present disclosure, as a seed (NaNbO₃) is provided, it has been confirmed that a grain is oriented in a (001) orientation in sintering.

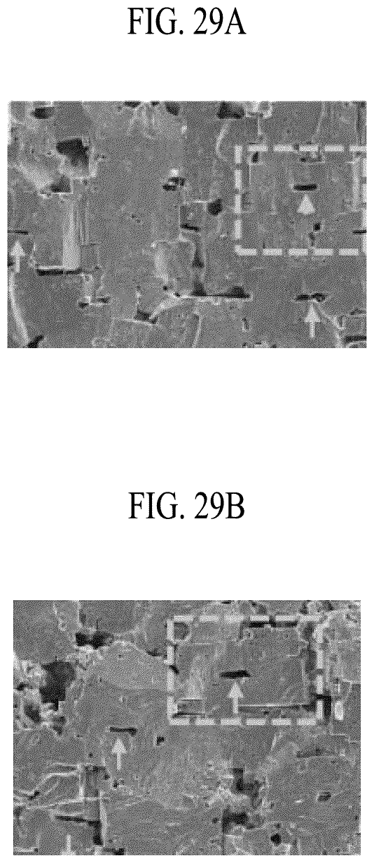

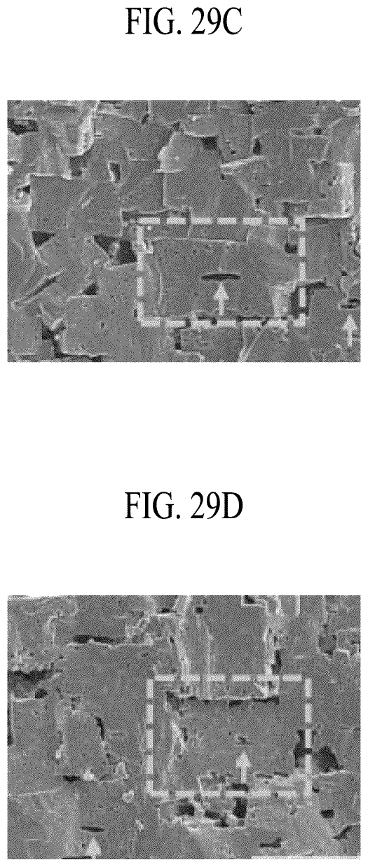

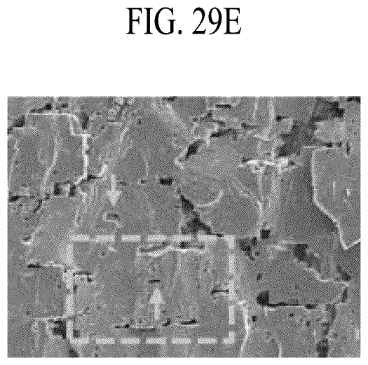

FIGS. 29A to 29E illustrate a microstructure based on a BAZ content of a TGG composition sample according to an embodiment of the present disclosure.

The inventors have prepared a sample where values of x are 0.00, 0.01, 0.02, 0.03, and 0.04 in Equation 2 described above with reference to FIG. 2, so as to analyze an SEM image of a TGG composition. A composition of the piezoelectric material composition may be 0.96(Na_{0.5}K_{0.5})(Nb_{0.93}Sb_{0.07})O₃-(0.04-x)BaZrO₃-x(Bi_{0.5}Ag_{0.5})ZrO₃+0.5 mol % Fe₂O₃+3 mol % NaNbO₃, and a sample of a piezoelectric material composition has been prepared through sintering performed for 6 hours at 1,090° C. The piezoelectric material composition may be configured where T is Ba, a is 0.50, b is 0.93, c is 0.50, d is 0.50, and e is 3.00 in Equation 2 described above with reference to FIG. 2. A seed material has used NaNbO₃ of 3 mol %.

With reference to FIGS. 29A to 29E, a TGG composition has a grain size of about 30 μm to about 40 μm in all of samples where values of x are 0.00, 0.01, 0.02, 0.03, and 0.04, and grain growth (a tetragonal dotted line of the drawing) has been smoothly performed to be vertical to a tape casting direction (or a horizontal direction of the drawing). Also, in some grains of all samples, evidence has been discovered where an NN seed helps orientation grain growth, and then, is diffused as a grain and is removed.

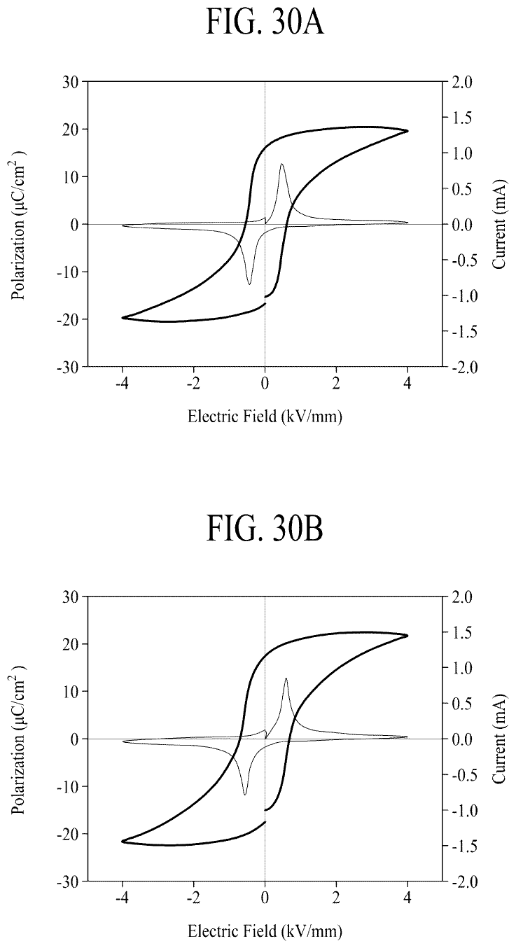

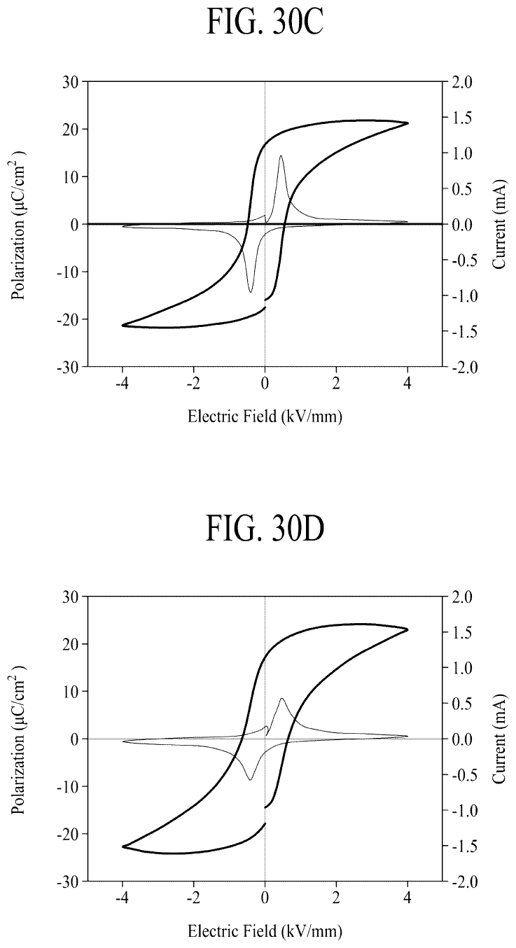

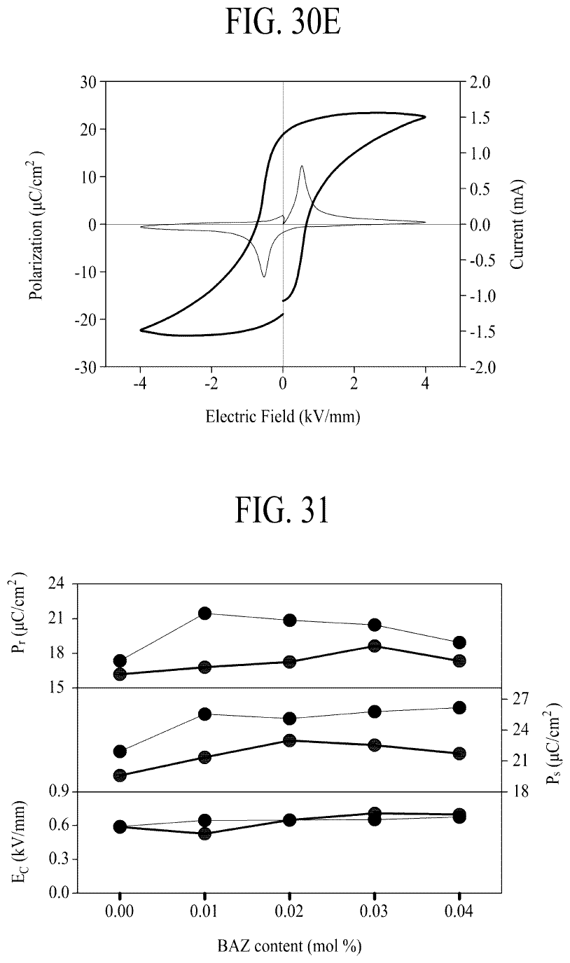

FIGS. 30A to 30E illustrate P-E and I-E of a TGG composition according to an embodiment of the present disclosure. In FIGS. 30A to 30E, a thick solid line represents a hysteresis curve of polarization versus electric field (P-E) with respect to a BAZ content of a TGG composition according to an embodiment of the present disclosure. In FIGS. 30A to 30E, a thin solid line represents current versus electric field (I-E) with respect to the BAZ content of the TGG composition according to an embodiment of the present disclosure. In FIGS. 30A to 30E, a composition of each sample based on a change in BAZ content of a composition has been prepared by the same method as the non-TGG composition sample of each of FIGS. 29A to 29E. In FIGS. 30A to 30E, values of x are 0.0, 0.01, 0.02, 0.03, and 0.04, respectively.

With reference to FIGS. 30A to 30E, a piezoelectric material composition based on a BAZ content represents a conventional P-E hysteresis curve of a ferroelectric material. In an I-E graph of the piezoelectric material composition based on the BAZ content, two peaks have been observed because of domain switching based on application of an electric field. The I-E curve may be observed in a ferroelectric material generally. Therefore, it may be confirmed that the piezoelectric material composition according to an embodiment of the present disclosure has a ferroelectric characteristic.

FIG. 31 illustrates numerical variations of saturated polarization Pₛ, remnant polarization Pᵣ, and a coercive field E_{c} with respect to a BAZ content of each of a TGG composition and a non-TGG composition according to an embodiment of the present disclosure. In FIG. 31, a thin solid line represents a numerical variation of each of saturated polarization Pₛ, remnant polarization Pᵣ, and a coercive field E_{c} with respect to a BAZ content of a non-TGG composition, and a thick solid line represents a numerical variation of each of saturated polarization Pₛ, remnant polarization Pᵣ, and a coercive field E_{c} with respect to a BAZ content of a TGG composition. In FIG. 31, the thin solid line represents a piezoelectric characteristic of the non-TGG composition, and the thick solid line represents a piezoelectric characteristic of the TGG composition

With reference to the thin solid line of FIG. 31, it has been confirmed that numerical values of the saturated polarization Pₛ and the remnant polarization Pᵣ of the non-TGG composition increase by adding BAZ. However, when x is more than 0.01, numerical variations of the saturated polarization Pₛ and the remnant polarization Pᵣ based on an increase in x are not large and have similar values. Accordingly, according to an embodiment of the present disclosure, it has been confirmed that an increase in numerical values of the saturated polarization Pₛ and the remnant polarization Pᵣ is associated with an increase in grain size caused by addition of a small amount of BAZ.

With reference to the thick solid line of FIG. 31, the remnant polarization Pᵣ of the TGG composition has increased as a value of x increases from 0.00 to 0.03 and has again decreased in 0.04. The saturated polarization Pₛ of the TGG composition has increased as a value of x increases from 0.00 to 0.02 and has decreased from 0.03. A numerical value of the of the coercive field E_{c} of the TGG composition has increased as a value of x increases from 0.00 to 0.02 and has been similar after 0.02.

According to an embodiment of the present disclosure, in all of the non-TGG composition and the TGG composition, it has been measured that remnant polarization Pᵣ is lowest in a sample where a value of x is 0.00 and is highest in a sample where a value of x is 0.03. Also, in all of the non-TGG composition and the TGG composition, it has been measured that saturated polarization Pₛ is lowest in a sample where a value of x is 0.00 and is highest in a sample where a value of x is 0.02. Also, in all of the non-TGG composition and the TGG composition, it has been measured that a numerical value of a coercive field E_{c} is hardly changed as a value of x increases, but slightly increases as a value of x increases.

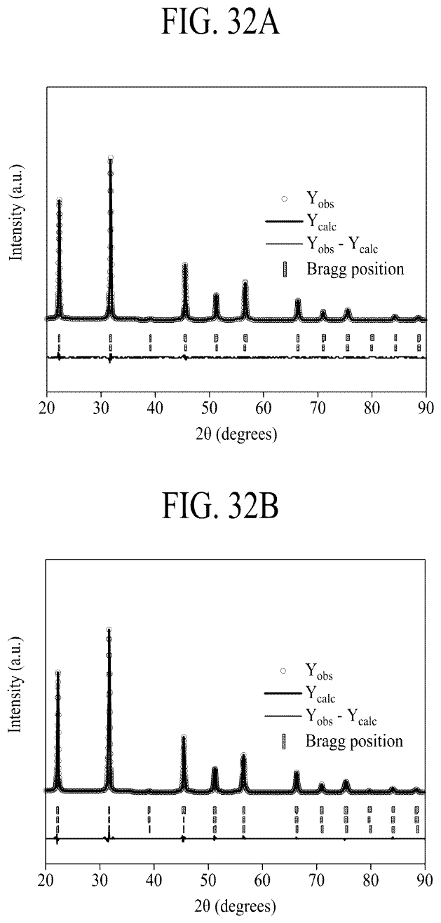

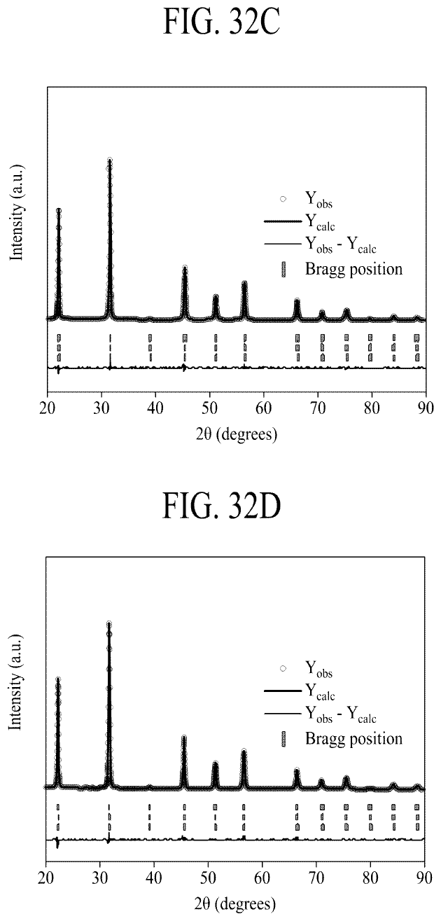

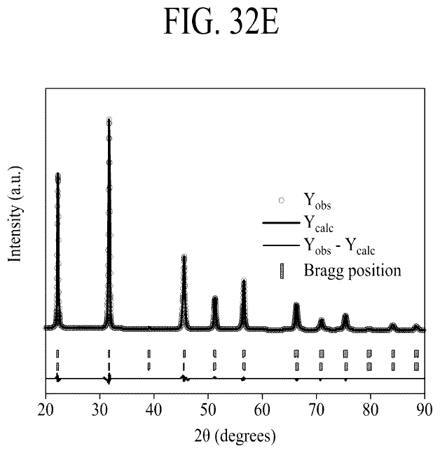

FIGS. 32A to 32E are graphs showing an X-ray diffraction pattern with respect to a BAZ content of a TGG composition according to an embodiment of the present disclosure. This is data for checking a volume fraction of rhombohedral, orthorhombic, and tetragonal with respect to a BAZ content of a non-TGG composition including an NN seed. In FIGS. 32A to 32E, intensity (a.u.) of the Y axis is a numerical value expressed as a relative value with respect to a maximum value of an X-ray diffraction pattern. In FIGS. 32A to 32E, Yobs represents an XRD measurement value, Ycalc represents an XRD analysis calculation value, Yobs−Ycalc represents an error between the XRD measurement value and an XRD analysis calculation value, and a Bragg position represents a refractive index.

The inventors have performed the precise analysis of an X-ray diffraction pattern based on a BAZ content of a TGG composition, for optimization of TGG. In FIGS. 32A to 32E, samples for analyzing an X-ray diffraction pattern based on each BAZ content have been prepared like FIGS. 29A to 29E. A sample has been prepared where a BAZ content is 0.00 in FIG. 32A, a BAZ content is 0.01 in FIG. 32B, a BAZ content is 0.02 in FIG. 32C, a BAZ content is 0.03 in FIG. 32D, and a BAZ content is 0.04 in FIG. 32E.

As in FIG. 32A, when a BAZ content is 0.00, it has been measured that a volume fraction of rhombohedral is 29.25% and a volume fraction of orthorhombic is 70.75%. Therefore, when a BAZ content is 0.00, it may be confirmed that a tetragonal phase is not formed. For example, when a BAZ content is 0.00, it may be seen that a sample has a structure, where rhombohedral and orthorhombic are provided together. For example, when a BAZ content is 0.00, it may be seen that a sample has a combination structure of R-O 2 phases. Also, when a BAZ content is 0.00, it has been confirmed that Rₚ is 3.81, R_{wp} is 5.08, and chi-square (χ²) is 2.57. R_{P} represents the degree to which a shape of an actually measured XRD pattern matches a shape of a Rietveld analyzed pattern. R_{WP} is a most important value and represents a weight of an R_{P} value. χ² denotes goodness-of-fit (GOF). For example, χ² denotes the degree to which fitting is well performed and may be a good numerical value as a numerical value is closer to 1. A Equation meaning may represent a ratio (R_{wp}/Rₑₓₚ) of Rₑₓₚ to R_{wp}. Therefore, χ² may not have a value which is less than 1. For example, statistically, χ² of about 1% may have a numerical value which is possible when R_{wp} is about 3% or less. For example, χ² may have a numerical value which is capable of being analyzed in a single crystal, a single-phase multi-crystal, a mixed-phase multi-crystal consisting of a single-phase, or a two-phase crystal having good crystal quality. For example, in a triple-phase multi-crystal, χ² of about 2% may be determined to be a good numerical value.

As in FIG. 32B, when a BAZ content is 0.01, it has been measured that a volume fraction of rhombohedral is 28.65%, a volume fraction of orthorhombic is 58.65%, and a volume fraction of tetragonal is 12.70%. For example, when the BAZ content increases, it may be seen that a ratio of a tetragonal appears. Also, when a BAZ content is 0.01, it has been confirmed that Rₚ is 3.69, R_{wp} is 5.00, and χ² is 2.46. For example, when the BAZ content is 0.01, it may be seen that a combination structure of R-O-T 3 phases is provided.

As in FIG. 32C, when a BAZ content is 0.02, it has been measured that a volume fraction of rhombohedral is 28.16%, a volume fraction of orthorhombic is 52.09%, and a volume fraction of tetragonal is 19.75%. Therefore, when the BAZ content is 0.02, it may be confirmed that a volume fraction of each of rhombohedral and orthorhombic is about 80%, and a volume fraction of tetragonal is about 20%. For example, when the BAZ content increases, it may be seen that a ratio of a tetragonal increases. Also, when a BAZ content is 0.02, it has been confirmed that Rₚ is 3.73, R_{wp} is 4.90, and χ² is 2.40. For example, when the BAZ content is 0.02, it may be seen that a combination structure of R-O-T 3 phases is provided.

As in FIG. 32D, when a BAZ content is 0.03, it has been measured that a volume fraction of rhombohedral is 30.13%, a volume fraction of orthorhombic is 35.36%, and a volume fraction of tetragonal is 34.51%. Therefore, when the BAZ content is 0.03, it may be confirmed that a volume fraction of each of rhombohedral, orthorhombic, and tetragonal is measured to be similar within a range of about 30% to about 36%. For example, when the BAZ content is 0.03, it may be seen that a ratio of three phases of rhombohedral, orthorhombic, and tetragonal is about 3:3:3. For example, when the BAZ content increases, it may be seen that a ratio of a tetragonal phase increases and a ratio of an orthorhombic phase decreases. Also, when a BAZ content is 0.03, it has been confirmed that Rₚ is 3.95, R_{wp} is 5.29, and χ² is 2.84. For example, when the BAZ content is 0.03, it may be seen that a combination structure of R-O-T 3 phases is provided.

As in FIG. 32E, when a BAZ content is 0.04, it has been measured that a volume fraction of rhombohedral is 30.10% and a volume fraction of tetragonal is 69.90%. Therefore, when the BAZ content is 0.04, it may be seen that a tetragonal phase is not formed. For example, when the BAZ content is 0.04, it may be confirmed that phase transition to orthorhombic is omitted and a rhombohedral phase and a tetragonal phase are provided together. Also, when a BAZ content is 0.04, it has been confirmed that Rₚ is 3.79, R_{wp} is 4.91, and χ² is 2.94. For example, when the BAZ content is 0.04, it may be seen that a combination structure of R-T 2 phases is provided.

In the TGG piezoelectric material composition according to an embodiment of the present disclosure, as a BAZ content increases, a volume fraction of a tetragonal phase may increase, and a volume fraction of an orthorhombic phase may decrease. In the TGG piezoelectric material composition according to an embodiment of the present disclosure, it may be seen that a volume fraction of a rhombohedral phase is hardly changed as a BAZ content increases.

When a BAZ content is 0.00, the TGG piezoelectric material composition according to an embodiment of the present disclosure may have a structure where rhombohedral and orthorhombic are provided together, and when the BAZ content is 0.04, the TGG piezoelectric material composition according to an embodiment of the present disclosure may have a structure where a rhombohedral phase and a tetragonal phase are provided together. Therefore, when a BAZ content of the TGG piezoelectric material composition according to an embodiment of the present disclosure is within a range of 0.01 to 0.03, it may be seen that the piezoelectric material composition has a structure of three phases of R-O-T. Accordingly, when the BAZ content of the TGG piezoelectric material composition according to an embodiment of the present disclosure is within a range of 0.02 to 0.03, it may be seen that the TGG piezoelectric material composition has a structure where a volume fraction of each of three phases of R-O-T is optimal.

Moreover, according to an embodiment of the present disclosure, it has been confirmed that a change in crystal structure is not large even after texturing. For example, texturing may denote a TGG process. For example, according to an embodiment of the present disclosure, it has been confirmed that a crystal structure of the non-TGG composition described above with reference to FIGS. 18A to 18E is similar to a crystal structure of the TGG composition described above with reference to FIGS. 32A to 32E, where texturing is performed by adding a seed. According to an embodiment of the present disclosure, because the crystal structure of the non-TGG composition and the crystal structure of the TGG composition have the same matrix composition, grain directions of orientations may differ, but it has been confirmed that the non-TGG composition and the TGG composition have an almost similar phase structure and volume fraction. Accordingly, in TGG, it has been confirmed that a seed allows a direction of orientation of a material to be preferentially oriented in a (001) orientation and does not change a grain phase structure and a fraction of a material. Therefore, it has been confirmed that the same grain phase structure as a grain phase structure of a matrix composition is maintained even when a TGG process is performed.

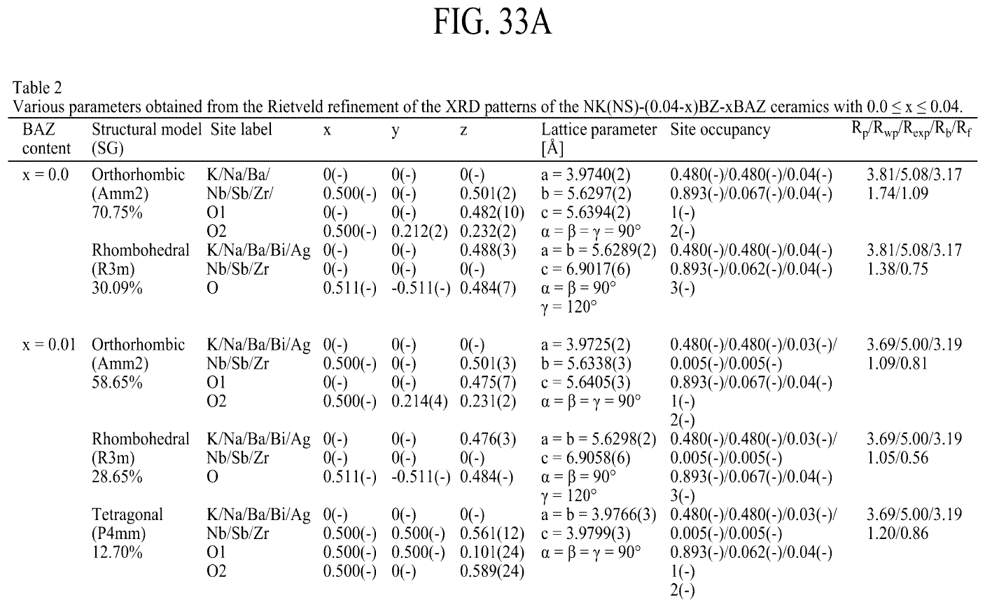

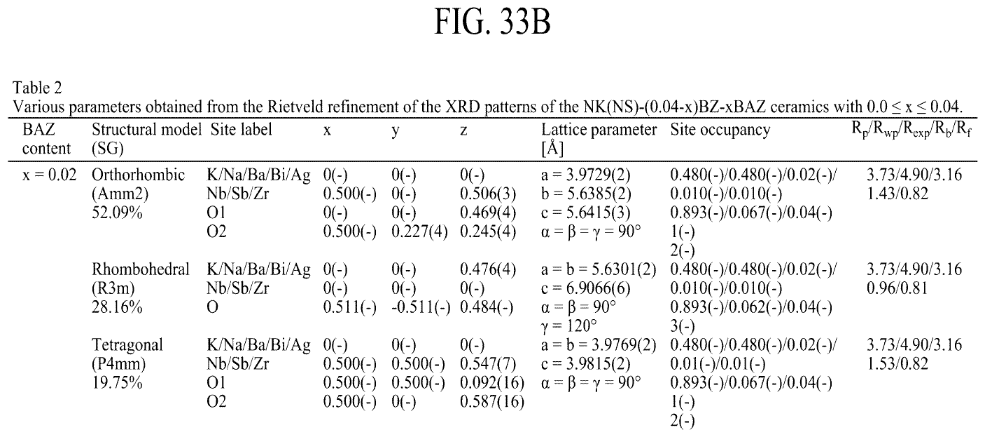

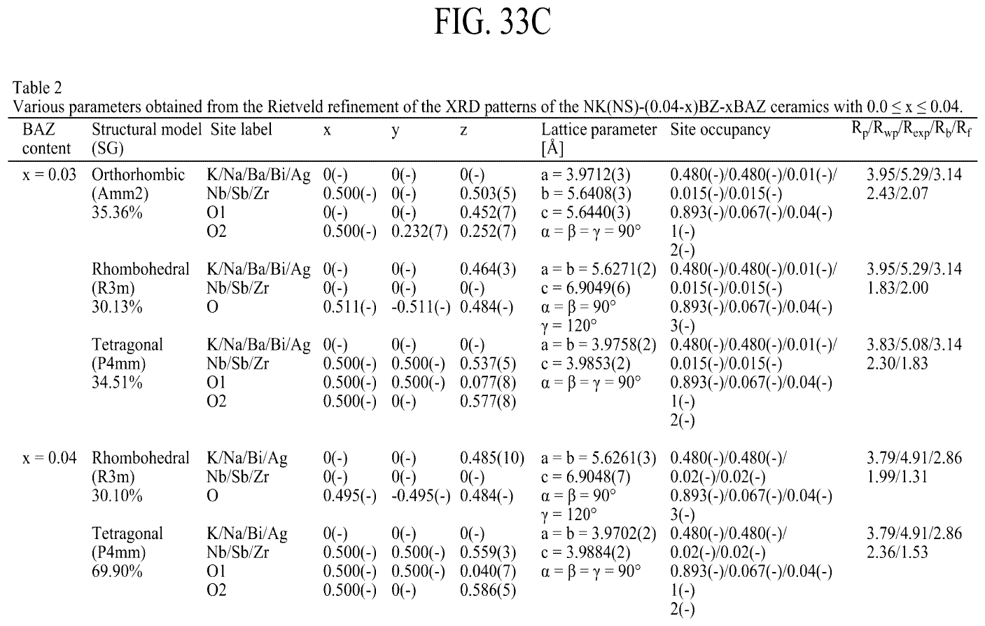

FIGS. 33A to 33C are Rietveld refinement result tables of TGG KNNS-BZ-BAZ ceramic according to an embodiment of the present disclosure. In FIGS. 33A to 33C, a structure model (or a space group SG), a site label, x, y, and z positions, a lattice parameter, and site occupancy, and R parameters may be as described above with reference to FIGS. 19A to 19C, and thus, descriptions thereof are omitted.

With reference to FIGS. 33A to 33C, comparing with a result table of the non-TGG Rietveld analysis described above with reference to FIGS. 19A to 19C, it may be confirmed that an embodiment of the present disclosure is measured to be similar thereto. Accordingly, the inventors have confirmed a volume fraction of each of rhombohedral, orthorhombic, and tetragonal based on a BAZ content of a TGG composition including an NN seed, based on the Rietveld analysis.

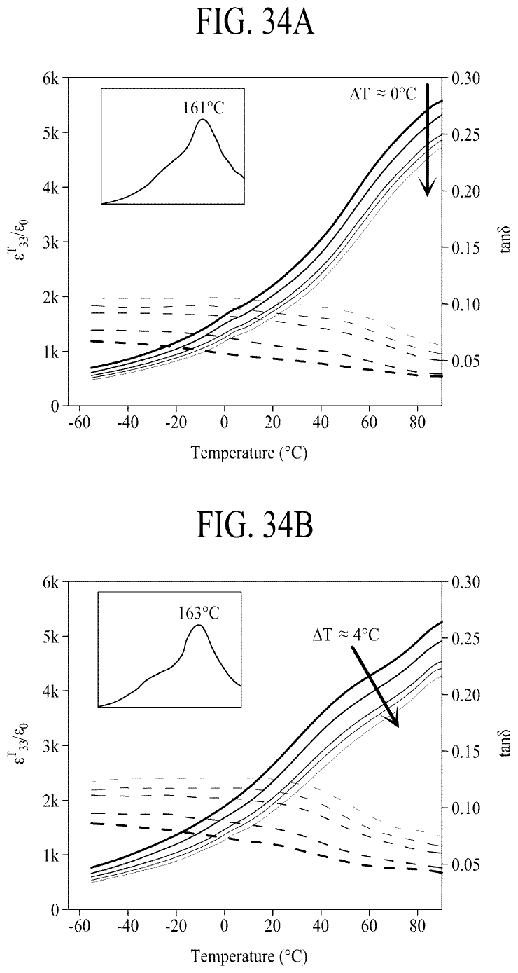

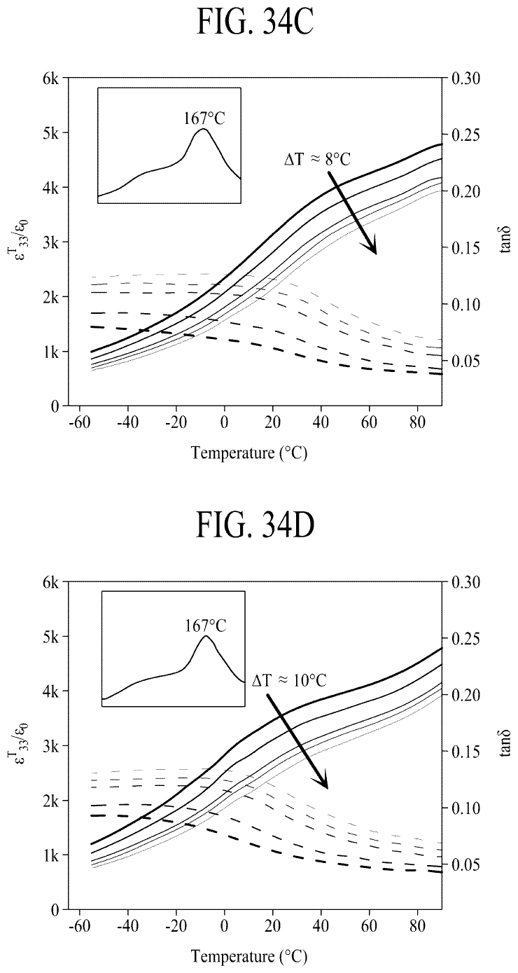

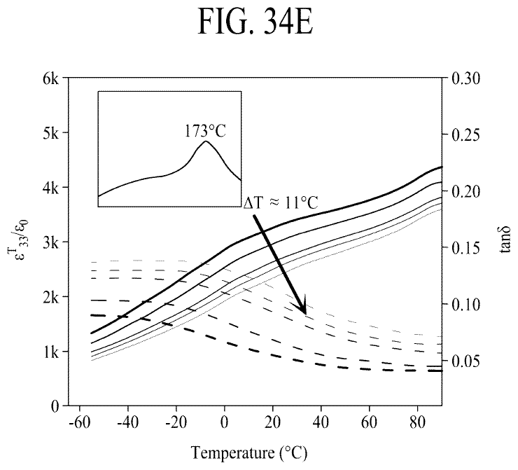

FIGS. 34A to 34E are temperature versus dielectric constant graphs in different frequencies with respect to a BAZ content of a TGG composition according to an embodiment of the present disclosure. Measurement has been performed under a condition where a temperature is −60° C. to 90° C. In FIGS. 34A to 34E, a composition of each sample based on a variation of a BAZ content of a composition has been prepared by the same method as the TGG composition sample of FIGS. 29A to 29E, and values of x are 0.00, 0.01, 0.02, 0.03, and 0.04, respectively. In FIGS. 34A to 34E, thin solid lines from thick solid lines represent a temperature versus a dielectric constant in 1 kHz, 10 KHz, 100 kHz, 200 kHz, and 500 kHz. Measurement has been performed under a condition where a temperature of a frequency is −60° C. to 250° C. In the drawings, a dotted line represents a loss factor with respect to each frequency.

With reference to FIG. 34A, in a sample where a value of x is 0.00, it may be seen that a temperature of a T_{O-T} dielectric peak is constant despite a variation of a frequency. In the sample where the value of x is 0.00, it has been confirmed that the T_{O-T} dielectric peak is about 74.0° C. In the sample where the value of x is 0.00, it has been confirmed that Curie temperature is about 161.0° C. Accordingly, it has been confirmed that a piezoelectric material composition is a ferroelectric material.

With reference to FIGS. 34B to 34E, in a sample where a value of x is 0.01 to 0.04, it may be seen that a relaxor dielectric including a nano domain or a polar nano region (PNR) is provided, or a dielectric peak is changed by a defect dipole with respect to a frequency.

With reference to FIG. 34B, in a sample where a value of x is 0.01, it has been confirmed that a T_{O-T} dielectric peak is small shifted to about 2.0° ° C. In the sample where the value of x is 0.01, it has been confirmed that Curie temperature is about 163.0° ° C. With reference to FIG. 34E, in an embodiment where a value of x is 0.04, it has been confirmed that a T_{O-T} dielectric peak is largely shifted to about 13.0° C. In the sample where the value of x is 0.04, it has been confirmed that Curie temperature is about 173.0° C. Accordingly, as a value of x increases, it has been confirmed that a characteristic of the relaxor dielectric increases. Also, the non-TGG composition according to an embodiment of the present disclosure may have frequency dependency, and thus, it may be seen that the non-TGG composition has a nano domain by adding a composition of BAZ.

With reference to FIGS. 34A to 34E, T_{O-T} (a phase transition temperature where an O phase and a T phase transit) has decreased as x increases, T_{O-T} and T_{R-O} have been shifted to T_{R-O-T} in a sample where a value of x is 0.03, and T_{O-T} and T_{R-O} have been shifted to T_{R-T} in a sample where a value of x is 0.04. As x increases, T_{O-T} has decreased to a low temperature, and T_{R-O} has not almost been observed.

With reference to FIGS. 34A to 34E, in each sample, it has been confirmed that a loss factor slightly increases as a frequency increases.

Comparing FIGS. 20A to 20E with FIGS. 34A to 34E, it may be seen that a peak shape of T_{c} of the TGG composition is wider than a peak shape of T_{c} of the non-TGG composition. Also, it may be seen that a T_{c} temperature of the TGG composition is slightly lower than a T_{c} temperature of the non-TGG composition having the same x content.

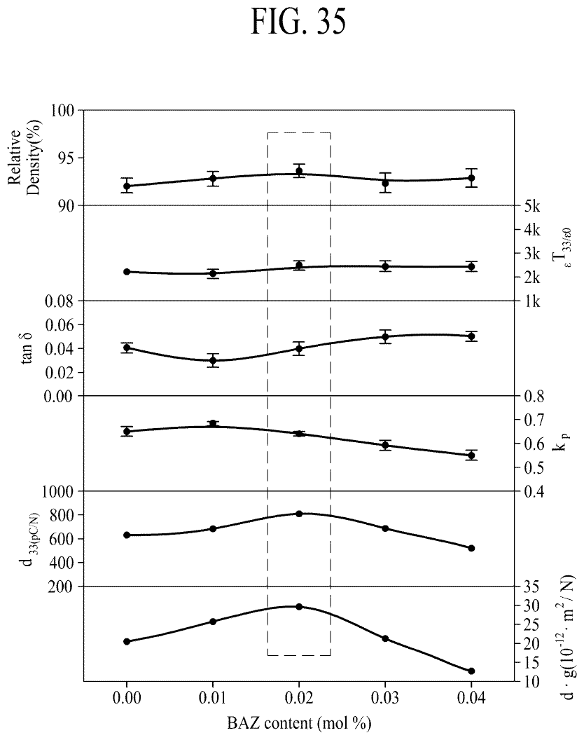

FIG. 35 is a graph showing a relative density (%), a dielectric constant ε^{T}₃₃/ε₀, a loss factor tan δ, a piezoelectric charge constant d₃₃, an electromechanical coupling factor k_{ρ}, and an energy harvesting performance index of a TGG piezoelectric material composition with respect to a BAZ content according to an embodiment of the present disclosure.

The inventors have measured the performance of a piezoelectric material composition based on a BAZ content, so as to optimize TGG. In FIG. 35, samples for analyzing an X-ray diffraction pattern based on each BAZ content have been prepared like FIGS. 29A to 29E. In FIG. 35, BAZ contents of samples are 0.00, 0.01, 0.02, 0.03, and 0.04, respectively.

With reference to FIG. 35, a relative density (%) according to an embodiment of the present disclosure represents a value of 92% or more in all of samples where BAZ contents are 0.00, 0.01, 0.02, 0.03, and 0.04. Accordingly, it has been confirmed that a variation based on an increase in BAZ content is not observed.

It has been confirmed that a dielectric constant ε^{T}₃₃/ε₀ represents more than 2,000 in all of samples where BAZ contents are 0.00, 0.01, 0.02, 0.03, and 0.04. Accordingly, it has been confirmed that a variation based on an increase in BAZ content is not observed.

A loss factor tan δ has a value between 0.02 to 0.06 in samples where BAZ contents are 0.00, 0.01, 0.02, 0.03, and 0.04. Comparing with a sample where a BAZ content is 0, a loss factor tan δ has decreased in a case where a BAZ content is 0.01, and as a BAZ content increases to 0.02 and 0.03, a loss factor tan δ has increased. In a case where a BAZ content is 0.04, it has been confirmed that a loss factor tan δ has a similar value in a case where a BAZ content is 0.03.

An electromechanical coupling factor kρ has a value between 0.5 to 0.7 in samples where BAZ contents are 0.00, 0.01, 0.02, 0.03, and 0.04. Comparing with a case where a BAZ content is 0.00, an electromechanical coupling factor kρ has slightly increased in a case where a BAZ content is 0.01, and as a BAZ content increases to 0.02, 0.03, and 0.04, an electromechanical coupling factor kρ has slightly decreased. In cases where BAZ contents are 0.01 and 0.02, it may be confirmed that electromechanical coupling factors kρ have values of 0.64 and 0.67 and a good piezoelectric characteristic is realized. For example, an electromechanical coupling factor kρ may be a factor representing conversion efficiency between electrical energy and mechanical energy, may be a significant constant in a piezoelectric displacement, and may have a characteristic similar to a piezoelectric charge constant. For example, an electromechanical coupling factor kρ may be inversely proportional to porosity and may be proportional to a grain diameter, and as a sintering temperature increases, a value thereof may increase in proportion to an increase in the sintering temperature.

In samples where BAZ contents are 0.00, 0.01, 0.02, 0.03, and 0.04, a piezoelectric charge constant d₃₃ has a value within a range of 450 pC/N to 805 pC/N. Comparing with a case where a BAZ content is 0, a piezoelectric charge constant d₃₃ has increased in a case where a BAZ content is 0.01, and in a case where a BAZ content is 0.02, it has been confirmed that a piezoelectric charge constant d₃₃ has a highest value of 805 pC/N. However, as a BAZ content increases from 0.03 to 0.04, a piezoelectric charge constant d₃₃ has decreased again. Accordingly, in an embodiment of the present disclosure, when a BAZ content is 0.02, it has been confirmed that a piezoelectric characteristic is good. For example, a piezoelectric charge constant d₃₃ represents the amount of electric charges generated in a pressure direction when pressure is applied to a material, and a piezoelectric material where a piezoelectric charge constant d₃₃ is large may provide a high-density piezoelectric device having good piezoelectric performance. For example, a piezoelectric charge constant d₃₃ may be measured in a room temperature.

Comparing with a case where a BAZ content is 0, an energy harvesting performance index (d·g(10⁻¹²·m²/N)) represents a value which is higher than a case where a BAZ content is 0.01. In a case where a BAZ content is 0.02, an energy harvesting performance index has a highest value of 30 d·g(10⁻¹²·m²/N). However, as a BAZ content increases to 0.03 and 0.04, an energy harvesting performance index has decreased again. In a case where a BAZ content is 0.04, an energy harvesting performance index has a value of 15 or less. For example, as a numerical value increases, an energy harvesting performance index has a large output compared to an energy input. Accordingly, in an embodiment of the present disclosure, under a condition where a BAZ content is 0.02, it has been confirmed that an energy harvesting performance index have a highest value and a piezoelectric characteristic is good.

According to an embodiment of the present disclosure, the inventors have analyzed a relative density (%), a dielectric constant ε^{T}₃₃/ε₀, a loss factor tan δ, a piezoelectric charge constant d₃₃, an electromechanical coupling factor k_{ρ}, and an energy harvesting performance index of a piezoelectric material composition with respect to a BAZ content, and thus, have calculated an optimal condition of a BAZ content.

Therefore, according to an embodiment of the present disclosure, a piezoelectric material composition may not include Pb and may have a high piezoelectric characteristic.

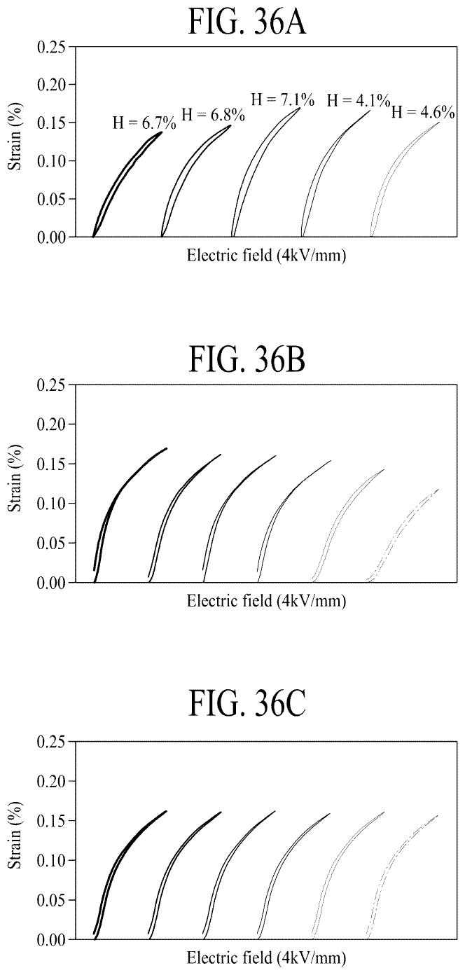

FIGS. 36A to 36C illustrate a piezoelectric characteristic when an electric field is applied to a TGG composition according to an embodiment of the present disclosure. FIG. 36A shows a unipolar strain when an electric field of 4 kV/mm is applied to a sample based on a BAZ content of a TGG composition. In a direction from the left of FIG. 36A to the right thereof, a value of x represents a unipolar strain in each of 0.00, 0.01, 0.02, 0.03, and 0.04. FIG. 36B shows a unipolar strain with respect to a temperature when an electric field of 4 kV/mm is applied to a sample where a BAZ content of a TGG composition is 0.02. In a direction from the left of FIG. 36B to the right thereof, a value of x represents a unipolar strain in each of a room temperature, 50° C., 75° C., 100° C., 125° C., and 150° C. FIG. 36C shows a unipolar strain with respect to the number of cycles (100 to 106 cycles) when an electric field of 4 kV/mm is applied to a sample where a BAZ content of a non-TGG composition is 0.03. In a direction from the left of FIG. 36C to the right thereof, a value of x represents a unipolar strain in each of 10⁰, 10¹, 10², 10³, 10⁴, 10⁵, and 10⁶.

With reference to FIG. 36A, it may be seen that a unipolar strain when an electric field of 4 kV/mm is applied to a sample based on a BAZ content of a TGG composition is 0.17% and highest in a sample where a BAZ content is 0.02.

With reference to FIG. 36B, it may be seen that a unipolar strain with respect to a temperature when an electric field of 4 kV/mm is applied to a sample where a BAZ content of a TGG composition is 0.02 represents a strain of 0.17% in a room temperature RT, and a strain is maintained up to 0.15% in about 125° C. Also, it may be seen that a unipolar strain decreases to 0.13% or less in about 150° C. or more.

With reference to FIG. 36C, it may be seen that a unipolar strain, which is based on the number of cycles (100 to 106 cycles) when an electric field of 4 kV/mm is applied to a sample where a BAZ content of a TGG composition is 0.02, is not reduced even when driving is performed based on an input signal of 1 kV/mm up to 100 to 106 cycles.

Therefore, according to an embodiment of the present disclosure, when a BAZ content of a TGG composition is 0.02, it has been confirmed that a piezoelectric characteristic is good.

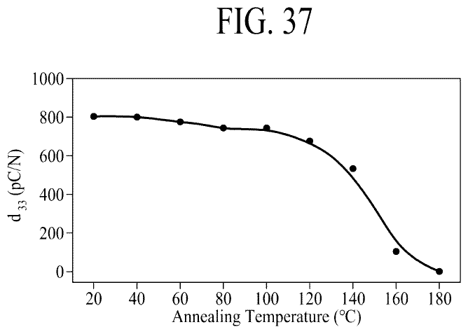

FIG. 37 is a graph showing a piezoelectric charge constant d₃₃ with respect to a variation of an annealing temperature with respect to a BAZ content according to an embodiment of the present disclosure.

The inventors have measured a piezoelectric charge constant d₃₃ of a piezoelectric material composition based on an annealing temperature, so as to optimize a TGG process. Samples for preparing the piezoelectric charge constant d₃₃ of the piezoelectric material composition based on the annealing temperature have been prepared to have the same composition as FIG. 7. Here, a BAZ content may be 0.02.

With reference to FIG. 37, according to an embodiment of the present disclosure, a piezoelectric charge constant d₃₃ has been measured to be about 805 pC/N in an annealing temperature of 20° C. and 40° C. According to an embodiment of the present disclosure, as the annealing temperature increases to 60° C., 80° C., and 100° C., a piezoelectric charge constant d₃₃ has been slightly reduced. When the annealing temperature is 100° C. or more, an piezoelectric charge constant d₃₃ has rapidly decreased, and when the annealing temperature is 160° C. or more, an piezoelectric charge constant d₃₃ has decreased to 110 pC/N or less.

According to an embodiment of the present disclosure, the reliability of a piezoelectric material composition may be maintained under a condition where an annealing temperature of the piezoelectric material composition is less than 100° C., and the piezoelectric material composition may have a highest piezoelectric characteristic and a high piezoelectric charge constant d₃₃ within a range of 20° C. and 40° C.

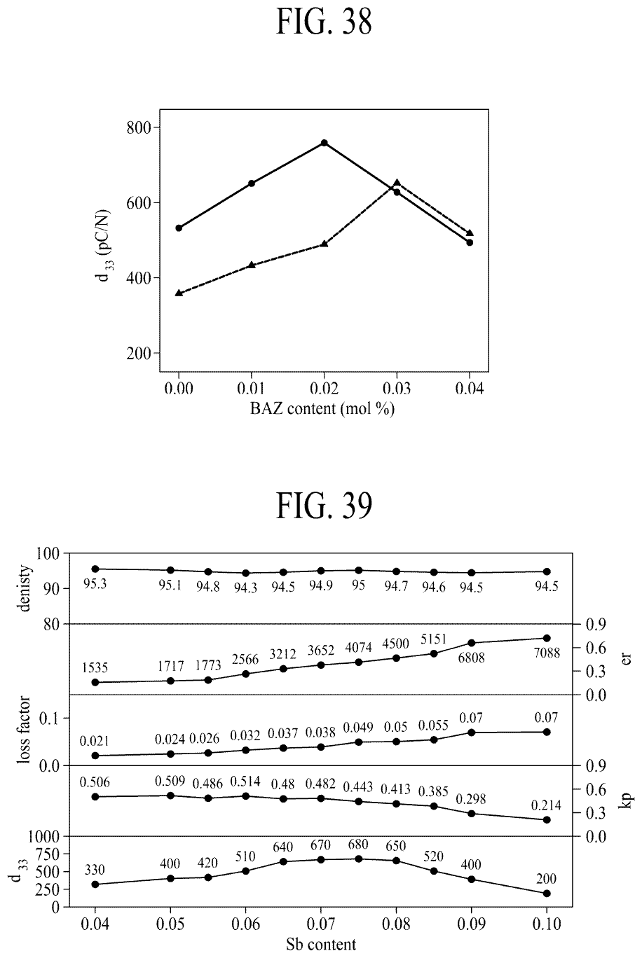

FIG. 38 is a graph showing a piezoelectric charge constant d₃₃ with respect to a BAZ content according to an embodiment of the present disclosure. FIG. 38 is a graph showing a piezoelectric charge constant with respect to a BAZ content of each of a sample where grains are randomly oriented and a sample where grains are oriented in a (001) orientation. In FIG. 38, a dotted line represents a piezoelectric charge constant corresponding to a sample where grains are randomly oriented, and a solid line represents a piezoelectric charge constant corresponding to a sample where grains are oriented in a (001) orientation.

The inventors have measured a piezoelectric charge constant d₃₃ when Sr is used as M in Equation 2 described above with reference to FIG. 2, so as to analyze a piezoelectric charge constant d₃₃ based on a BAZ content. A composition of a piezoelectric material composition may be 0.96(Na_{0.5}K_{0.5})(Nb_{0.93}Sb_{0.7})-(0.04-x)SrZrO₃-x(Bi_{0.5}Ag_{0.5})ZrO₃+0.5 mol % Fe₂O₃+3 mol % NaNbO₃, and a sample has been prepared through sintering performed for 6 hours at 1,090° C. For example, a sintering temperature may be 900° C. to 1,150° C. and a maintenance time may be 1 hour to 10 hours, but embodiments of the present disclosure are not limited thereto. In the piezoelectric material composition, a BAZ content (or a value of x in Equation 1) may be set to each of 0.00, 0.01, 0.02, 0.03, and 0.04. A seed material has used NaNbO₃ of 3 mol %.

With reference to a dotted line of FIG. 38, in the sample where grains are randomly oriented, a piezoelectric charge constant d₃₃ has increased as a BAZ content (or a value of x in Equation 2) is changed to each of 0.00, 0.01, 0.02, and 0.03. Also, in the sample where grains are randomly oriented, a piezoelectric charge constant d₃₃ has decreased as a BAZ content (or a value of x in Equation 2) is more than 0.03.

With reference to a solid line of FIG. 38, in the sample where grains are oriented in a (001) orientation, a piezoelectric charge constant d₃₃ has increased as a BAZ content (or a value of x in Equation 2) is changed to each of 0.00, 0.01, and 0.02. Also, in the sample where grains are oriented in a (001) orientation, a piezoelectric charge constant d₃₃ has decreased as a BAZ content (or a value of x in Equation 2) is more than 0.03.

According to an embodiment of the present disclosure, when a BAZ content (or a value of x in Equation 2) is 0.03 or less, it has been confirmed that a piezoelectric material composition, where grains are oriented in a (001) orientation, has a high piezoelectric charge constant d₃₃ and a high piezoelectric characteristic.

FIG. 39 is a graph showing a density (%), a dielectric constant ε^{T}₃₃/ε₀, a loss factor tan δ, an electromechanical coupling factor k_{ρ}, and a piezoelectric charge constant d₃₃ with respect to a content of antimony (Sb) of a non-TGG composition according to an embodiment of the present disclosure.

The inventors have measured a piezoelectric charge constant d₃₃ based on a variation of Sb in Equation 1 described above with reference to FIG. 1, so as to analyze a piezoelectric charge constant d₃₃ based on an Sb content of a non-TGG piezoelectric material composition. A composition of a non-TGG piezoelectric material composition may be 0.96(Na_{0.5}K_{0.5})(Nb_{0.93}Sb_{0.07})-(0.04-x)CaZrO3-x(Bi0.5Ag0.5)ZrO₃+0.5 mol % Fe₂O₃, and a sample has been prepared through sintering performed for 6 hours at 1,090° C. A sintering temperature and a maintenance time do not limit details of the present disclosure. In a composition of a piezoelectric material, a BAZ content has been prepared to have 0.03 (x=0.03). In the piezoelectric material composition, a content of Sb may be set to each of 0.040, 0.050, 0.060, 0.070, 0.080, 0.090, and 0.100.

With reference to FIG. 39, a relative density (%) according to an embodiment of the present disclosure represents a value of 94% or more in all of samples where Sb contents are 0.040, 0.050, 0.060, 0.070, 0.080, 0.090, and 0.100. A relative density (%) according to an embodiment of the present disclosure represents 95.3%, 95.1%, 94.3%, 94.9%, 94.7%, 94.5%, and 94.5% in samples where Sb contents are 0.040, 0.050, 0.060, 0.070, 0.080, 0.090, and 0.100, respectively. Accordingly, in a density (%), it has been confirmed that a variation based on an increase in Sb content is not observed.

A dielectric constant ε^{T}₃₃/ε₀ represents values of 1535, 1717, 2566, 3652, 4500, 6508, and 7088 in samples where Sb contents are 0.040, 0.050, 0.060, 0.070, 0.080, 0.090, and 0.100, respectively. Accordingly, in an embodiment of the present disclosure, it has been confirmed that a dielectric constant increases as an Sb content increases. Also, in an embodiment of the present disclosure, it has been confirmed that a dielectric constant is capable of being controlled based on an Sb content.

A loss factor tan δ represents values of 0.021, 0.024, 0.032, 0.038, 0.050, 0.070, and 0.070 in samples where Sb contents are 0.040, 0.050, 0.060, 0.070, 0.080, 0.090, and 0.100, respectively. Accordingly, in another embodiment of the present disclosure, it has been confirmed that a loss factor tan δ increases as an Sb content increases. Also, when an Sb content is 0.090 or more, it has been confirmed that a loss factor tan δ does not increase any longer.

An electromechanical coupling factor kρ represents values of 0.506, 0.509, 0.514, 0.482, 0.413, 0.298, and 0.214 in samples where Sb contents are 0.040, 0.050, 0.060, 0.070, 0.080, 0.090, and 0.100, respectively. When an Sb content is 0.040 to 0.070, it has been confirmed that an electromechanical coupling factor kρ according to another embodiment of the present disclosure represents a similar value. Also, when an Sb content is more than 0.070, it has been confirmed that an electromechanical coupling factor kρ according to another embodiment of the present disclosure decreases progressively. Accordingly, in another embodiment of the present disclosure, when an Sb content is 0.070 or less, it has been confirmed that an electromechanical coupling factor kρ is higher than a case where an Sb content is more than 0.070.

A piezoelectric charge constant d₃₃ represents values of 330 pC/N, 400 pC/N, 510 pC/N, 670 pC/N, 650 pC/N, 400 pC/N, and 200 pC/N in samples where Sb contents are 0.040, 0.050, 0.060, 0.070, 0.080, 0.090, and 0.100, respectively. When an Sb content is 0.040 to 0.070, it has been confirmed that a piezoelectric charge constant d₃₃ according to another embodiment of the present disclosure increases progressively. On the other hand, when an Sb content is more than 0.075, it has been confirmed that a piezoelectric charge constant d₃₃ decreases progressively.

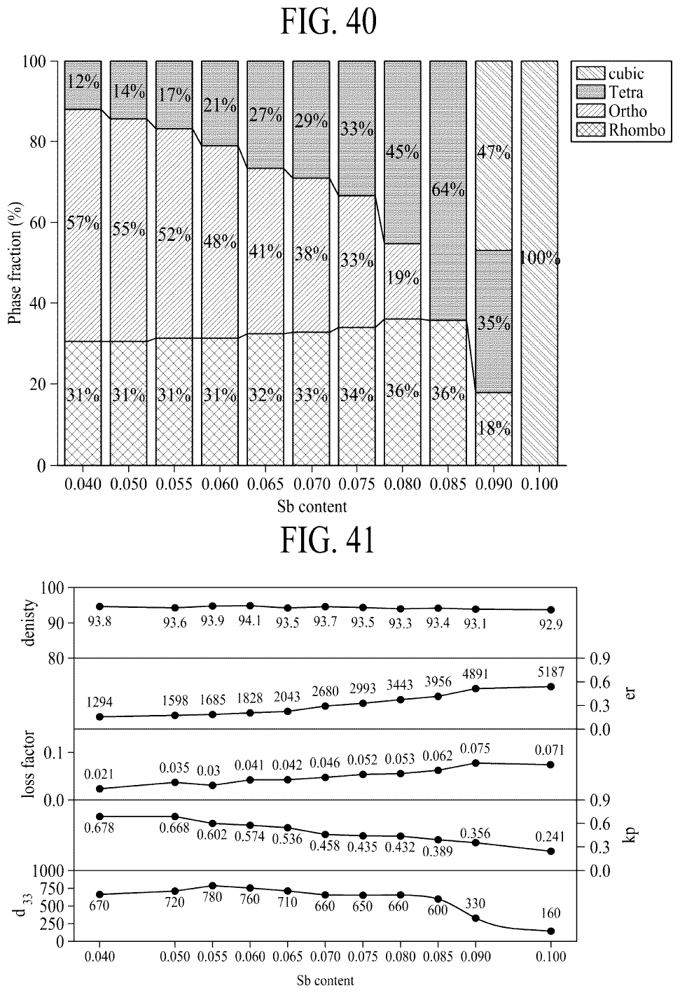

FIG. 40 is a graph showing a volume fraction of R-O-T with respect to a content of Sb of a non-TGG composition according to an embodiment of the present disclosure. In FIG. 40, a composition of a sample based on a variation of content of Sb for measuring a volume fraction of R-O-T according to another embodiment of the present disclosure has been prepared like the non-TGG piezoelectric material composition described above with reference to FIG. 39.

With reference to FIG. 40, when a content of Sb is 0.040, a volume fraction of rhombohedral represents 31%, a volume fraction of orthorhombic represents 57%, and a volume fraction of tetragonal represents 12%.

According to another embodiment of the present disclosure, when a content of Sb is 0.050, a volume fraction of rhombohedral represents 31%, a volume fraction of orthorhombic represents 55%, and a volume fraction of tetragonal represents 14%.

According to another embodiment of the present disclosure, when a content of Sb is 0.055, a volume fraction of rhombohedral represents 31%, a volume fraction of orthorhombic represents 52%, and a volume fraction of tetragonal represents 17%.

According to another embodiment of the present disclosure, when a content of Sb is 0.060, a volume fraction of rhombohedral represents 31%, a volume fraction of orthorhombic represents 48%, and a volume fraction of tetragonal represents 21%.

According to another embodiment of the present disclosure, when a content of Sb is 0.065, a volume fraction of rhombohedral represents 32%, a volume fraction of orthorhombic represents 41%, and a volume fraction of tetragonal represents 27%.

According to another embodiment of the present disclosure, when a content of Sb is 0.070, a volume fraction of rhombohedral represents 33%, a volume fraction of orthorhombic represents 38%, and a volume fraction of tetragonal represents 29%.

According to another embodiment of the present disclosure, when a content of Sb is 0.075, a volume fraction of rhombohedral represents 34%, a volume fraction of orthorhombic represents 33%, and a volume fraction of tetragonal represents 33%.

According to another embodiment of the present disclosure, when a content of Sb is 0.080, a volume fraction of rhombohedral represents 36%, a volume fraction of orthorhombic represents 19%, and a volume fraction of tetragonal represents 45%.

According to another embodiment of the present disclosure, when a content of Sb is 0.085, a volume fraction of rhombohedral represents 36%, and a volume fraction of tetragonal represents 64%.

According to another embodiment of the present disclosure, when a content of Sb is 0.090, a volume fraction of rhombohedral represents 18%, a volume fraction of orthorhombic represents 35%, and a volume fraction of tetragonal represents 47%.

According to another embodiment of the present disclosure, when a content of Sb is 0.100, a volume fraction of cubic represents 100%.

Therefore, in an embodiment of the present disclosure, it has been confirmed that a volume fraction of tetragonal increases as a content of Sb increases to 0.040 to 0.085. Also, in an embodiment of the present disclosure, when a content of Sb is 0.040 to 0.060, it has been confirmed that a structure where orthorhombic, rhombohedral, and tetragonal phases are provided together is implemented and a volume fraction of each of orthorhombic and rhombohedral is 80% or more.

According to an embodiment of the present disclosure, when a content of Sb is 0.085, it has been confirmed that phase transition to orthorhombic is omitted and a structure where a rhombohedral phase and a tetragonal phase are provided together is implemented.

According to an embodiment of the present disclosure, when a content of Sb is 0.090, it has been confirmed that phase transition to orthorhombic is omitted and a structure where a rhombohedral phase, a tetragonal phase, and a cubic phase are provided together is implemented.

According to an embodiment of the present disclosure, when a content of Sb is 0.100, it has been confirmed that a cubic phase is 100%.

FIG. 41 is a graph showing a density (%), a dielectric constant ε^{T}₃₃/ε₀, a loss factor tan δ, an electromechanical coupling factor k_{ρ}, and a piezoelectric charge constant d₃₃ with respect to a content of Sb of a TGG composition according to an embodiment of the present disclosure.

The inventors have measured a piezoelectric charge constant d₃₃ based on a variation of Sb in Equation 2 described above with reference to FIG. 2, so as to analyze a piezoelectric charge constant d₃₃ based on an Sb content of a TGG piezoelectric material composition. A composition of a TGG piezoelectric material composition may be 0.96(Na_{0.5}K_{0.5})(Nb_{0.93}Sb_{0.07})-(0.04-x)CaZrO₃-x(Bi_{0.5}Ag_{0.5})+0.5 mol % Fe₂O₃+3 mol % NaNbO₃, and a sample has been prepared through sintering performed for 6 hours at 1,090° C. A sintering temperature and a maintenance time do not limit details of the present disclosure. In a composition of a TGG piezoelectric material, a BAZ content has been prepared to have 0.03 (x=0.03). In the composition of the TGG piezoelectric material, a content of Sb may be set to each of 0.040, 0.050, 0.060, 0.070, 0.080, 0.090, and 0.100.

With reference to FIG. 41, a relative density (%) according to an embodiment of the present disclosure represents a value of 94% or more in samples where Sb contents are 0.040, 0.050, 0.060, 0.070, 0.080, 0.090, and 0.100. A relative density (%) according to an embodiment of the present disclosure represents 93.8%, 93.6%, 94.1%, 93.7%, 93.9%, 93.1%, and 92.9% in samples where Sb contents are 0.040, 0.050, 0.060, 0.070, 0.080, 0.090, and 0.100, respectively. Accordingly, in a density (%), it has been confirmed that a variation based on an increase in Sb content is not observed.

A dielectric constant ε^{T}₃₃/ε₀ represents values of 1294, 1598, 1828, 2680, 3443, 4891, and 5187 in samples where Sb contents are 0.040, 0.050, 0.060, 0.070, 0.080, 0.090, and 0.100, respectively. Accordingly, in an embodiment of the present disclosure, it has been confirmed that a dielectric constant increases as a content of Sb increases. Also, in another embodiment of the present disclosure, it has been confirmed that a dielectric constant is capable of being controlled based on a content of Sb.

A loss factor tan δ represents values of 0.021, 0.035, 0.041, 0.046, 0.053, 0.075, and 0.071 in samples where Sb contents are 0.040, 0.050, 0.060, 0.070, 0.080, 0.090, and 0.100, respectively. Accordingly, in another embodiment of the present disclosure, it has been confirmed that a loss factor tan δ increases as a content of Sb increases. Also, when a content of Sb is 0.090 or more, it has been confirmed that a loss factor tan δ does not increase any longer.

An electromechanical coupling factor kρ represents values of 0.810, 0.800, 0.574, 0.458, 0.432, 0.356, and 0.241 in samples where Sb contents are 0.040, 0.050, 0.060, 0.070, 0.080, 0.090, and 0.100, respectively. It has been confirmed that an electromechanical coupling factor kρ according to another embodiment of the present disclosure decreases progressively as a content of Sb increases.

A piezoelectric charge constant d₃₃ represents values of 670 pC/N, 720 pC/N, 730 pC/N, 660 pC/N, 660 pC/N, 330 pC/N, and 160 pC/N in samples where Sb contents are 0.040, 0.050, 0.060, 0.070, 0.080, 0.090, and 0.100, respectively. When a content of Sb is 0.040 to 0.080, it has been confirmed that a piezoelectric charge constant d₃₃ represents a value of 660 pC/N or more. When a content of Sb is 0.055, it has been confirmed that a piezoelectric charge constant d₃₃ represents a highest value of 780 pC/N. However, when a content of Sb is 0.085, it has been confirmed that a piezoelectric charge constant d₃₃ is rapidly reduced.

Accordingly, according to another embodiment of the present disclosure, it has been confirmed that a TGG piezoelectric material composition has a piezoelectric characteristic which is enhanced compared to non-TGG, based on a content of Sb.

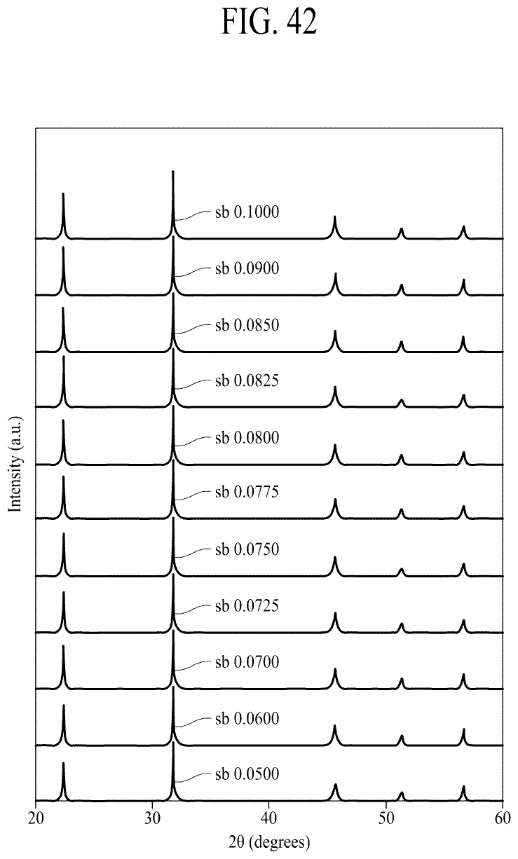

FIG. 42 is a graph showing an X-ray diffraction pattern with respect to a content of Sb of a TGG composition according to an embodiment of the present disclosure. In FIG. 42, a composition of a sample based on a variation of content of Sb has been prepared like the TGG piezoelectric material composition according to an embodiment of the present disclosure described above with reference to FIG. 41. In FIG. 42, intensity (a.u.) of the Y axis is a numerical value expressed as a relative value with respect to a maximum value of an X-ray diffraction pattern.

With reference to FIG. 42, even when an Sb content increases to 0.050, 0.060, 0.070, 0.0725, 0.075, 0.0775, 0.080, 0.825, 0.090, and 0.100, it has been confirmed that an X-ray diffraction pattern having the same grain growth orientation appears. Accordingly, in an embodiment of the present disclosure, it has been confirmed that an Sb content does not affect a grain growth orientation within a range of 0.050 to 0.100 and a dielectric constant is not controlled.

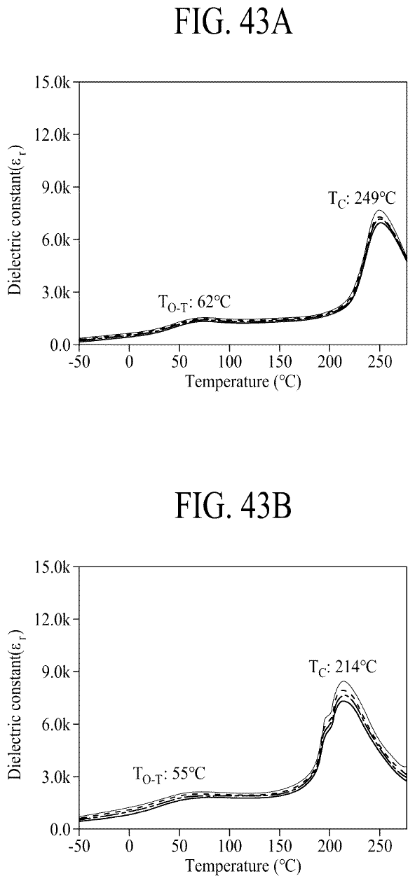

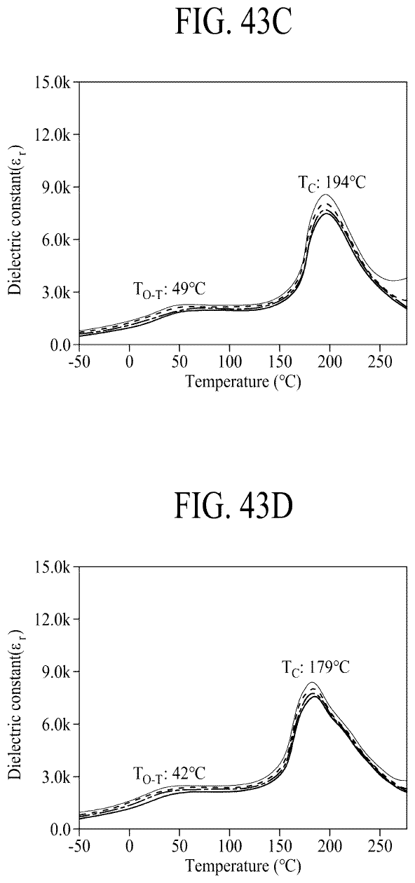

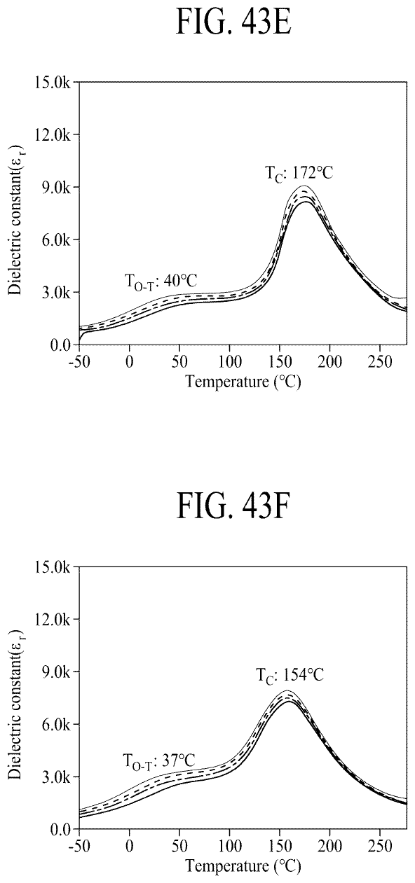

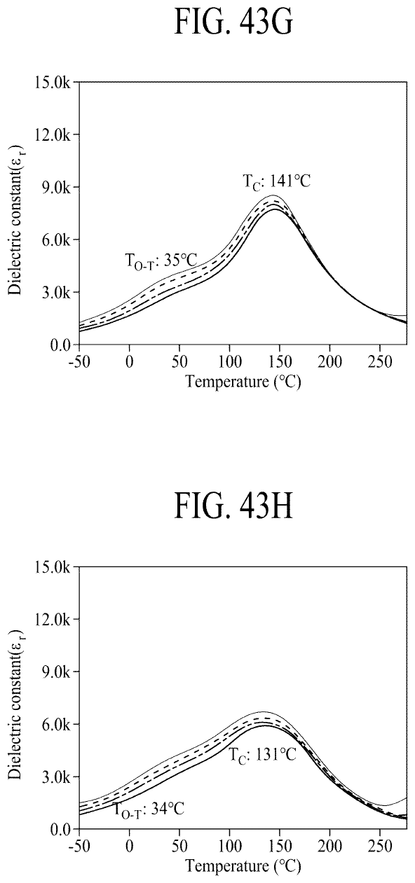

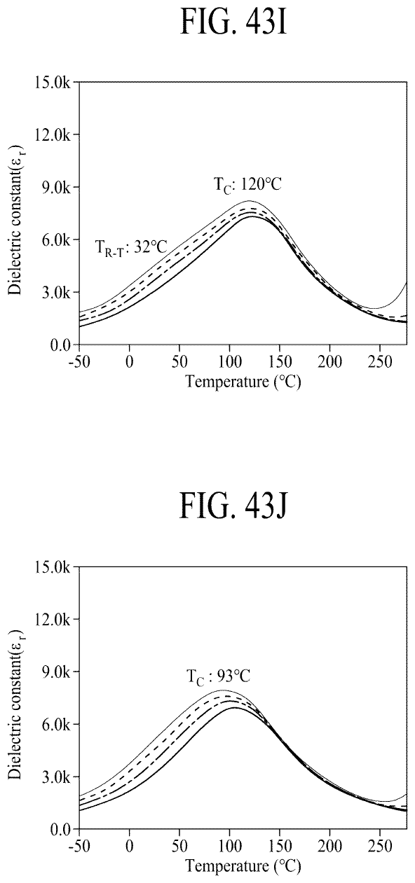

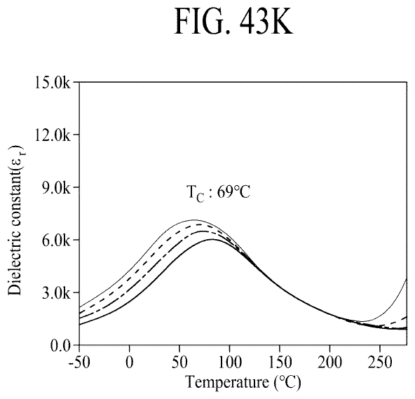

FIGS. 43A to 43K are temperature versus dielectric constant graphs with respect to a content of Sb according to an embodiment of the present disclosure. FIGS. 43A to 43K are temperature versus dielectric constant graphs with respect to a content of Sb of a TGG piezoelectric material composition according to an embodiment of the present disclosure. In FIGS. 43A to 43K, a composition of a sample based on a variation of content of Sb has been prepared like the TGG piezoelectric material composition according to an embodiment of the present disclosure described above with reference to FIG. 41. In FIGS. 43A to 43K, it has been confirmed that contents of Sb are 0.040, 0.050, 0.055, 0.060, 0.065, 0.070, 0.075, 0.080, 0.085, 0.090, and 0.100, respectively. T_{C} is a ferroelectric-paraelectric phase transition temperature (for example, a Curie temperature), and T_{O-T} and T_{R-T} are ferroelectric-ferroelectric phase transition temperature. In FIGS. 43A to 43K, a solid line represents a temperature versus dielectric constant graph in 100 Hz, a dotted line represents a temperature versus dielectric constant graph in 1 kHz, a dash-single dotted line represents a temperature versus dielectric constant graph in 10 kHz, and a thick solid line represents a temperature versus dielectric constant graph in 100 KHz.

In FIG. 43A, a content of Sb of a piezoelectric material composition is 0.040, a dielectric constant εᵣ slightly increases as a temperature increases, a dielectric constant εᵣ rapidly increases in 200° C. or more, and a dielectric constant εᵣ decreases as a temperature exceeds 249° C. According to an embodiment of the present disclosure, T_{O-T} of the piezoelectric material composition is 62° C., T_{C} is 249° C., and a dielectric constant εᵣ represents a value of about 7,397 in T_{C}. A change in temperature caused by a content of Sb of the piezoelectric material composition is similar in 100 Hz, 1 kHz, 10 kHz, and 100 kHz.

In FIG. 43B, a content of Sb of a piezoelectric material composition is 0.050, a dielectric constant εᵣ slightly increases as a temperature increases, a dielectric constant εᵣ rapidly increases in 170° C. or more, and a dielectric constant εᵣ decreases as a temperature exceeds 214° C. According to an embodiment of the present disclosure, T_{O-T} of the piezoelectric material composition is 55° C., T_{C} is 214° C., and a dielectric constant εᵣ represents a value of about 8,027 in T_{C}. A change in temperature caused by a content of Sb of the piezoelectric material composition is similar in 100 Hz, 1 kHz, 10 kHz, and 100 kHz.

In FIG. 43C, a content of Sb of a piezoelectric material composition is 0.055, a dielectric constant εᵣ slightly increases as a temperature increases, a dielectric constant εᵣ rapidly increases in 170° C. or more, and a dielectric constant εᵣ decreases as a temperature exceeds 194° C. According to an embodiment of the present disclosure, T_{O-T} of the piezoelectric material composition is 49° C., T_{C} is 194° C., and a dielectric constant εᵣ represents a value of about 8,104 in T_{C}. A change in temperature caused by a content of Sb of the piezoelectric material composition is similar in 100 Hz, 1 kHz, 10 kHz, and 100 KHz.

In FIG. 43D, a content of Sb of a piezoelectric material composition is 0.060, a dielectric constant εᵣ slightly increases as a temperature increases, a dielectric constant εᵣ rapidly increases in 150° C. or more, and a dielectric constant εᵣ decreases as a temperature exceeds 179° C. According to an embodiment of the present disclosure, T_{O-T} of the piezoelectric material composition is 42° C., T_{C} is 179° C., and a dielectric constant εᵣ represents a value of about 7,975 in T_{C}. A change in temperature caused by a content of Sb of the piezoelectric material composition is similar in 100 Hz, 1 kHz, 10 kHz, and 100 KHz.

In FIG. 43E, a content of Sb of a piezoelectric material composition is 0.065, a dielectric constant εᵣ slightly increases as a temperature increases, a dielectric constant εᵣ rapidly increases in 150° C. or more, and a dielectric constant εᵣ decreases as a temperature exceeds 172° C. According to an embodiment of the present disclosure, T_{O-T} of the piezoelectric material composition is 40° C., T_{C} is 172° C., and a dielectric constant εᵣ represents a value of about 8,732 in T_{C}. A change in temperature caused by a content of Sb of the piezoelectric material composition is similar in 100 Hz, 1 kHz, 10 kHz, and 100 KHz.

In FIG. 43F, a content of Sb of a piezoelectric material composition is 0.070, a dielectric constant εᵣ slightly increases as a temperature increases, a dielectric constant εᵣ rapidly increases in 110° C. or more, and a dielectric constant εᵣ decreases as a temperature exceeds 154° C. According to an embodiment of the present disclosure, T_{O-T} of the piezoelectric material composition is 37° C., T_{C} is 154° C., and a dielectric constant εᵣ represents a value of about 7,713 in T_{C}. A change in temperature caused by a content of Sb of the piezoelectric material composition is slightly reduced in 154° C. or less as a frequency increases to 100 Hz, 1 kHz, 10 KHz, and 100 kHz, but is similar in temperature which is higher than 154° C.

In FIG. 43G, a content of Sb of a piezoelectric material composition is 0.075, a dielectric constant εᵣ progressively increases as a temperature increases, and a dielectric constant εᵣ decreases as a temperature exceeds 141° C. According to an embodiment of the present disclosure, T_{O-T} of the piezoelectric material composition is 35° C., T_{C} is 141° C., and a dielectric constant εᵣ represents a value of about 8,306 in T_{C}. A change in temperature caused by a content of Sb of the piezoelectric material composition is slightly reduced in 150° C. or less as a frequency increases to 100 Hz, 1 KHz, 10 KHz, and 100 kHz, but is similar in temperature which is higher than 150° C.

In FIG. 43H, a content of Sb of a piezoelectric material composition is 0.080, a dielectric constant εᵣ progressively increases as a temperature increases, and a dielectric constant εᵣ decreases as a temperature exceeds 131° C. According to an embodiment of the present disclosure, T_{O-T} of the piezoelectric material composition is 34° C., T_{C} is 131° C., and a dielectric constant εᵣ represents a value of about 6,397 in T_{C}. A change in temperature caused by a content of Sb of the piezoelectric material composition is reduced in 150° C. or less as a frequency increases to 100 Hz, 1 kHz, 10 kHz, and 100 kHz, but is similar in temperature which is higher than 150° C.

In FIG. 43I, a content of Sb of a piezoelectric material composition is 0.085, a dielectric constant εᵣ progressively increases as a temperature increases, and a dielectric constant εᵣ decreases as a temperature exceeds 120° C. According to an embodiment of the present disclosure, when a content of Sb of the piezoelectric material composition is 0.085, there is no T_{O-T}, T_{R-T} is 32° C., T_{C} is 120° C., and a dielectric constant εᵣ represents a value of about 7,828 in T_{C}. A change in temperature caused by a content of Sb of the piezoelectric material composition is reduced in 120° C. or less as a frequency increases to 100 Hz, 1 kHz, 10 KHz, and 100 kHz, but is similar in temperature which is higher than 120° C.

In FIG. 43J, a content of Sb of a piezoelectric material composition is 0.090, a dielectric constant εᵣ progressively increases as a temperature increases, and a dielectric constant εᵣ decreases as a temperature exceeds 93° C. According to an embodiment of the present disclosure, there is no T_{O-T} of the piezoelectric material composition, T_{C} is 93° C., and a dielectric constant εᵣ represents a value of about 7,626 in T_{C}. A change in temperature caused by a content of Sb of the piezoelectric material composition is reduced in 100° C. or less as a frequency increases to 100 Hz, 1 kHz, 10 kHz, and 100 kHz, but is similar in temperature which is higher than 100° C.

In FIG. 43K, a content of Sb of a piezoelectric material composition is 0.100, a dielectric constant εᵣ progressively increases as a temperature increases, and a dielectric constant εᵣ decreases as a temperature exceeds 69° C. According to an embodiment of the present disclosure, there is no T_{O-T} of the piezoelectric material composition, T_{C} is 69° C., and a dielectric constant εᵣ represents a value of about 7,230 in T_{C}. A change in temperature caused by a content of Sb of the piezoelectric material composition is reduced in 80° C. or less as a frequency increases to 100 Hz, 1 kHz, 10 KHz, and 100 kHz, but is similar in temperature which is higher than 80° C.

According to an embodiment of the present disclosure, it has been confirmed that a content of Sb of a piezoelectric material composition is adjusted to a range of 0.040 to 0.100, and thus, a dielectric constant of the piezoelectric material composition is controllable.

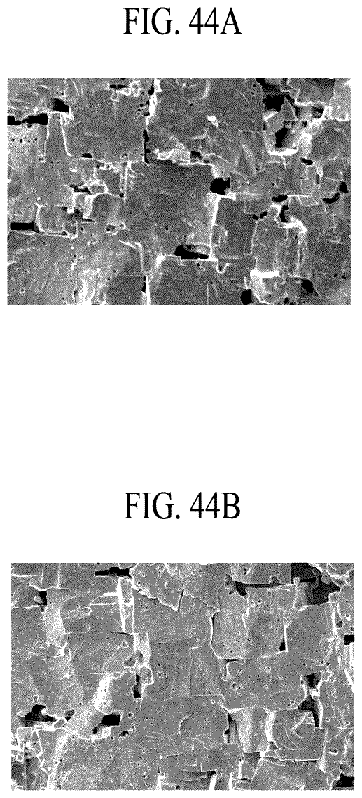

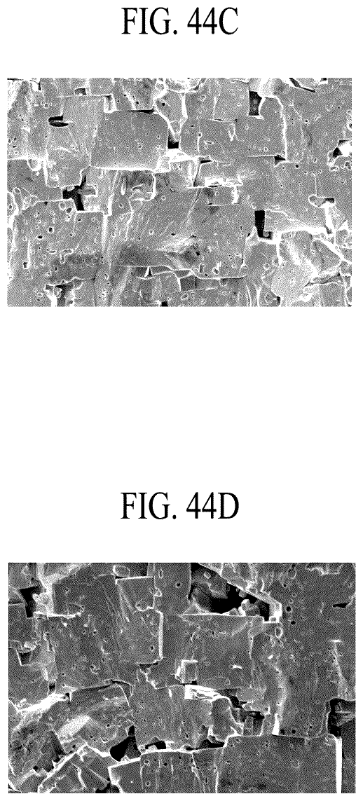

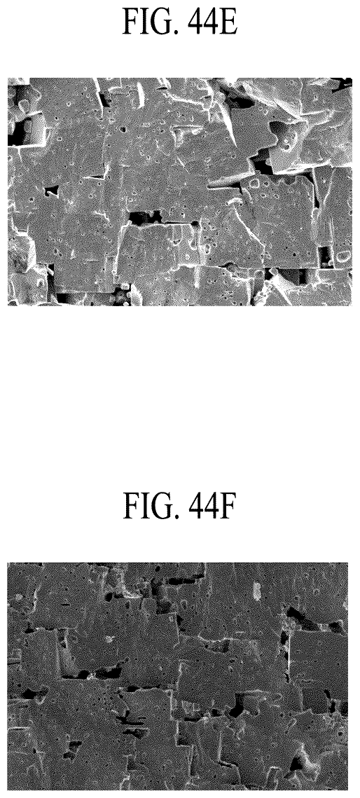

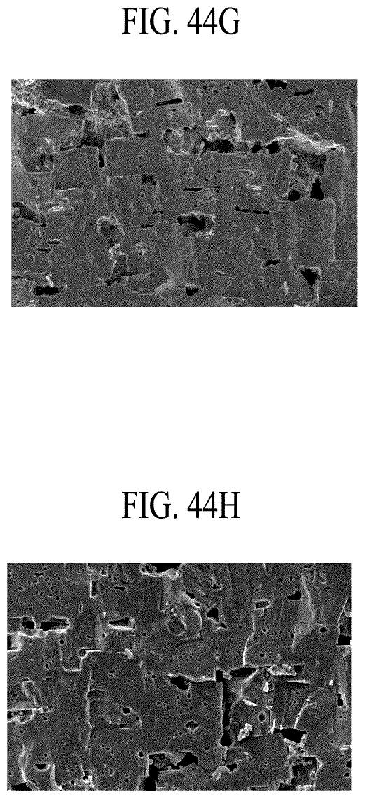

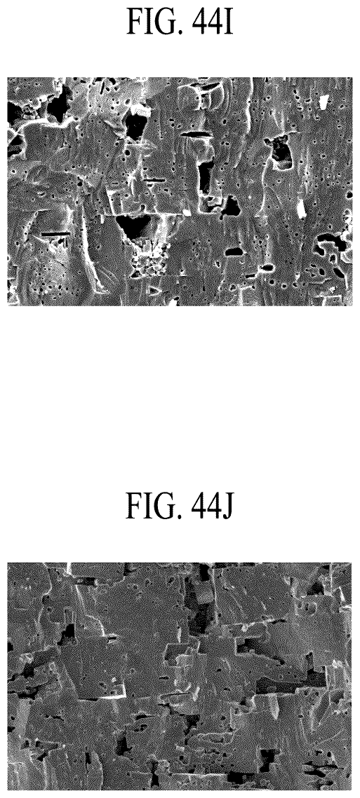

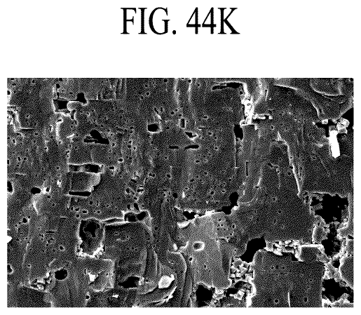

FIGS. 44A to 44K illustrate a microstructure of a piezoelectric material composition based on a content of Sb according to an embodiment of the present disclosure. This illustrates a microstructure of a piezoelectric material composition based on a content of Sb of a TGG piezoelectric material composition according to an embodiment of the present disclosure. In FIGS. 44A to 44K, a composition of a sample based on a variation of content of Sb has been prepared like the TGG piezoelectric material composition according to an embodiment of the present disclosure described above with reference to FIG. 41. In FIGS. 44A to 44K, it has been confirmed that contents of Sb are 0.040, 0.050, 0.055, 0.060, 0.065, 0.070, 0.075, 0.080, 0.085, 0.090, and 0.100, respectively.

With reference to FIGS. 44A to 44K, when a content of Sb is 0.040 to 0.100, it has been confirmed that a size of each of most grains is 35 μm to 40 μm. Accordingly, according to an embodiment of the present disclosure, in a piezoelectric material composition, it has been confirmed that a size of a grain is not changed based on a content of Sb. According to an embodiment of the present disclosure, it has been confirmed that a content of Sb of the piezoelectric material composition does not affect a grain size.

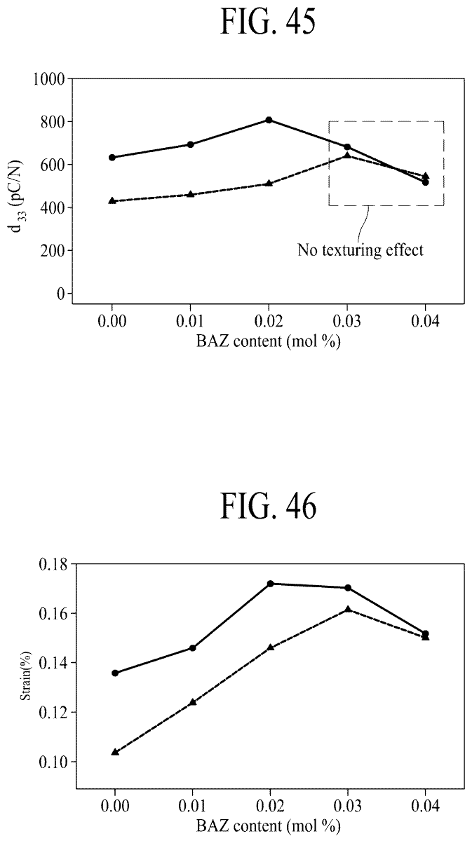

FIG. 45 is a graph showing a piezoelectric charge constant d₃₃ of each of a TGG composition and a non-TGG composition based on a BAZ content according to an embodiment of the present disclosure. In FIG. 45, a dotted line represents a piezoelectric charge constant d₃₃ of non-TGG, and a solid line represents a piezoelectric charge constant d₃₃ of TGG. TGG is data of a sample on which a TGG process has been performed, and non-TGG is data of a sample on which a grain growth process has been randomly performed without using an NN seed.

The inventors have measured a piezoelectric charge constant d₃₃ of a piezoelectric material composition based on a BAZ content of each of a sample on which a TGG process has been performed by an NN seed and a sample which is randomly grain-grown without using an NN seed, so as to optimize a TGG process. In FIG. 45, samples for analyzing an X-ray diffraction pattern based on each BAZ content have been prepared like FIG. 25. In FIG. 45, BAZ contents of samples are 0.00, 0.01, 0.02, 0.03, and 0.04.

With reference to FIG. 45, in a piezoelectric charge constant d₃₃ of a sample (or non-TGG) which does not use an NN seed, measurement values of the piezoelectric charge constant d₃₃ based on BAZ contents of 0.00, 0.01, 0.02, 0.03, and 0.04 represent 425 pC/N, 460 pC/N, 506 pC/N, 640 pC/N, and 540 pC/N, respectively. According to a measurement result of a sample (or non-TGG) which is randomly grain-grown, a piezoelectric charge constant d₃₃ increases as a BAZ content increases to 0.00, 0.01, 0.02, and 0.03. However, when a BAZ content is 0.04, a piezoelectric charge constant d₃₃ decreases again.

In a piezoelectric charge constant d₃₃ of a sample (or TGG sample) on which a TGG process has been performed by an NN seed, values of the piezoelectric charge constant d₃₃ based on BAZ contents of 0.00, 0.01, 0.02, 0.03, and 0.04 have been measured to be 630 pC/N, 690 pC/N, 805 pC/N, 680 pC/N, and 520 pC/N, respectively. According to a measurement result of a sample (or TGG) on which a TGG process has been performed by an NN seed, a piezoelectric charge constant d₃₃ increases as a BAZ content increases to 0.00, 0.01, and 0.02. However, as a BAZ content increases to 0.03 and 0.04, a piezoelectric charge constant d₃₃ decreases again. Accordingly, as a BAZ content increases to 0.03 and 0.04, it has been confirmed that a texturing effect is not obtained.

According to an embodiment of the present disclosure, when a BAZ content is 0.02, it has been confirmed that a piezoelectric material composition has a good piezoelectric characteristic. Also, according to an embodiment of the present disclosure, when a TGG process is performed on the piezoelectric material composition, it has been confirmed that a piezoelectric characteristic is better than a case where a TGG process is not performed (or non-TGG). Accordingly, according to an embodiment of the present disclosure, when a BAZ content is 0.02, the piezoelectric material composition has a high piezoelectric charge constant d₃₃, it has been confirmed that an optimal matrix composition having a high piezoelectric characteristic is implemented.

According to an embodiment of the present disclosure, in a piezoelectric material composition, it has been confirmed that a piezoelectric characteristic is enhanced by performing a TGG process with an NN seed.

FIG. 46 is a graph showing a strain of each of a TGG composition and a non-TGG composition based on a BAZ content according to an embodiment of the present disclosure.

The inventors have measured a strain of a piezoelectric material composition based on a BAZ content, so as to optimize a TGG process. Samples for measuring a strain of a piezoelectric material composition based on a BAZ content have been prepared like FIG. 25. In FIG. 46, a dotted line represents a strain based on a BAZ content of a non-TGG composition, and a solid line represents a strain based on a BAZ content of a TGG composition. In FIG. 46, BAZ contents of samples are 0.00, 0.01, 0.02, 0.03, and 0.04, respectively.

With reference to FIG. 46, according to a measurement result before TGG, strains respectively based on BAZ contents of 0.00, 0.01, 0.02, 0.03, and 0.04 represent 0.104%, 0.124%, 0.146%, 0.161%, and 0.150%, respectively. According to the measurement result before TGG, it has been confirmed that a strain increases as a BAZ content increases to 0.00 to 0.03. However, when a BAZ content is 0.04, a strain decreases again.

According to a measurement result after TGG, strains respectively based on BAZ contents of 0.00, 0.01, 0.02, 0.03, and 0.04 represent 0.136%, 0.146%, 0.172%, 0.170%, and 0.152%, respectively. According to the measurement result after TGG, it has been confirmed that a strain increases as a BAZ content increases to 0.00 to 0.02. However, as a BAZ content increases to 0.03 and 0.04, a strain decreases again.

Therefore, in an embodiment of the present disclosure, when a BAZ content is 0.02, it has been confirmed that a piezoelectric charge constant d₃₃ before TGG and a strain after TGG increase largest. Therefore, in an embodiment of the present disclosure, when a BAZ content is 0.02, it has been confirmed that a good piezoelectric characteristic is implemented. Also, in an embodiment of the present disclosure, when a TGG process is performed, it has been confirmed that a better piezoelectric characteristic is realized. Accordingly, in an embodiment of the present disclosure, when a BAZ content is 0.02, it has been confirmed that an optimal matrix composition having a high strain and a high piezoelectric characteristic is implemented.

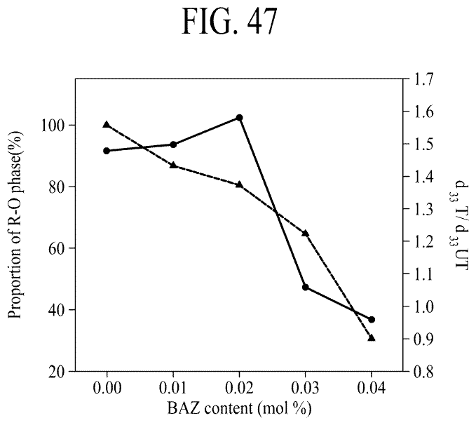

FIG. 47 is a graph showing a ratio of a piezoelectric charge constant and a ratio of an R-O phase structure of each of a TGG composition and a non-TGG composition based on a BAZ content according to an embodiment of the present disclosure. In FIG. 47, a dotted line represents a ratio (d₃₃^{T}/d₃₃^{UT}) of a piezoelectric charge constant of TGG to non-TGG, and a solid line represents a ratio (%) of an R-O phase structure of TGG to an R-O phase structure of non-TGG.

The inventors have measured a ratio (%) of an R-O phase structure based on a BAZ content and a ratio (d₃₃^{T}/d₃₃^{UT}) of a piezoelectric charge constant before and after orientation, so as to optimize TGG. In FIG. 47, samples for analyzing a ratio (%) of an R-O phase structure based on a BAZ content and a ratio (d₃₃^{T}/d₃₃^{UT}) of a piezoelectric charge constant before and after TGG have been prepared like FIG. 25. In FIG. 47, BAZ contents of samples are 0.00, 0.01, 0.02, 0.03, and 0.04, respectively.

With reference to FIG. 47, when BAZ contents are 0.00, 0.01, 0.02, 0.03, and 0.04, ratios of an R-O phase structure according to an embodiment of the present disclosure represent values of 100%, 87.38%, 80.73%, 66.91%, and 30.18%, respectively. According to an embodiment of the present disclosure, it has been confirmed that a ratio of an R-O phase structure decreases as a BAZ content increases.

According to an embodiment of the present disclosure, comparing with a case where a BAZ content is 0.00, when a BAZ content increases to 0.01 and 0.02, a ratio (d₃₃^{T}/d₃₃^{UT}) of a piezoelectric charge constant before and after TGG increases. For example, when a BAZ content is 0.02, it has been confirmed that a ratio (d₃₃^{T}/d₃₃^{UT}) of a piezoelectric charge constant before and after TGG has a highest value of 100 or more. However, as a BAZ content increases to 0.03 and 0.04, a ratio (d₃₃^{T}/d₃₃^{UT}) of a piezoelectric charge constant before and after TGG decreases rapidly.

In an embodiment of the present disclosure, when a BAZ content is 0.02, it has been confirmed that a good piezoelectric characteristic is implemented. Also, in an embodiment of the present disclosure, when a ratio of an R-O phase structure is 80% or more, it has been confirmed that a good piezoelectric characteristic is realized. Accordingly, in an embodiment of the present disclosure, when a BAZ content is 0.02, it has been confirmed that an optimal matrix composition having a high piezoelectric characteristic and a high piezoelectric charge constant d₃₃ is implemented.

According to an embodiment of the present disclosure, in a case where a piezoelectric material composition uses a TGG process, this is effective in an R-O structure, and for example, when a volume fraction of tetragonal is about 20%, it has been confirmed that the piezoelectric material composition has a best piezoelectric charge constant. When a volume fraction of tetragonal having a polarization direction toward a (001) orientation is about 20%, it has been confirmed that a piezoelectric charge constant d₃₃ decreases.

Also, it has been confirmed that a piezoelectric charge constant d₃₃ of a piezoelectric material composition according to an embodiment of the present disclosure is higher in a sample (or TGG), on which a TGG process has been performed, than a sample (or non-TGG) on which a TGG process is not performed.

In an embodiment of the present disclosure, it has been confirmed that a piezoelectric characteristic is enhanced by performing TGG.

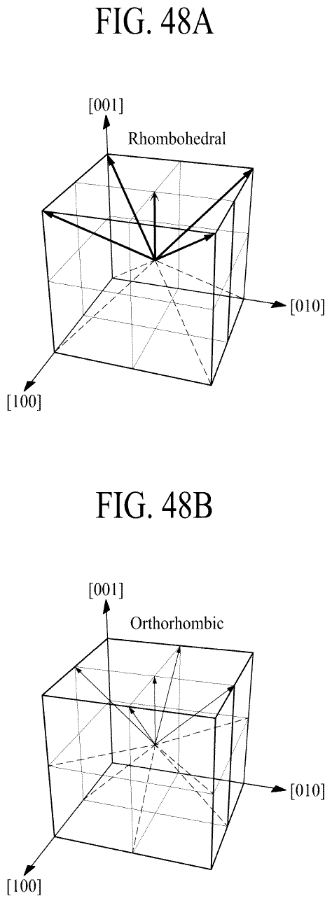

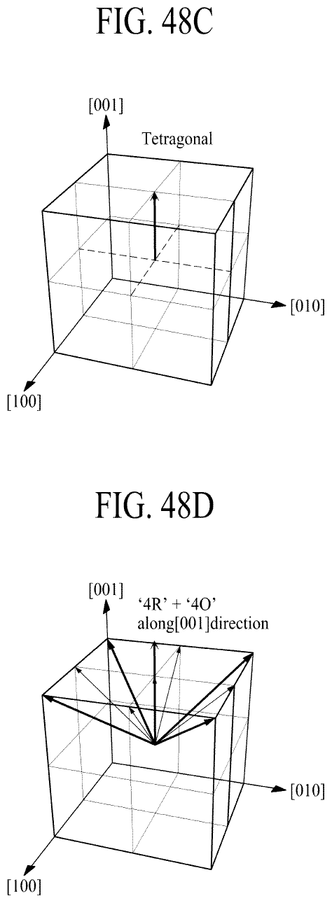

FIGS. 48A to 48D illustrate a direction of orientation with respect to the kind of phase. FIG. 48A shows a direction of orientation of polarization in a (001) orientation of a rhombohedral (R) structure, FIG. 48B shows a direction of orientation of polarization in a (001) orientation of an orthorhombic (O) structure, FIG. 48C shows a direction of orientation of polarization in a (001) orientation of a tetragonal (T) structure, and FIG. 48D shows a direction of orientation of mixed polarization in a (001) orientation of R-O-T 3-phase structure.

With reference to FIG. 48A, a direction of orientation of polarization of R of an R phase is (111). For example, even when a grain is orientation-grown in a (001) orientation, a unit cell configuring the grain is an R phase, and thus, a polarization orientation of R maintains (111) and polarization of R toward a vertex of a lattice is aligned. In this case, orientations capable of being aligned are four orientations, and polarizations of R in four orientations have free energy which is thermodynamically equal.

With reference to FIG. 48B, a direction of orientation of polarization of O of an O phase is (110). For example, even when a grain is orientation-grown in a (001) orientation, a unit cell configuring the grain is an O phase, and thus, a polarization orientation of O maintains (110) and polarization of O toward a vertex of a lattice is aligned. In this case, orientations capable of being aligned are four orientations, and polarizations of O in four orientations have free energy which is thermodynamically equal.

With reference to FIG. 48C, a direction of orientation of polarization of T of a T phase is (001). For example, even when a grain is orientation-grown in a (001) orientation, a unit cell configuring the grain is a T phase, and thus, a polarization orientation of O maintains (110) and polarization of T is aligned in the same orientation as a growth orientation of a lattice. In this case, an orientation capable of being aligned is one orientation and has the same alignment orientation as a non-TGG according to an embodiment of the present disclosure. Accordingly, when a volume fraction of a T phase increases, it may be difficult to realize an effect of TGG.

With reference to FIG. 48D, a direction of orientation of polarization represents a direction of orientation of polarization when all phases of a R-O-T 3-phase structure are provided together.

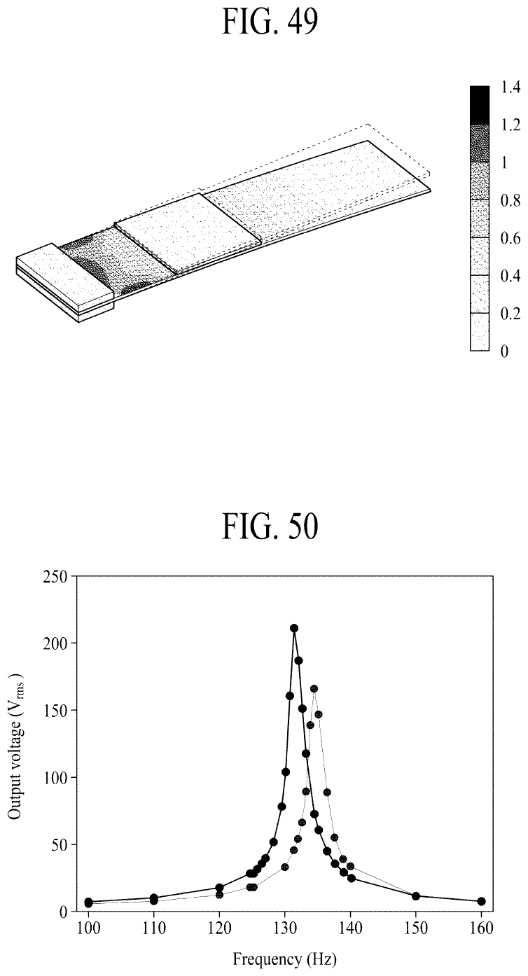

FIG. 49 illustrates a comsol driving simulation result of an energy harvester EH of each of a TGG composition and a non-TGG composition according to an embodiment of the present disclosure. FIG. 49 shows data obtained by simulating an energy harvester structure of a cantilever type. In FIG. 49, red appears in a direction toward 1.4, and blue appears in a direction toward 0). Red represents a clamped region, and an acceleration force of the clamped region is 1G. For example, when an acceleration force of 1G is applied to the clamped region, a simulation has been performed in an off-resonance frequency (@132 Hz) where the amount of tip displacement is largest in a corresponding harvester. That is, this is a result obtained by simulating a stress of an energy harvester when a simulation is performed under a condition where 132 Hz and 1G are set.

With reference to FIG. 49, in an energy harvester according to an embodiment of the present disclosure, it may be seen that a stress is applied to a piezoelectric device and is not applied to a cantilever tip portion. The piezoelectric device may be a square portion of the drawing, and the cantilever tip portion may be an end portion of the energy harvester which is not bound with a clamp.

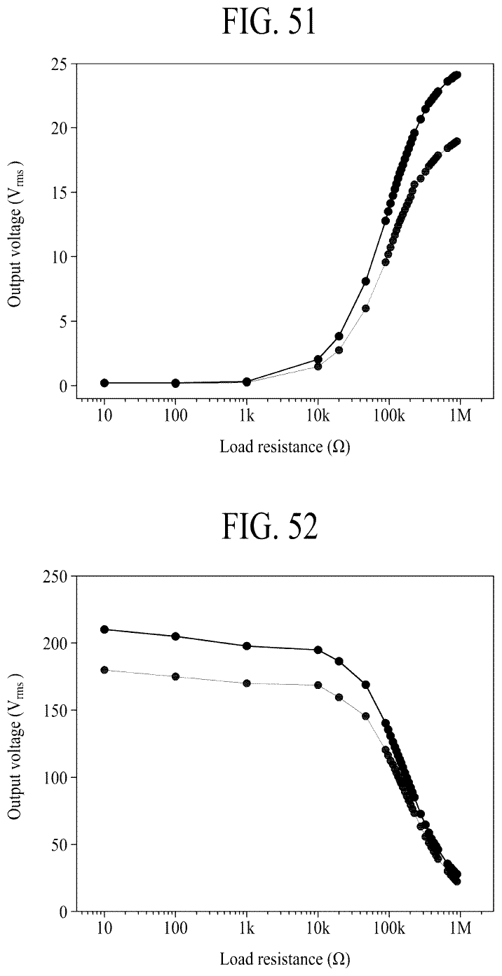

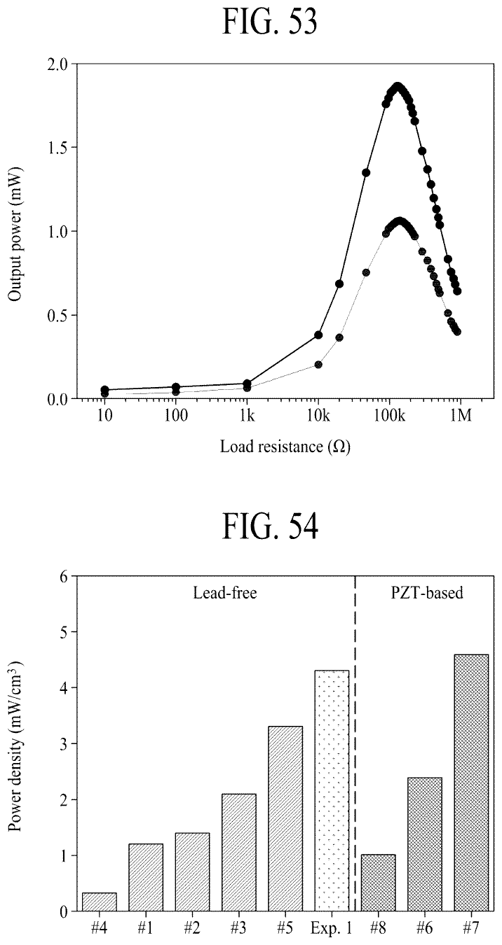

FIG. 50 illustrates a frequency versus output voltage graph of an energy harvester EH of each of a TGG composition and a non-TGG composition according to an embodiment of the present disclosure. FIG. 51 illustrates a load resistance versus output voltage graph of an energy harvester EH of each of a TGG composition and a non-TGG composition according to an embodiment of the present disclosure. FIG. 52 illustrates a load resistance versus output current graph of an energy harvester EH of each of a TGG composition and a non-TGG composition according to an embodiment of the present disclosure. FIG. 53 illustrates a load resistance versus output power graph of an energy harvester EH of each of a TGG composition and a non-TGG composition according to an embodiment of the present disclosure. In FIGS. 50 to 53, a dotted line represents a measurement value of a non-TGG composition, and a solid line represents a measurement value of a TGG composition. In FIGS. 50 to 53, each sample has been prepared like FIGS. 27A and 27B, and a BAZ content has been set to 0.02. In FIGS. 50 to 53, a thick solid line represents a graph of a TGG composition, and a thin solid line represents a graph of a non-TGG composition.

With reference to FIG. 50, it may be seen that an energy harvester EH of a non-TGG composition according to an embodiment of the present disclosure represents an output voltage of 17 Vᵣₘₛ in 134 Hz, and an energy harvester EH of a TGG composition according to an embodiment of the present disclosure represents an output voltage of 22 Vᵣₘₛ in 131 Hz. For example, the reason that a slight difference (˜3 Hz) between off-resonance frequencies occurs in TGG and non-TGG samples may be because there is a possibility that the energy harvesters are not manufactured in completely the same energy harvester structure because the energy harvesters are manufactured in a laboratory environment. As another example, this may be because the TGG sample is lower in hardness than the non-TGG sample.

With reference to FIG. 51, an output voltage of each of energy harvesters EH manufactured with a non-TGG composition and a TGG composition according to an embodiment of the present disclosure increases as a load resistance increases. For example, an output voltage has been measured in a non-resonance frequency of 200 Hz. For example, an output voltage of each energy harvester EH manufactured with the TGG composition represents a value which is greater than an output voltage of each energy harvester EH manufactured with the non-TGG composition. For example, an output voltage of each of energy harvesters EH manufactured with the non-TGG composition and the TGG composition according to an embodiment of the present disclosure increases rapidly in 10 kΩ.

With reference to FIG. 52, an output current of each of energy harvesters EH manufactured with a non-TGG composition and a TGG composition according to an embodiment of the present disclosure represents a high value of 150 μA or more within a range of 10 92 to 30 kΩ and decreases rapidly after 30 kΩ. For example, an output current of each energy harvester EH manufactured with the TGG composition represents a value which is greater than an output current of each energy harvester EH manufactured with the non-TGG composition.

With reference to FIG. 53, an output power of each of energy harvesters EH manufactured with a non-TGG composition and a TGG composition according to an embodiment of the present disclosure represents a value of each of 1.9 mW and 1.1 mW in 100 kΩ. For example, an output power of the energy harvester EH manufactured with the TGG composition represents a value which is greater than an output power of the energy harvester EH manufactured with the non-TGG composition.

FIG. 54 illustrates an output power of each of an energy harvester EH according to a comparative example and an energy harvester EH according to an embodiment of the present disclosure. In FIG. 54, an energy harvester EH according to an embodiment of the present disclosure has been prepared like FIG. 27B, a TGG composition has been used, and a BAZ content has been set to 0.02. In FIG. 54, comparative examples 1 to 8 (#1 to #8) have used energy harvesters including a composition such as Mn-KNN(#4), CuO-KNN(#1), CuO-BCTZ(#2), BCSTZ(#3), CT-KNN-LS(#5), Mn-PZT-PZN(#8), PZT-PZN(#6), and PZT-5H(#7). For example, a Mn-KNN(#4) sample may include a (K, Na)NbO₃ (or KNN) piezoelectric device to which Mn is added, and a CuO-KNN sample may include a (K, Na)NbO₃ (or KNN) piezoelectric device to which CuO is added. For example, a CuO-BCTZ sample may include (Ba, Ca)(Ti, Zr)O₃ (or BCTZ) ceramic to which CuO is added, a BCSTZ sample may include a (Ba, Ca, Sr)(Ti, Zr)O₃ piezoelectric device, and a CT-KNN-LS sample may include a (K, Na)NbO₃-LiSbO₃ (or KNN-LS) piezoelectric device to which CaTiO₃ is added. For example, a Mn-PZT-PZN sample may include a Pb(Zr, Ti)O₃-Pb(ZnNb)O₃ (or PZT-PZN) piezoelectric device to which Mn is added, and a PZT-PZN sample may include a Pb(Zr, Ti)O₃-Pb(ZnNb)O₃ (or PZT-PZN) piezoelectric device. For example, a PZT-5H(Navy Type-VI) sample may include a piezoelectric device conforming with U.S. Navy standard based on Pb(Zr, Ti)O₃ (or PZT).

With reference to FIG. 54, an output power of an energy harvester (Exp. 1) according to an embodiment of the present disclosure is higher than an output power of each energy harvester EH including a Mn-KNN(#4) composition, a CuO-KNN(#1) composition, a CuO-BCTZ(#2) composition, a BCSTZ(#3) composition, a CT-KNN-LS(#5) composition, a Mn-PZT-PZN(#8) composition, and a PZT-PZN(#6) composition, which is a comparative example. Also, the output power of the energy harvester (Exp. 1) according to an embodiment of the present disclosure is higher than an output power of each energy harvester EH including a Mn-KNN(#4) composition, a CuO-KNN(#1) composition, a CuO-BCTZ(#2) composition, a BCSTZ(#3) composition, and a CT-KNN-LS(#5) composition, which are Pb-free materials in the comparative example. Accordingly, it has been confirmed that a piezoelectric material composition according to an embodiment of the present disclosure among Pb-free materials has a harvesting output power which is best.

Moreover, the output power of the energy harvester (Exp. 1) including a Pb-free material according to an embodiment of the present disclosure is higher than an output power of an energy harvester EH manufactured with a Mn-PZT-PZN(#8) composition and a PZT-PZN(#6) composition including Pb. Accordingly, it has been confirmed that a piezoelectric material composition according to an embodiment of the present disclosure has a harvesting output power which is better than the Mn-PZT-PZN(#8) composition and the PZT-PZN(#6) composition including Pb.

The following Table 1 is a table which shows an energy harvesting performance index (d·g(10⁻¹²·m²/N)), an electromechanical coupling factor k_{ρ}, and an off-resonance frequency fᵣ of each of the energy harvester (Exp. 1) according to an embodiment of the present disclosure and the energy harvesters (#1 to #8) according to the comparative examples.

TABLE 1

| | | | d₃₃ × | | |
|---|---|---|---|---|---|
| Materials | | | g₃₃(10-12 m²/N) | Kₚ | fᵣ |
| Lead- | Experimental | TGG KNN- | 29.5 | 0.64 | 130 |
| free | example | BZ-BAZ | | | |
| | Example 1 | CuO-KNN | 4.9 | 0.38 | 93 |
| | Example 2 | CuO-BCTZ | ~4.2 | — | 90 |
| | Example 3 | BCSTZ | 8.6 | 0.56 | 30 |
| | Example 4 | Mn-KNN | — | 0.37 | 90 |
| | Example 5 | CT-KNN-LS | — | — | 90-110 |
| PZT- | Example 6 | PZT-PZN | 25.2 | ~0.65 | 255-266 |
| based | Example 7 | PZT-5H | 20.5 | ~0.65 | 92 |
| | Example 8 | Mn-PZT-PZN | — | — | 100 |

With reference to Table 1, it has been confirmed that an energy harvesting performance index (d·g(10⁻¹²·m²/N)) of a KNNS-BZ-BAZ(x=0.02) composition, which is a TGG composition according to an embodiment of the present disclosure among Pb-free materials, is highest. Accordingly, comparing with Pb-free energy harvesters having an off-resonance frequency and a similar structure, it has been confirmed that an energy harvester according to an embodiment of the present disclosure has a harvesting output power which is best.

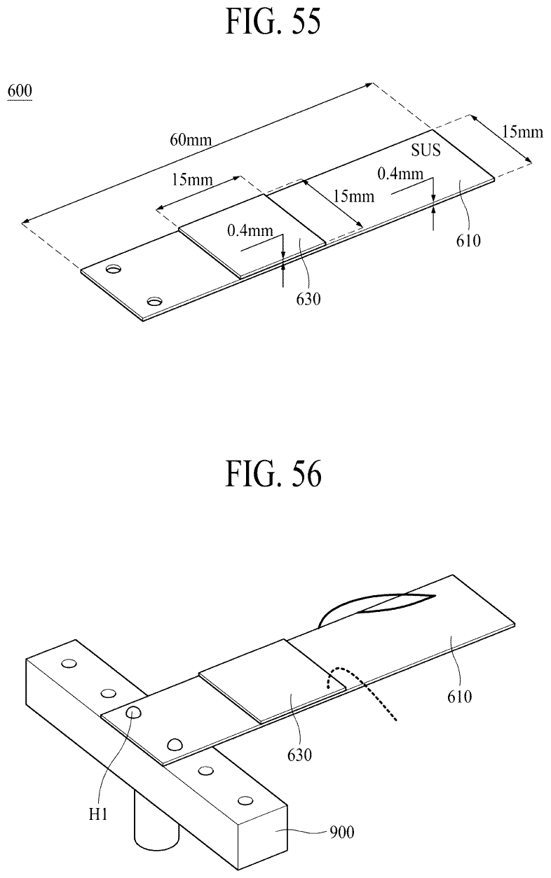

FIG. 55 illustrates an energy harvester EH according to an embodiment of the present disclosure. FIG. 56 illustrates an example where the energy harvester EH of FIG. 55 is mounted on a zig.

With reference to FIGS. 55 and 56, an energy harvester 600 according to an embodiment of the present disclosure has been prepared based on a cantilever type. The energy harvester 600 may include a plate 610 and a piezoelectric device 630. The plate 610 may be a metal plate such as nickel (Ni) or stainless steel (SUS), but embodiments of the present disclosure are not limited thereto. For example, a length of the plate 610 in a first direction (or an X-axis direction) and a length and a thickness of the plate 610 in a second direction (or a Y-axis direction) may be respectively prepared to be 60 mm, 15 mm, and 0.4 mm.

The piezoelectric device 630 may be provided at one surface of the plate 610. The piezoelectric device 630 may include a non-TGG composition expressed as Equation 1. The piezoelectric device 630 may be attached on an upper surface of the plate 610. For example, a length of the piezoelectric device 630 in the first direction (or the X-axis direction) and a length and a thickness of the piezoelectric device 630 in the second direction (or the Y-axis direction) may be respectively prepared to be 15 mm, 15 mm, and 0.4 mm. In FIGS. 55 and 56, a dotted line and a solid line may be power lines connected for evaluating a piezoelectric characteristic of the energy harvester 600.

The energy harvester 600 may be coupled to a zig 900. To this end, at least one hole H1 for facilitating a connection with the zig 900 may be formed in one end of the plate 610. Various characteristics of the piezoelectric device 630 may be measured by g the energy harvester 600 coupled to the zig 900.

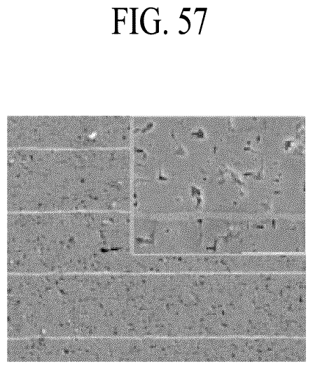

FIG. 57 is an image showing a break surface of a multi-layered actuator prepared based on a TGG composition according to an embodiment of the present disclosure. In FIG. 57, a thick portion may be a piezoelectric device layer, and a thin portion may be an electrode layer.

With reference to FIG. 57, in the multi-layered actuator prepared based on the TGG composition according to an embodiment of the present disclosure, a continuous interface image between the electrode layer and the piezoelectric device layer shows that the electrode layer is diffused to the piezoelectric device layer, or an element of the piezoelectric device layer is not diffused to the electrode layer. Accordingly, the TGG composition according to an embodiment of the present disclosure may be applied to the multi-layered actuator.

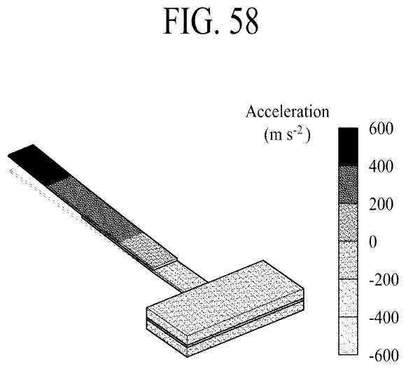

FIG. 58 illustrates a comsol driving simulation result of a multi-layered actuator MLA prepared based on each of a non-TGG composition and a TGG composition according to an embodiment of the present disclosure. In FIG. 58, red is shown as an acceleration is closer to 600 ms⁻², green is shown as an acceleration is closer to 0 ms⁻², and blue is shown as an acceleration is closer to −600 ms⁻². Red represents a clamped region, and an acceleration force of the clamped region is 1G. In FIG. 58, an off-resonance frequency of an actuator structure has been simulated to be 60 Hz.

With reference to FIG. 58, in the comsol driving simulation result of the multi-layered actuator MLA prepared based on the non-TGG composition and the TGG composition, it may be seen that an acceleration of the multi-layered actuator increases progressively in a direction distancing from the zig. For example, in an input signal of 60 Hz, when a sine wave signal of 50 V is applied in peak to peak, acceleration displacements of actuator tips in a TGG sample and a non-TGG sample have been simulated to be 4.4 mm and 3.3 mm. Accordingly, it may be seen that an acceleration displacement is greater in the TGG sample than the non-TGG sample.

Moreover, according to an embodiment of the present disclosure, it may be seen that an acceleration is large in a tip of an actuator, and it may be seen that an actuator tip strain occurs in only a z axis without an undesired strain such as a shear strain.

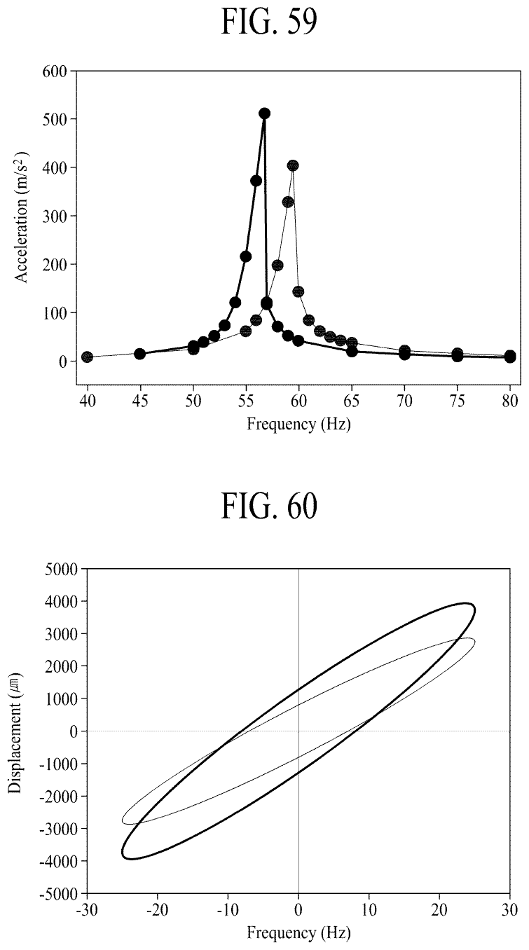

FIG. 59 illustrates a frequency versus acceleration graph of a multi-layered actuator MLA prepared based on a non-TGG composition and a TGG composition according to an embodiment of the present disclosure. In FIG. 59, a thin solid line represents a measurement value of a sample prepared based on a non-TGG composition, and a thick solid line represents a measurement value of a sample prepared based on a TGG composition. A composition of a sample of each actuator has been prepared like FIGS. 27A and 27B, and a BAZ content has been set to 0.02. Measurement has been performed at an end portion of an actuator.

With reference to FIG. 59, a multi-layered actuator MLA prepared based on each of a non-TGG composition and a TGG composition according to an embodiment of the present disclosure has a highest acceleration within a range of 55 Hz to 60 Hz. For example, the multi-layered actuator prepared based on the non-TGG composition according to an embodiment of the present disclosure has an acceleration of 400 m/s² or more in about 59.5 Hz. For example, the multi-layered actuator prepared based on the TGG composition according to an embodiment of the present disclosure has an acceleration of 500 m/s² or more in about 56.8 Hz. According to an embodiment of the present disclosure, an acceleration of the multi-layered actuator prepared based on the TGG composition has a value which is about 100 m/s² higher than that of the multi-layered actuator prepared based on the non-TGG composition, within a range of 55 Hz to 60 Hz. Accordingly, the multi-layered actuator manufactured based on the TGG composition may have an actuating acceleration which is higher than that of the multi-layered actuator manufactured based on the non-TGG composition.

FIG. 60 illustrates a displacement graph of a multi-layered actuator MLA prepared based on a non-TGG composition and a TGG composition according to an embodiment of the present disclosure. In FIG. 60, a thin solid line represents a measurement value of a sample prepared based on a non-TGG composition, and a thick solid line represents a measurement value of a sample prepared based on a TGG composition. A composition of a sample of each actuator has been prepared like FIGS. 27A and 27B, and a BAZ content has been set to 0.02. FIG. 60 is a graph showing a displacement when a voltage of 25 V is applied to a sample of each actuator.

With reference to FIG. 60, it has been confirmed that a displacement when a voltage of 25 V is applied to a sample of an actuator prepared based on a TGG composition is greater in displacement width than a displacement when a voltage of 25 V is applied to a sample of an actuator prepared based on a non-TGG composition.

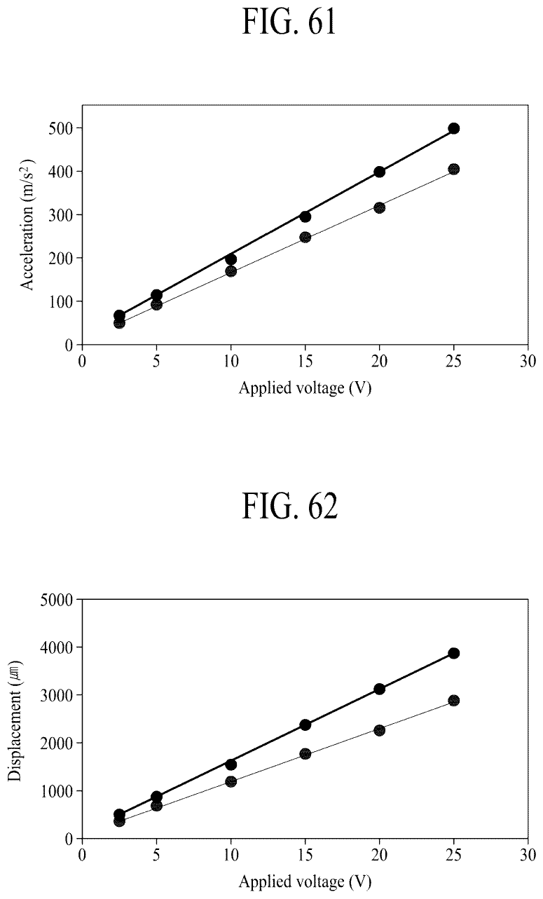

FIG. 61 illustrates a variation of an acceleration with respect to a voltage of a multi-layered actuator MLA prepared based on a non-TGG composition and a TGG composition according to an embodiment of the present disclosure. In FIG. 61, a thin solid line represents a measurement value of a sample prepared based on a non-TGG composition, and a thick solid line represents a measurement value of a sample prepared based on a TGG composition. A composition of a sample of each actuator has been prepared like FIGS. 27A and 27B, and a BAZ content has been set to 0.02.

With reference to FIG. 61, an acceleration of a multi-layered actuator MLA prepared based on each of a non-TGG composition and a TGG composition according to an embodiment of the present disclosure increases as a voltage increases. For example, in the same voltage, an acceleration of the multi-layered actuator prepared based on the TGG composition is greater than that of the multi-layered actuator prepared based on the non-TGG composition. For example, as a voltage increases, an increase rate of an acceleration of the multi-layered actuator prepared based on the TGG composition is higher than that of an acceleration of the multi-layered actuator prepared based on the non-TGG composition. For example, in a voltage of 25 V, an acceleration of the multi-layered actuator prepared based on the TGG composition is about 500 m/s², and an acceleration of the multi-layered actuator prepared based on the non-TGG composition is about 400 m/s². Therefore, in an acceleration based on an increase in voltage, it has been confirmed that the multi-layered actuator prepared based on the TGG composition is higher in value than the multi-layered actuator prepared based on the non-TGG composition. In all voltages, the multi-layered actuator manufactured based on the TGG composition may have an actuating acceleration which is higher than that of the multi-layered actuator manufactured based on the non-TGG composition.

FIG. 62 illustrates a variation of a displacement with respect to a voltage of a multi-layered actuator MLA prepared based on a non-TGG composition and a TGG composition according to an embodiment of the present disclosure. In FIG. 62, a thin solid line represents a measurement value of a sample prepared based on a non-TGG composition, and a thick solid line represents a measurement value of a sample prepared based on a TGG composition. A composition of a sample of each actuator has been prepared like FIGS. 27A and 27B, and a BAZ content has been set to 0.02.

With reference to FIG. 62, a displacement of a multi-layered actuator MLA prepared based on each of a non-TGG composition and a TGG composition according to an embodiment of the present disclosure increases as a voltage increases. For example, in the same voltage, a displacement of the multi-layered actuator prepared based on the TGG composition is greater than that of the multi-layered actuator prepared based on the non-TGG composition. For example, as a voltage increases, an increase rate of a displacement of the multi-layered actuator prepared based on the TGG composition is higher than that of a displacement of the multi-layered actuator prepared based on the non-TGG composition. For example, in a voltage of 25 V, a displacement of the multi-layered actuator prepared based on the TGG composition is about 4,000 μm, and a displacement of the multi-layered actuator prepared based on the non-TGG composition is about 3,000 μm. Therefore, in a displacement based on an increase in voltage, it has been confirmed that the multi-layered actuator prepared based on the TGG composition is higher in value than the multi-layered actuator prepared based on the non-TGG composition.

Accordingly, the multi-layered actuator manufactured based on the TGG composition may have an actuating displacement which is higher than that of the multi-layered actuator manufactured based on the non-TGG composition, with respect to all voltages.

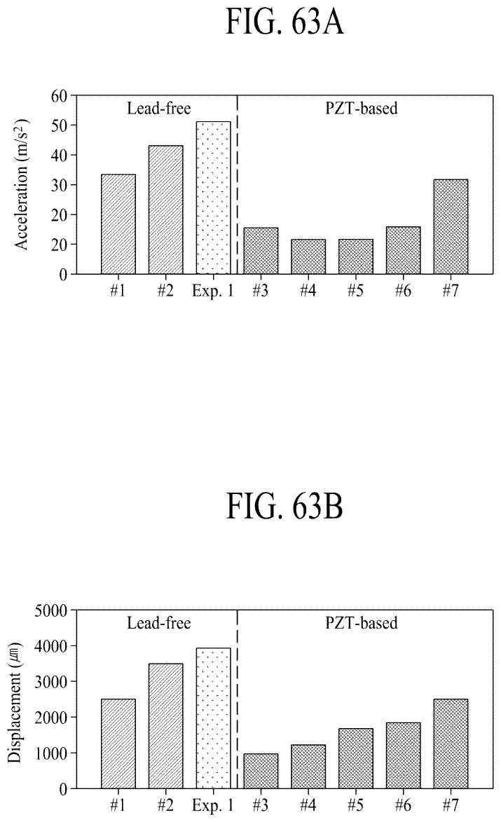

FIGS. 63A and 63B illustrate an acceleration and a displacement of each of a multi-layered actuator MLA according to a comparative example and a multi-layered actuator MLA prepared based on a non-TGG composition and a TGG composition according to an embodiment of the present disclosure. In FIGS. 63A and 63B, a multi-layered actuator according to an embodiment of the present disclosure has been prepared like FIG. 27B, a TGG composition has been used, and a BAZ content has been set to 0.02. In FIGS. 63A and 63B, comparative examples 1 to 8 (#1 to #7) are configured with a multi-layered actuator including a composition such as CLNKNG-SZ(#1), KNLNS-CSZ(#2), PZT-PZNN(#3), PZT-5H(#4, #5, #6), and PZT-5A(#7). For example, a CLNKNG-SZ sample may include a (Li, Na, K)(Nb, Sb)O₃-CaZrO₃ piezoelectric device to which CuO is added, and a KNLNS-CSZ sample may include a (K, Na, Li)(Nb, Sb)O₃-(Ca, Sr)ZrO₃ piezoelectric device to which CuO is added. A PZT-PZNN sample may include a Pb(Zr, Ti)O₃-Pb(Zn, Ni, Nb)O₃ (or PZT-PZNN) piezoelectric device. For example, a PZT-5H(Navy Type-VI) sample and a PZT-5A sample may include a piezoelectric device conforming with U.S. Navy standard based on Pb(Zr, Ti)O₃ (or PZT).

With reference to FIG. 63A, an acceleration of a multi-layered actuator (Exp. 1) according to an embodiment of the present disclosure is higher than that of a multi-layered actuator including compositions such as CLNKNG-SZ(#1), KNLNS-CSZ(#2), PZT-PZNN(#3), PZT-5H(#1, #5, #6), and PZT-5A(#7), which is a comparative example. For example, an acceleration of the multi-layered actuator (Exp. 1) according to an embodiment of the present disclosure is higher than that of a multi-layered actuator including CLNKNG-SZ(#1) and KNLNS-CSZ(#2), which are Pb-free compositions. For example, an acceleration of the multi-layered actuator according to an embodiment of the present disclosure represents a considerably high acceleration which is 1.5 to 4 times higher than that of a multi-layered actuator (#3 to #7) including a PZT-based composition. Accordingly, it has been confirmed that the multi-layered actuator according to an embodiment of the present disclosure does not include Pb and has a high acceleration. Comparing with actuators according to comparative examples, it has been measured that an actuating characteristic (acceleration or displacement) of an actuator according to the present disclosure is very high despite a lowest input signal being input. Because the actuator according to the present disclosure has a largest piezoelectric characteristic, it has been confirmed that an actuating characteristic (acceleration or displacement) is measured to be best.

With reference to FIG. 63B, a displacement of the multi-layered actuator according to an embodiment of the present disclosure is higher than that of the multi-layered actuator including compositions such as CLNKNG-SZ(#1), KNLNS-CSZ(#2), PZT-PZNN(#3), PZT-5H(#1, #5, #6), and PZT-5A(#7), which is the comparative example. For example, a displacement of the multi-layered actuator according to an embodiment of the present disclosure is higher than that of a multi-layered actuator including CLNKNG-SZ(#1) and KNLNS-CSZ(#2), which are Pb-free compositions. For example, a displacement of the multi-layered actuator according to an embodiment of the present disclosure represents a considerably high acceleration which is maximum 4 times higher than that of the multi-layered actuator (#3 to #7) including a PZT-based composition. Accordingly, it has been confirmed that the multi-layered actuator according to an embodiment of the present disclosure does not include Pb and has a high displacement.

The following Table 2 is a table which shows the number of layers, an off-resonance frequency fᵣ, a dimension, and an electric field of each of the actuator according to an embodiment of the present disclosure and the actuator according to the comparative example.

TABLE 2

| | | | | | | Electric |
|---|---|---|---|---|---|---|
| | | | Number | ƒr | Demension | field |
| Materials | | | of layer | (Hz) | (mm) | (V/mm) |
| Lead- | Experimental | TGG KNNS- | 5 | 57 | 28*6*0.52 | 0.25 |
| free | example(Exp. 1) | BZ-BAZ | | | | |
| | Example #1 | CLNKNS- | 5 | 58.5 | 27.1*5.8*0.5 | 0.25 |
| | | CZ | | | | |
| | Example #2 | KNLNS- | 5 | 57 | 28*6*0.52 | 0.25 |
| | | CSZ | | | | |
| PZT- | Example #3 | PZT-PZNN | 5 | 57 | 27.1*5.8*0.5 | 0.25 |
| based | Example #4 | PZT-5H | 1 | 65 | 60*20*0.2 | 0.8 |
| | Example #5 | PZT-5H | 2 | 58 | 60*20*0.4 | 0.8 |
| | Example #6 | PZT-5H | 2 | 88 | 63.5*31.8*0.38 | 0.3 |
| | Example #7 | PZT-5A | 2 | 68 | 63.5*31.8*0.38 | 0.45 |

With reference to Table 2, it has been confirmed that an actuator characteristic of a KNNS-BZ-BAZ(x=0.02) composition, which is a TGG composition according to an embodiment of the present disclosure among Pb-free materials, is highest. Accordingly, comparing with Pb-free actuators having an off-resonance frequency and a similar structure, it has been confirmed that an actuator including a TGG composition according to an embodiment of the present disclosure has an acceleration and a displacement characteristic which are best.

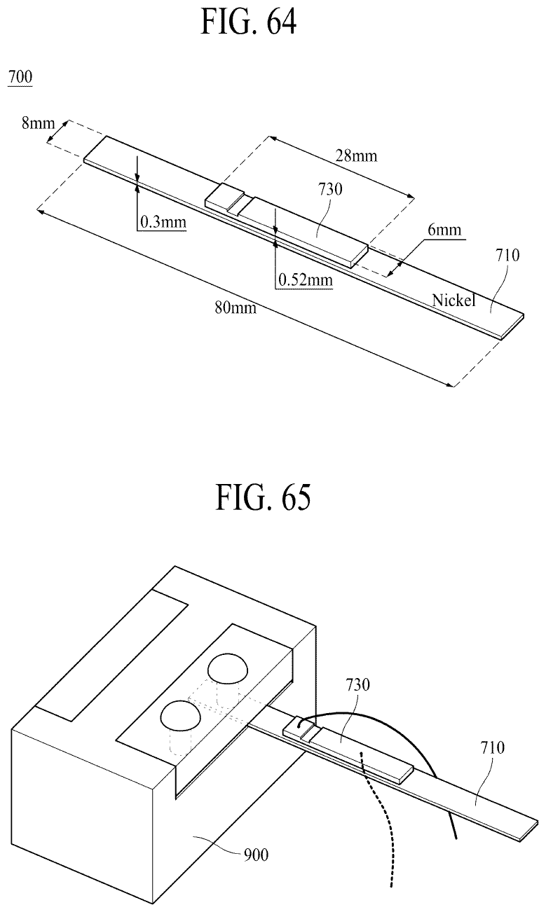

FIG. 64 illustrates a multi-layered actuator MLA prepared based on a non-TGG composition and a TGG composition according to an embodiment of the present disclosure. FIG. 65 illustrates an example where a non-TGG composition and a TGG composition according to an embodiment of the present disclosure is mounted on a zig.

With reference to FIGS. 64 and 65, a multi-layered actuator 600 according to an embodiment of the present disclosure may include a plate 710 and a piezoelectric device 730. The plate 710 may be a metal plate such as Ni or SUS, but embodiments of the present disclosure are not limited thereto. For example, a length of the plate 710 in a first direction (or an X-axis direction) and a length and a thickness of the plate 710 in a second direction (or a Y-axis direction) may be respectively prepared to be 80 mm, 8 mm, and 0.3 mm.

The piezoelectric device 730 may be provided at one surface of the plate 710. The piezoelectric device 730 may include a TGG composition expressed as Equation 2. The piezoelectric device 730 may be attached on an upper surface of the plate 710. For example, a length of the piezoelectric device 730 in the first direction (or the X-axis direction) and a length and a thickness of the piezoelectric device 730 in the second direction (or the Y-axis direction) may be respectively prepared to be 28 mm, 6 mm, and 0.52 mm.

The actuator 700 may be coupled to a zig 900. To this end, at least one hole for facilitating a connection with the zig 900 may be formed in one end of the plate 710. Various characteristics of the piezoelectric device 730 may be measured by the actuator 700 coupled to the zig 900.

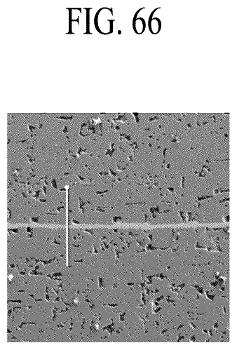

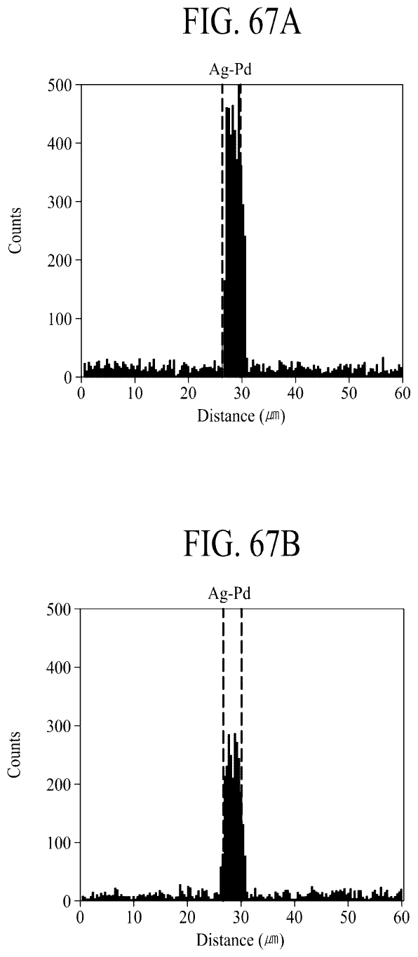

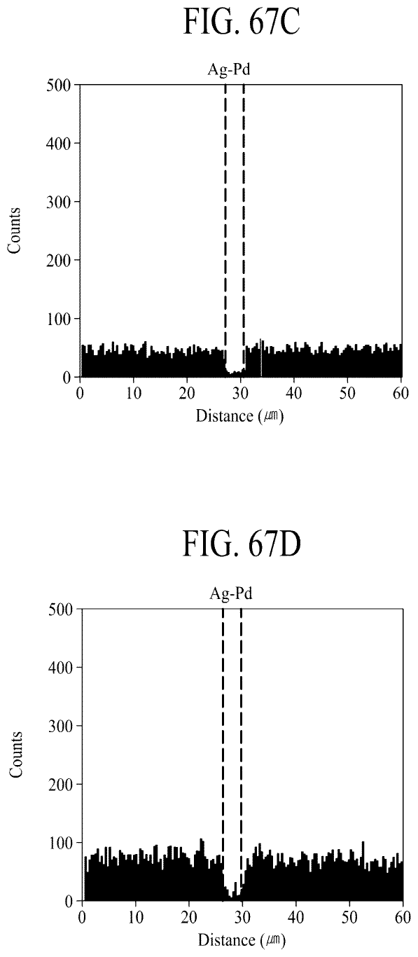

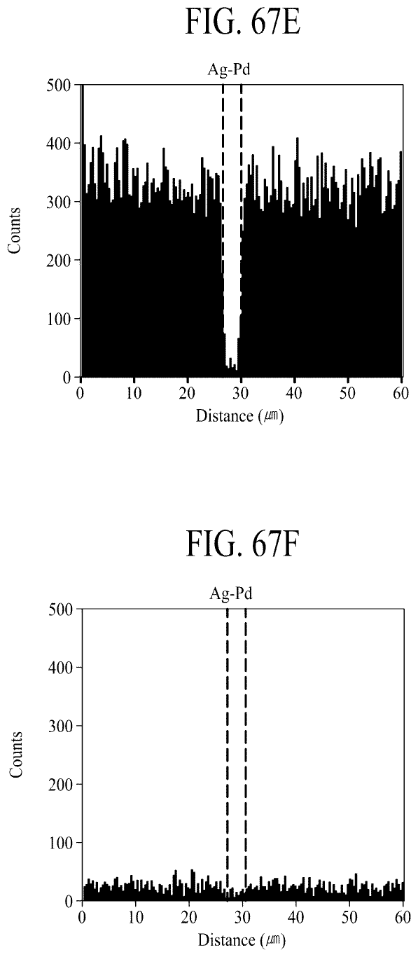

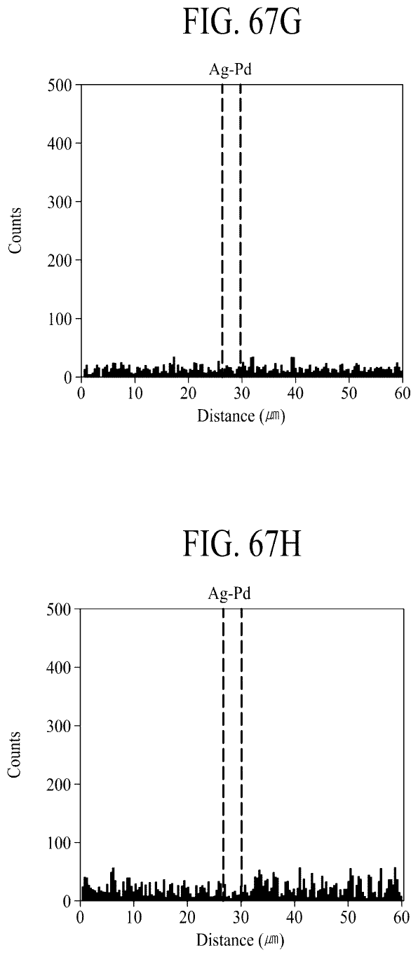

FIG. 66 is an image showing a break surface of a multi-layered actuator prepared based on a TGG composition according to an embodiment of the present disclosure. FIGS. 67A to 67I illustrate energy dispersive spectrometer (EDS) analysis data of a multi-layered actuator prepared based on a TGG composition according to an embodiment of the present disclosure. In FIGS. 67A to 67I, results obtained by analyzing elements of a break surface of the multi-layered actuator illustrated in FIG. 66 are shown.

The inventors have performed energy dispersive spectrometer (EDS) analysis, so as to determine whether to perform a diffusion reaction between an electrode used in manufacturing a multi-layered actuator and a TGG piezoelectric composition based on Chemical Equation 2.

In FIG. 66, a white vertical line in a middle of an image is a guide line for EDS. In FIG. 66, results obtained by performing line element analysis based on EDS along the guide line in the middle of the image are shown in FIGS. 67A to 67I. In FIGS. 67A to 67I, an x-axis distance is a length of a white guide line (a vertical line) of the middle of FIG. 66, and the y axis represents detection intensity (counts) of an analysis element.

FIGS. 67A to 67I show whether elements included in KNNS-BZ-BAZ (x=0.02) based on TGG Chemical Equation 2 perform a diffusion reaction with an electrode used in manufacturing a multi-layered actuator. For example, the electrode may include silver (Ag) and palladium (Pd), a content of Ag may be 70%, and a content of Pd may be 30%, but embodiments of the present disclosure are not limited thereto. Each of left regions and right regions of FIGS. 65A to 651 represent a piezoelectric device, and a middle region represents a guide line for element analysis. For example, in FIGS. 67A to 67I, an analysis of EDS may be for checking whether there is no element movement between an electrode layer of a multi-layered actuator and a piezoelectric device layer. FIGS. 67A to 67I represent whether diffusion reactions of Ag, Pd, Na, K, Nb, Sb, Ba, Bi, and Zr are performed, respectively.

With reference to FIGS. 66 and 67A to 67I, as a result of element analysis on a break surface of a piezoelectric actuator according to an embodiment of the present disclosure, it has been confirmed that element diffusion between an electrode (Ag-Pd) and a TGG KNNS-BZ-BAZ composition is not performed at all. Accordingly, a TGG composition according to an embodiment of the present disclosure has been confirmed to be a material which is suitable for manufacturing a multi-layered actuator.

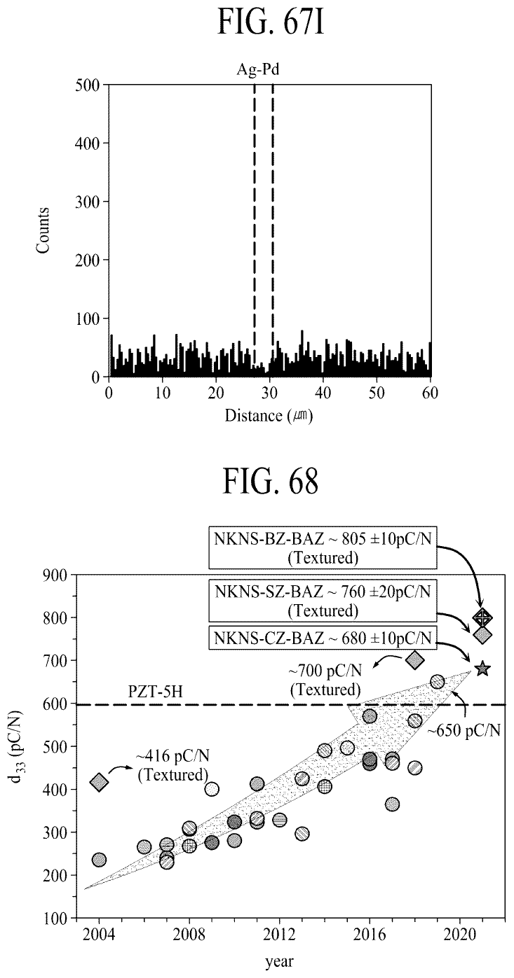

FIG. 68 illustrates a piezoelectric characteristic of each of a non-TGG composition and a TGG composition according to an embodiment of the present disclosure.

With reference to FIG. 68, research for enhancing a piezoelectric characteristic of a piezoelectric device is being actively performed, and in an electrode and a TGG KNNS-BZ-BAZ composition according to an embodiment of the present disclosure, it has been confirmed that a high piezoelectric characteristic of 805 Pc/N is implemented.

According to an embodiment of the present disclosure, because a piezoelectric material composition does not include lead (Pb) and has a high piezoelectric characteristic, a piezoelectric device and a display apparatus each including the piezoelectric material composition may be driven with a low driving voltage.

According to an embodiment of the present disclosure, a method of manufacturing a piezoelectric material composition may be considerably reduced in time and cost, thereby considerably enhancing productivity.

According to an embodiment of the present disclosure, productivity may be enhanced, and thus, optimization of a manufacturing process may be implemented.

According to an embodiment of the present disclosure, because a piezoelectric material composition does not include Pb, a production restriction material may be reduced and replacement of a harmful material may be implemented, and thus, an environment-friendly piezoelectric material composition may be provided.

According to an embodiment of the present disclosure, a piezoelectric material composition may have good energy harvesting characteristic and actuating characteristic, and thus, may be applied to all of an energy harvester and a multi-layered actuator.

According to an embodiment of the present disclosure, when a non-TGG process is applied, a problem where a piezoelectric material composition has a low piezoelectric charge constant may be solved, and thus, a piezoelectric material composition having a high piezoelectric charge constant may be implemented.

According to an embodiment of the present disclosure, a TGG process may be applied for improving a low piezoelectric charge constant of when the non-TGG process is applied, but a problem where a piezoelectric charge constant is low may be solved despite the application of the TGG process, thereby implementing a piezoelectric material composition having a high piezoelectric charge constant.

According to an embodiment of the present disclosure, a piezoelectric material composition may configure a combination structure of R-O-T 3 phases through the non-TGG process and/or the TGG process, thereby implementing a piezoelectric material composition having a piezoelectric charge constant which is higher than a structure of R-O 2 phases.

FIG. 69 illustrates a vehicular sound apparatus according to an embodiment of the present disclosure:

With reference to FIG. 69, a vehicular sound apparatus according to an embodiment of the present disclosure may include a sound apparatus 500. The sound apparatus 500 may be disposed or equipped in a vehicle so as to output a sound S toward an internal space IS of a vehicle 800.

The vehicle 800 may include an interior material (or an interior finish material) 850. In the following description, for convenience of description, the “interior material 850” may be referred to as a “vehicular interior material 850”.

The vehicular interior material 850 may include all parts configuring the inside of the vehicle 800, or may include all parts disposed at the internal space IS of the vehicle 800. For example, the vehicular interior material 850 may be an interior member or an inner finishing member of the vehicle 800, but embodiments of the present disclosure are not limited thereto.

The vehicular interior material 850 according to an embodiment of the present disclosure may be configured to be exposed at the internal or indoor space IS of the vehicle 800, in the internal or indoor space IS of the vehicle 800. For example, the vehicular interior material 850 may be provided to cover one surface (or an interior surface) of at least one of a main frame (or a vehicular body), a side frame (or a side body), a door frame (or a door body), a handle frame (or a steering hub), and a seat frame, which are exposed at the indoor space IS of the vehicle 800.

The vehicular interior material 850 according to an embodiment of the present disclosure may include a dash board, a pillar interior material (or a pillar trim), a floor interior material (or a floor carpet), a roof interior material (or a headliner), a door interior material (or a door trim), a handle interior material (or a steering cover), a seat interior material, a rear package interior material (or a backseat shelf), an overhead console (or an indoor illumination interior material), a rear view mirror, a glove box, and a sun visor, but embodiments of the present disclosure are not limited thereto.

The vehicular interior material 850 according to an embodiment of the present disclosure may include one or more of metal, wood, rubber, plastic, glass, fiber, cloth, paper, mirror, leather, and carbon, but embodiments of the present disclosure are not limited thereto. The vehicular interior material 850 including a plastic material may be an injection material which is implemented by an injection process using thermosetting resin or thermoplastic resin, but embodiments of the present disclosure are not limited thereto. The vehicular interior material 850 including a fiber material may include one or more of synthetic fiber, carbon fiber (or aramid fiber), and natural fiber, but embodiments of the present disclosure are not limited thereto. The vehicular interior material 850 including a fiber material may include may be a fabric sheet, a knitting sheet, or a nonwoven fabric, but embodiments of the present disclosure are not limited thereto. For example, the interior material 20c or the outer surface member including a fiber material may be a fabric member, but embodiments of the present disclosure are not limited thereto. For example, the paper may be cone paper. For example, the cone paper may be pulp or foam plastic, but embodiments of the present disclosure are not limited thereto. The vehicular interior material 850 including a leather material may include may be a natural leather or an artificial leather, but embodiments of the present disclosure are not limited thereto.

The vehicular interior material 850 according to an embodiment of the present disclosure may include one or more of a flat-part and a curved part. For example, the vehicular interior material 850 may have a structure corresponding to a structure of a corresponding vehicular structure material, or may have a structure which differs from the structure of the corresponding vehicular structure material.

According to an embodiment of the present disclosure, the sound apparatus 500 may be disposed at the vehicular interior material 850. The sound apparatus 500 may vibrate the vehicular interior material 850 to generate a sound S, based on a vibration of the vehicular interior material 850. For example, the sound apparatus 500 may directly vibrate the vehicular interior material 850 to generate the sound S, based on a vibration of the vehicular interior material 850.

For example, the sound apparatus 500 may be configured with one of the piezoelectric devices according to one or more embodiments of the present disclosure described above with reference to FIGS. 1 to 53.

For example, the sound apparatus 500 may be configured to vibrate the vehicular interior material 850 to output the sound S toward the internal or indoor space IS of the vehicle 800. Therefore, the vehicular interior material 850 may be used as a sound vibration plate. The vehicular interior material 850 may be a vibration plate, a sound vibration plate, or a sound generating plate for outputting the sound S. For example, the vehicular interior material 850 may have a size which is greater than that of the sound apparatus 500, but embodiments of the present disclosure are not limited thereto.

For example, the sound apparatus 500 may be disposed at one or more of a dash board, a pillar interior material, a floor interior material, a roof interior material, a door interior material, a handle interior material, and a seat interior material, or may be disposed in one or more of a rear package interior material, an overhead console, a rear view mirror, a glove box, and a sun visor.

The sound apparatus 500 according to an embodiment of the present disclosure may vibrate a correspond vehicular interior material 850 through at least one of one or more sound apparatuses 500 disposed at the vehicular interior material 850 to output a realistic sound S and/or stereo sound, including a multichannel, toward the indoor space IS of the vehicle 800.

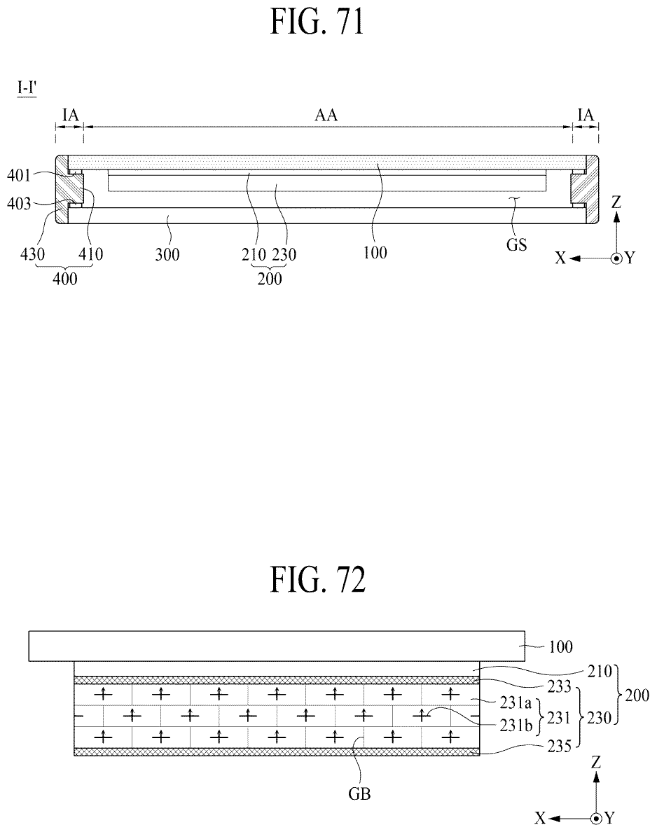

FIG. 70 is a perspective view of a display apparatus according to an embodiment of the present disclosure. FIG. 71 is a cross-sectional view taken along line I-I′ of FIG. 70 according to an embodiment of the present disclosure.

With reference to FIGS. 70 and 71, an apparatus according to an embodiment of the present disclosure may include a vibration member 100 and a piezoelectric device 200.

The vibration member 100 may be configured to display an image. The piezoelectric device 200 may be disposed at a rear surface (or a backside) of the vibration member 100. For example, the piezoelectric device 200 may be configured to vibrate the vibration member 100.

For example, the vibration member 100 may output a sound based on a vibration of the piezoelectric device 200. For example, the vibration member 100 may be a vibration object, a display panel, a vibration plate, or a front member, but embodiments of the present disclosure are not limited thereto.

For example, the vibration member 100 or the vibration object may include one or more among a display panel including a pixel configured to display an image, a screen panel on which an image is projected from a display apparatus, a lighting panel, a signage panel, a vehicular interior material, a vehicular glass window; a vehicular exterior material, a building ceiling material, a building interior material, a building glass window, an aircraft interior material, an aircraft glass window, wood, plastic, glass, metal, cloth, fiber, paper, rubber, leather, and a mirror, but embodiments of the present disclosure are not limited thereto.

In the following description, the vibration member 100 is a display panel 100 will be described.

The display panel 100 may display an electronic image, a digital image, a still image, or a video image. For example, the display panel 100 may output light to display an image. The display panel 100 may be a curved display panel, or may be any type of display panel, such as a liquid crystal display panel, an organic light emitting display panel, a quantum dot light emitting display panel, a micro light emitting diode display panel, and an electrophoresis display panel, or the like. The display panel 100 may be a flexible display panel. For example, the display panel 100 may a flexible light emitting display panel, a flexible electrophoretic display panel, a flexible electro-wetting display panel, a flexible micro light emitting diode display panel, or a flexible quantum dot light emitting display panel, but embodiments of the present disclosure are not limited thereto.

The display panel 100 according to an embodiment of the present disclosure may include a display area AA (or an active area) for displaying an image according to driving of the plurality of pixels. Also, the display panel 100 may further include a non-display area IA surrounding the display area AA, but embodiments of the present disclosure are not limited thereto.

The piezoelectric device 200 may vibrate the display panel 100 at a rear surface of the display panel 100, thereby providing a sound and/or a haptic feedback based on a vibration of the display panel 100 to a user (or a viewer). The piezoelectric device 200 may be implemented at the rear surface of the display panel 100 to directly vibrate the display panel 100.

As an embodiment of the present disclosure, the piezoelectric device 200 may vibrate according to a voice signal synchronized with an image displayed by the display panel 100 to vibrate the display panel 100. As another embodiment of the present disclosure, the piezoelectric device 200 may be disposed at the display panel 100, or may vibrate according to a haptic feedback signal (or a tactile feedback signal) synchronized with a user touch applied to a touch panel (or a touch sensor layer) embedded into the display panel 100 to vibrate the display panel 100. Accordingly, the display panel 100 may vibrate based on a vibration of the piezoelectric device 200 to provide a user (or a viewer) with at least one of sound and a haptic feedback.

The piezoelectric device 200 according to an embodiment of the present disclosure may be implemented to have a size corresponding to the display area AA of the display panel 100. A size of the piezoelectric device 200 may be 0.9 to 1.1 times a size of the display area AA, but embodiments of the present disclosure are not limited thereto. For example, a size of the piezoelectric device 200 may be the same as or smaller than the size of the display area AA. For example, a size of the piezoelectric device 200 may be the same as or approximately same as the display area AA of the display panel 100, and thus, the piezoelectric device 200 may cover a most region of the display panel 100 and a vibration generated by the piezoelectric device 200 may vibrate a whole portion of the display panel 100, and thus, localization of a sound may be high, and satisfaction of a user may be improved. Also, a contact area (or panel coverage) between the display panel 100 and the piezoelectric device 200 may increase, and thus, a vibration region of the display panel 100 may increase, thereby improving a sound of a middle-low-pitched sound band generated based on a vibration of the display panel 100. And, a piezoelectric device 200 applied to a large-sized display apparatus may vibrate the entire display panel 100 having a large size (or a large area), and thus, localization of a sound based on a vibration of the display panel 100 may be further enhanced, thereby realizing an improved sound effect. Therefore, the piezoelectric device 200 according to an embodiment of the present disclosure may be disposed at the rear surface of the display panel 100 to sufficiently vibrate the display panel 100 in a vertical (or front-to-rear) direction, thereby outputting a desired sound to a forward region in front of the apparatus or the display apparatus.

The piezoelectric device 200 according to an embodiment of the present disclosure may be implemented as a film type. Since the piezoelectric device 200 may be implemented as a film type, it may have a thickness which is thinner than the display panel 100, and thus, a thickness of the display apparatus may not increase due to the arrangement of the piezoelectric device 200. For example, the piezoelectric device 200 may use the display panel 100 as a sound vibration plate. For example, the piezoelectric device 200 may be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a vibration plate, but embodiments of the present disclosure are not limited thereto. As another embodiment of the present disclosure, the piezoelectric device 200 may not be disposed at the rear surface of the display panel 100 and may be applied to the vibration object instead of the display panel. For example, the vibration object may be one or more of a non-display panel, wood, metal, plastic, glass, cloth, paper, mirror, fiber, rubber, leather, a vehicle interior material, a vehicle glass window, a building indoor ceiling, a building glass window, a building interior material, an aircraft interior material, and an aircraft glass window, or the like, but embodiments of the present disclosure are not limited thereto. For example, the non-display panel may be a light emitting diode lighting panel (or apparatus), an organic light emitting lighting panel (or apparatus), or an inorganic light emitting lighting panel (or apparatus), or the like, but embodiments of the present disclosure are not limited thereto. In this case, the vibration object may be applied as a vibration plate, and the piezoelectric device 200 may vibrate the vibration object to output a sound.

The piezoelectric device 200 according to an embodiment of the present disclosure may further include a vibration structure 230, a connection member 210 disposed between the vibration structure 230 and the display panel 100.

According to an embodiment of the present disclosure, the connection member 210 may include at least one substrate, and may include an adhesive layer attached to one surface or both surfaces of the substrate, or may be configured as a single layer of adhesive layer.

For example, the connection member 210 may include a foam pad, a double-sided foam pad, a double-sided tape, a double-sided foam tape, a double-sided adhesive, or an adhesive, or the like, but embodiments of the present disclosure are not limited thereto. For example, the adhesive layer of the connection member 210 may include epoxy-based, acrylic-based, silicone-based, or urethane-based, but embodiments of the present disclosure are not limited thereto.

The display panel 100 according to an embodiment of the present disclosure may further include a supporting member 300 disposed at a rear surface of the display panel 100.

The supporting member 300 may cover a rear surface of the display panel 100. For example, the supporting member 300 may cover a whole rear surface of the display panel 100 with a gap space GS therebetween. For example, the supporting member 300 may include at least one or more among a glass material, a metal material, and a plastic material. For example, the supporting member 300 may be a rear structure or a set structure. For example, the supporting member 300 may be a cover bottom, a plate bottom, a back cover, a base frame, a metal frame, a metal chassis, a chassis base, or m-chassis, or the like, but embodiments of the present disclosure are not limited thereto. Therefore, the supporting member 300 may be implemented as an arbitrary type frame or a plate-shaped structure disposed at a rear surface of the display panel 100.

The apparatus according to an embodiment of the present disclosure may further include a middle frame 400.

The middle frame 400 may be disposed between a rear periphery of the display panel 100 and a front periphery of the supporting member 300. The middle frame 400 may support at least one or more among the rear periphery of the display panel 100 and the front periphery of the supporting member 300, respectively, and may surround one or more of side surfaces among each of the display panel 100 and the supporting member 300. The middle frame 400 may configure a gap space GS between the display panel 100 and the supporting member 300. The middle frame 400 may be referred to as a middle cabinet, a middle cover, a middle chassis, or the like, but embodiments of the present disclosure are not limited thereto.

The middle frame 400 according to an embodiment of the present disclosure may include a first supporting part 410 and a second supporting part 430.

The first supporting part 410 may be disposed between the rear periphery of the display panel 100 and the front periphery of the supporting member 300, and thus, may configure the gap space GS between the display panel 100 and the supporting member 300. A front surface of the first supporting part 410 may be coupled or connected to the rear periphery of the display panel 100 by a first frame connection member 401. A rear surface of the first supporting part 410 may be coupled or connected to the front periphery of the supporting member 300 by a second frame connection member 403. For example, the first supporting part 710 may have a single picture frame structure having a square shape or a frame structure having a plurality of divided bar shapes, but embodiments of the present disclosure are not limited thereto.

The second supporting part 430 may be vertically coupled to an outer surface of the first supporting part 410 in parallel with a thickness direction Z of the apparatus. The second supporting part 430 may surround one or more among an outer surface of the display panel 100 and an outer surface of the supporting member 300, thereby protecting the outer surface of each of the display panel 100 and the supporting member 300. The first supporting part 410 may protrude from an inner surface of the second supporting part 430 toward the gap space GS between the display panel 100 and the supporting member 300.

FIG. 72 illustrates a piezoelectric device of FIG. 70.

With reference to FIG. 72, the piezoelectric device 200 according to an embodiment of the present disclosure may include a vibration structure 230.

The vibration structure 230 may include a piezoelectric device layer 231, a first electrode part 233, and a second electrode part 235.

The vibration structure 230 may include a first electrode part 233 disposed at a first surface of a piezoelectric device layer 231, and a second electrode part 235 disposed at a second surface, which is opposite to (or different from) the first surface, of the piezoelectric device layer 231.

The piezoelectric device layer 231 may include a first material layer 231a and a second material layer 231b surrounded by the first material layer 231a. According to an embodiment of the present disclosure, one first material layer 231a and one second material layer 231b may configure one grain having the same or substantially the same crystal direction, and a grain boundary GB may be formed at a portion where another first material layer 231a and second material layer 231b configuring another adjacent grain contact each other. In one or more embodiments of the present disclosure, the crystal direction is +Z axis direction defined in the figures. However, embodiments of the present disclosure are not limited thereto, and the crystal direction could also be various directions applicable.

According to an embodiment of the present disclosure, a grain of the first material layer 231a may be grown based on a crystal direction of the second material layer 231b, and thus, a plurality of first material layers 231a may have the same or substantially the same crystal direction, and for example, may have a (001) crystal direction, but embodiments of the present disclosure are not limited thereto.

According to an embodiment of the present disclosure, the first electrode part 233 may be disposed at the first surface of a piezoelectric device layer 231. The second electrode part 235 may be disposed at the second surface, which is opposite to (or different from) the first surface, of the piezoelectric device layer 231.

The first electrode part 233 and the second electrode part 235 may use a metal electrode, and for example, a silver electrode may be used, but embodiments of the present disclosure are not limited thereto.

Moreover, in FIG. 72, the vibration structure 230 is illustrated as a single layer, but may be configured to be additionally stacked based on the desired performance of a piezoelectric device.

The embodiment of the vibration structure 230 described above has been described as an example. The vibration structure 230 according to an embodiment of the present disclosure is not limited to a specific structure or configuration, such as the amount and/or location, or the like, of material layers.

A piezoelectric device according to an embodiment of the present disclosure may be applied to (or included in) a vibration apparatus (or a sound apparatus) disposed at an apparatus. The apparatus according to an embodiment of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic book, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game apparatuses, notebook computers, monitors, cameras, camcorders, home appliances, or the like. Addition, the vibration apparatus according to some embodiments of the present disclosure may be applied to (or included in) organic light emitting lighting apparatuses or inorganic light emitting lighting apparatuses. When the vibration apparatus is applied to (or included in) lighting apparatuses, the lighting apparatuses may act as lighting and a speaker. Addition, when the vibration apparatus of the present disclosure is applied to (or included in) a mobile device, or the like, the vibration apparatus may act as one or more of a speaker, a receiver, and a haptic device, but embodiments of the present disclosure are not limited thereto.

A vibration apparatus and an apparatus including the same according to one or more embodiment of the present disclosure are described below.

A piezoelectric material composition according to an embodiment of the present disclosure may be represented by Equation 1:

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A , \qquad Equation 1$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00.

According to one or more embodiments of the present disclosure, the piezoelectric material composition may comprise the Sb of 0.0 to 0.1.

According to one or more embodiments of the present disclosure, the piezoelectric material composition may comprise (BiAg)ZrO₃ (BAZ) of 0.03.

According to one or more embodiments of the present disclosure, the piezoelectric material composition may comprise the Fe₂O₃ of 1 mol % or less.

According to one or more embodiments of the present disclosure, an orthorhombic (O) phase, a rhombohedral (R) phase, and a tetragonal (T) phase may be provided together in the piezoelectric material composition, and a volume fraction of each of the orthorhombic (O), the rhombohedral (R), and the tetragonal (T) may have a value of 30% to 35%.

According to one or more embodiments of the present disclosure, the piezoelectric material composition may have a piezoelectric charge constant within a range of 400 pC/N to 650 pC/N.

According to one or more embodiments of the present disclosure, a unipolar strain of the piezoelectric material composition may have a value within a range of 0.15% to 0.17%.

A piezoelectric material composition according to an embodiment of the present disclosure may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, 0.00<d≤1.00, and 2.00≤e≤4.00.

According to one or more embodiments of the present disclosure, the piezoelectric material composition may comprise a first material, and a second material surrounded by the first material.

According to one or more embodiments of the present disclosure, the first material may be represented by Equation 3,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A , \qquad Equation 1$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

According to one or more embodiments of the present disclosure, the first material may comprise Sb of 0.0 to 0.1.

According to one or more embodiments of the present disclosure, the first material may comprise (BiAg)ZrO₃ of 0.02.

According to one or more embodiments of the present disclosure, the piezoelectric material composition may have a grain size of 30 μm to 40 μm.

According to one or more embodiments of the present disclosure, the piezoelectric material composition may have a piezoelectric charge constant within a range of 790 pC/N to 810 pC/N.

According to one or more embodiments of the present disclosure, the first material may comprise Fe₂O₃ of 1 mol % or less.

According to one or more embodiments of the present disclosure, the second material may comprise NaNbO₃.

According to one or more embodiments of the present disclosure, the second material may comprise the NaNbO₃ of 2 mol % to 4 mol %.

According to one or more embodiments of the present disclosure, the first material may comprise a plurality of grains oriented in a (001) single orientation, and the second material may be disposed in the plurality of grains, and the plurality of grains may be grown by reacting from the second material.

According to one or more embodiments of the present disclosure, a Lotgering factor of the piezoelectric material composition may be 97% or more.

According to one or more embodiments of the present disclosure, an orthorhombic (O) phase, a rhombohedral (R) phase, and/or a tetragonal (T) phase may be provided together in the piezoelectric material composition, and a volume fraction of each of the orthorhombic (O) and the rhombohedral (R) may be 80% or more.

A method of manufacturing a piezoelectric material composition according to an embodiment of the present disclosure, the method may comprise mixing a matrix material with a seed material to prepare a slurry, molding the slurry to prepare a molding element, and sintering the molding element to prepare a sintered material, the sintered material may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, 0.00<d≤1.00, and 2.00≤e≤4.00.

According to one or more embodiments of the present disclosure, the matrix material may be represented by Equation 3,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 3 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

According to one or more embodiments of the present disclosure, the seed material may comprise NaNbO₃.

According to one or more embodiments of the present disclosure, the piezoelectric material composition may comprise the seed material of 2 mol % to 4 mol %.

According to one or more embodiments of the present disclosure, the molding of the slurry to prepare the molding element may comprise tape-casting the slurry, primarily molding a tape-casted piezoelectric material, and secondarily molding a primarily-molded piezoelectric material, and a tape casting temperature may be 30° C. to less than 90° C.

According to one or more embodiments of the present disclosure, preparing the matrix material may comprise mixing raw materials for manufacturing the matrix material, calcining and synthesizing mixed raw materials, and milling the matrix material manufactured by the calcining and synthesizing.

According to one or more embodiments of the present disclosure, the calcining and synthesizing of the mixed raw materials may comprise calcining the mixed raw materials for 3 hours to 6 hours at 750° C. to 850° C., and then, cooling calcined raw materials up to a room temperature.

According to one or more embodiments of the present disclosure, preparing the seed material may comprise primarily weighing a raw material of the seed material, preparing a primary seed, secondarily weighing the primary seed, and preparing a secondary seed.

According to one or more embodiments of the present disclosure, an orthorhombic (O) phase, a rhombohedral (R) phase, and/or a tetragonal (T) phase may be provided together in the piezoelectric material composition, and a volume fraction of each of the orthorhombic (O) and the rhombohedral (R) may be 80% or more.

A piezoelectric device according to one or more embodiments of the present disclosure may comprise a piezoelectric device layer including a first material and a second material surrounded by the first material, a first electrode part disposed at a first surface of the piezoelectric device layer, and a second electrode part disposed at a second surface different from the first surface of the piezoelectric device layer, the piezoelectric device layer may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00 x≤0.04, 0.00<d≤1.00, and 2.00≤e≤4.00.

According to one or more embodiments of the present disclosure, the second material may comprise NaNbO₃ and may be added to the piezoelectric material composition of Equation 1 by 2 mol % to 4 mol %.

According to one or more embodiments of the present disclosure, the first material may comprise a plurality of grains oriented in a (001) single orientation, and the second material may be disposed in the plurality of grains, and the plurality of grains may be grown by reacting from the second material.

An apparatus according to an embodiment of the present disclosure may comprise a vibration member, and a piezoelectric device disposed at a rear surface of the vibration member. The piezoelectric device may comprise a piezoelectric device layer including a first material and a second material surrounded by the first material, a first electrode part disposed at a first surface of the piezoelectric device layer, and a second electrode part disposed at a second surface different from the first surface of the piezoelectric device layer, the piezoelectric device layer may be represented by Equation 2,

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$

where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, 0.00<d≤1.00, and 2.00≤e≤4.00.

According to one or more embodiments of the present disclosure, the vibration member may comprise one or more of a display panel including a plurality of pixels displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a building, an interior material of a building, a glass window of a building, an interior material of an aircraft, a glass window of an aircraft, wood, plastic, glass, metal, cloth, fiber, paper, rubber, leather, carbon, and a mirror.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the piezoelectric material composition, the method of manufacturing the same, the piezoelectric device, and the apparatus including the piezoelectric of the device present disclosure without departing from the technical idea or scope of the disclosure. Thus, it is intended that the present disclosure cover the modifications and variations of this disclosure provided they come within the scope of the appended claims and their equivalents.

What is claimed is:

1. A piezoelectric material composition represented by Equation 1,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A , \qquad Equation 1$$
where Tis Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

2. The piezoelectric material composition of claim 1, wherein the piezoelectric material composition comprises the Sb of 0.0 to 0.1.

3. The piezoelectric material composition of claim 1, wherein the piezoelectric material composition comprises (BiAg)ZrO₃ (BAZ) of 0.03.

4. The piezoelectric material composition of claim 1, wherein the piezoelectric material composition comprises the Fe₂O₃ of 1 mol % or less.

5. The piezoelectric material composition of claim 1, wherein:
an orthorhombic (O) phase, a rhombohedral (R) phase, and a tetragonal (T) phase are provided together in the piezoelectric material composition, and
a volume fraction of each of the orthorhombic (O), the rhombohedral (R), and the tetragonal (T) has a value of 30% to 35%.

6. The piezoelectric material composition of claim 1, wherein the piezoelectric material composition has a piezoelectric charge constant within a range of 400 pC/N to 650 pC/N.

7. The piezoelectric material composition of claim 1, wherein a unipolar strain of the piezoelectric material composition has a value within a range of 0.15% to 0.17%.

8. A piezoelectric material composition represented by Equation 2,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, 0.00<d≤1.00, and 2.00≤e≤4.00.

9. The piezoelectric material composition of claim 8, wherein the piezoelectric material composition comprises:
a first material; and
a second material surrounded by the first material.

10. The piezoelectric material composition of claim 9, where the first material represented by Equation 3,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 3 ]$$
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

11. The piezoelectric material composition of claim 9, wherein the first material comprises Sb of 0.0 to 0.1.

12. The piezoelectric material composition of claim 9, wherein the first material comprises (BiAg)ZrO₃ of 0.02.

13. The piezoelectric material composition of claim 12, wherein the piezoelectric material composition has a grain size of 30 μm to 40 μm.

14. The piezoelectric material composition of claim 12, wherein the piezoelectric material composition has a piezoelectric charge constant within a range of 790 pC/N to 810 pC/N.

15. The piezoelectric material composition of claim 9, wherein the first material comprises Fe₂O₃ of 1 mol % or less.

16. The piezoelectric material composition of claim 9, wherein the second material comprises NaNbO₃.

17. The piezoelectric material composition of claim 16, wherein the second material comprises the NaNbO₃ of 2 mol % to 4 mol %.

18. The piezoelectric material composition of claim 9, wherein the first material comprises a plurality of grains oriented in a (001) single orientation, and the second material is disposed in the plurality of grains, and
the plurality of grains are grown by reacting from the second material.

19. The piezoelectric material composition of claim 8, wherein a Lotgering factor of the piezoelectric material composition is 97% or more.

20. The piezoelectric material composition of claim 8, wherein an orthorhombic (O) phase, a rhombohedral (R) phase, and/or a tetragonal (T) phase are provided together in the piezoelectric material composition, and
wherein a volume fraction of each of the orthorhombic (O) and the rhombohedral (R) is 80% or more.

21. A method of manufacturing a piezoelectric material composition, the method comprising:
mixing a matrix material with a seed material to prepare a slurry;
molding the slurry to prepare a molding element; and
sintering the molding element to prepare a sintered material,
wherein the sintered material is represented by Equation 2,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, 0.00<d≤1.00, and 2.00≤e≤4.00.

22. The method of claim 21, wherein the matrix material is represented by Equation 3,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A \qquad [ Equation 3 ]$$
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

23. The method of claim 21, wherein the seed material comprises NaNbO₃.

24. The method of claim 23, wherein the piezoelectric material composition comprises the seed material of 2 mol % to 4 mol %.

25. The method of claim 21, wherein the molding of the slurry to prepare the molding element comprises:
tape-casting the slurry;
primarily molding a tape-casted piezoelectric material; and
secondarily molding a primarily-molded piezoelectric material, and
wherein a tape casting temperature is 30° C. to less than 90° C.

26. The method of claim 21, wherein preparing the matrix material comprises:
mixing raw materials for manufacturing the matrix material;
calcining and synthesizing the mixed raw materials; and
milling the matrix material manufactured by the calcining and synthesizing.

27. The method of claim 26, wherein the calcining and synthesizing of the mixed raw materials comprises calcining the mixed raw materials for 3 hours to 6 hours at 750° C. to 850° C., and then, cooling calcined raw materials up to a room temperature.

28. The method of claim 21, wherein preparing the seed material comprises:
primarily weighing a raw material of the seed material;
preparing a primary seed;
secondarily weighing the primary seed; and
preparing a secondary seed.

29. The method of claim 21, wherein:
an orthorhombic (O) phase, a rhombohedral (R) phase, and/or a tetragonal (T) phase are provided together in the piezoelectric material composition; and
a volume fraction of each of the orthorhombic (O) and the rhombohedral (R) is 80% or more.

30. A piezoelectric device, comprising:
a piezoelectric device layer including a first material and a second material;
a first electrode part disposed at a first surface of the piezoelectric device layer; and
a second electrode part disposed at a second surface different from the first surface of the piezoelectric device layer,
wherein the piezoelectric device layer is represented by Equation 2,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% A + e mol \% {NaNbO}_{3} \qquad [ Equation 2 ]$$
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, 0.00<d≤1.00, and 2.00≤e≤4.00.

31. The piezoelectric device of claim 30, wherein the second material comprises NaNbO₃ and is added to the piezoelectric material composition of Equation 1 by 2 mol % to 4 mol %.

32. The piezoelectric device of claim 30, wherein the first material comprises a plurality of grains oriented in a (001) single orientation, and the second material is disposed in the plurality of grains, and
the plurality of grains are grown by reacting from the second material.

33. An apparatus, comprising:
a vibration member; and
the piezoelectric device of claim 30, the piezoelectric device being disposed at a rear surface of the vibration member.

34. The apparatus of claim 33, wherein the vibration member comprises one or more of a display panel including a plurality of pixels displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a building, an interior material of a building, a glass window of a building, an interior material of an aircraft, a glass window of an aircraft, wood, plastic, glass, metal, cloth, fiber, paper, rubber, leather, carbon, and a mirror.
